(19) United States
(12) Patent Application Publication
(10) Pub. No.: US 2020/0198389 A1
(43) Pub. Date: Jun. 25, 2020

(54) PRINTING PLATE PRECURSOR AND PRINTING PLATE PRECURSOR LAMINATE

(71) Applicant: FUJIFILM Corporation, Tokyo (JP)

(72) Inventors: Shuji SHIMANAKA, Haibara-gun (JP); Yusuke IKEYAMA, Haibara-gun (JP); Shumpei WATANABE, Haibara-gun (JP)

(73) Assignee: FUJIFILM Corporation, Tokyo (JP)

(21) Appl. No.: 16/801,195

(22) Filed: Feb. 26, 2020

Related U.S. Application Data
(63) Continuation of application No. PCT/JP2018/032508, filed on Aug. 31, 2018.

(30) Foreign Application Priority Data
Aug. 31, 2017 (JP) 2017-167854

(51) Int. Cl. B41N 1/12; B41C 1/055; B41C 1/10

(52) U.S. Cl. CPC B41N 1/12; B41C 1/055; G03F 7/033; B41C 1/1016; B41C 1/1025

(57) ABSTRACT

Provided are a printing plate precursor including a support, a layer containing a polymer on a printing surface side on the support, and a layer containing tabular particles on a non-printing surface side opposite to the layer containing a polymer in a state of sandwiching the support therebetween, and a printing plate precursor laminate which is obtained by laminating a plurality of the printing plate precursors, wherein the printing plate precursor laminate is formed such that an outermost layer on a surface where the layer containing the polymer is provided and an outermost layer on a surface where the layer containing the tabular particles is provided are laminated by being brought into direct contact with each other.

### CROSS REFERENCE TO RELATED APPLICATION

This is a continuation of International Application No. PCT/JP2018/032508 filed on Aug. 31, 2018, and claims priority from Japanese Patent Application No. 2017-167854 filed on Aug. 31, 2017, the entire disclosure of which is incorporated herein by reference.

### BACKGROUND OF THE INVENTION

### 1. Field of the Invention

The present invention relates to a printing plate precursor including a planographic printing plate precursor and a key plate precursor, and a printing plate precursor laminate.

### 2. Description of the Related Art

A planographic printing plate precursor is frequently stored and transported as a laminate formed by laminating a plurality of sheets thereof. In this laminate, interleaving paper is typically inserted into the space between planographic printing plate precursors for the purpose of preventing dislocation in stacking of planographic printing plate precursors, preventing adhesion between planographic printing plate precursors, and preventing scratches on a surface of a planographic printing plate precursor on a recording layer side. However, in a case where interleaving paper is used, problems of cost increase, a disposal treatment, and the like may occur, and thus the interleaving paper needs to be removed before an exposure step. Therefore, this may also result in risk of occurrence of a load on a plate-making step and occurrence of interleaving paper peeling failure. Further, at the time of removing the interleaving paper, it is necessary to give consideration so that the surface of the planographic printing plate precursor on the recording layer side is not damaged. Accordingly, development of a planographic printing plate precursor that enables lamination without the interleaving paper has been required.

For example, a printing plate precursor including a support, a layer containing a polymer on one side of the support, and a layer contains metal oxides and fine particles obtained by hydrolyzing and polycondensing an organic metal compound or an inorganic metal compound on the other side of the support, in which the average particle diameter of the fine particles is 0.3 μm or greater and is greater than the thickness of the layer containing the metal oxides and the fine particles (WO2017/002641A); and an offset planographic printing plate provided with a back coat layer which is formed of an organic polymer material having a glass transition temperature (Tg) of 35° C. or higher and contains particles colored by a pigment have been known (JP2002-046363A).

### SUMMARY OF THE INVENTION

However, even in WO2017/002641A and JP2002-046363A, in a case where printing plate precursors each including a planographic printing plate precursor and a key plate precursor are laminated, there has been a demand for further improvement in scratches on rear surface layers of the printing plate precursors and peeling of the rear surface layers even without using interleaving paper.

An object of the present invention is to provide a printing plate precursor which is capable of preventing scratches on a rear surface layer and peeling of the rear surface layer even without interleaving paper in a case where printing plate precursors each including a planographic printing plate precursor and a key plate precursor are laminated. Further, another object of the present invention is to provide a laminate of the printing plate precursors.

The present invention includes the following configurations.

[1] A printing plate precursor comprising: a support; a layer containing a polymer on a printing surface side on the support; and a layer containing tabular particles on a non-printing surface side opposite to the layer containing a polymer in a state of sandwiching the support therebetween.

[2] The printing plate precursor according to [1], in which a thickness of each tabular particle is smaller than a thickness of the layer containing tabular particles.

[3] The printing plate precursor according to [1] or [2], in which the tabular particles contain a silicon atom and an oxygen atom.

[4] The printing plate precursor according to [3], in which the tabular particles containing a silicon atom and an oxygen atom are smectite, bentonite, or mica.

[5] The printing plate precursor according to any one of [1] to [4], in which the layer containing tabular particles contains a polymer or a metal oxide obtained by hydrolyzing and polycondensing an organic metal compound or an inorganic metal compound.

[6] The printing plate precursor according to any one of [1] to [5], in which the layer containing tabular particles further contains particles other than the tabular particles, and an average particle diameter of the particles other than the tabular particles is 0.1 μm or greater and is greater than a thickness of the layer containing tabular particles.

[7] The printing plate precursor according to [6], in which the particles other than the tabular particles are organic resin particles, inorganic particles, or organic-inorganic composite particles.

[8] The printing plate precursor according to any one of [1] to [7], in which an arithmetic average height Sa of the layer containing tabular particles is in a range of 0.1 to 20 μm.

[9] The printing plate precursor according to any one of [1] to [8], in which the layer containing a polymer is an image recording layer including an infrared absorbent, a polymerization initiator, a polymerizable compound, and a polymer compound having a particle shape.

[10] The printing plate precursor according to [9], in which the polymer compound having a particle shape contained in the image recording layer has a hydrophobic main chain and both of a constitutional unit (i) which contains a pendant-cyano group directly bonded to the hydrophobic main chain and a constitutional unit (ii) which contains a pendant group having a hydrophilic polyalkylene oxide segment.

[11] The printing plate precursor according to any one of [1] to [8], in which the layer containing a polymer includes an infrared absorbent and thermoplastic polymer particles.

[12] A printing plate precursor laminate which is obtained by laminating a plurality of the printing plate precursors according to any one of [1] to [11], in which the printing plate precursor laminate is formed such that an outermost layer on a surface where the layer containing a polymer is provided and an outermost layer on a surface where the layer containing tabular particles is provided are laminated by being brought into direct contact with each other.

According to the present invention, it is possible to provide a printing plate precursor which is capable of preventing scratches on a rear surface layer and peeling of the rear surface layer even without interleaving paper in a case where printing plate precursors each including a planographic printing plate precursor and a key plate precursor are laminated. Further, it is also possible to provide a laminate of the printing plate precursors.

### BRIEF DESCRIPTION OF THE DRAWINGS

FIG. 1 is a schematic view illustrating an anodizing device used for an anodizing treatment.

FIG. 2 is a side view illustrating the concept of a brush graining step used in a mechanical roughening treatment in production of an aluminum support.

FIG. 3 is a graph showing an example of an alternating waveform current waveform diagram used for an electrochemical roughening treatment in production of an aluminum support.

FIG. 4 is a side view illustrating an example of a radial type cell in an electrochemical roughening treatment carried out using an alternating current.

### DESCRIPTION OF THE PREFERRED EMBODIMENTS

Hereinafter, the present invention will be described in detail.

In the present specification, the term “printing plate precursor” includes a planographic printing plate precursor and a printing key plate precursor. Further, the term “printing plate” includes a planographic printing plate and a printing key plate which are produced by performing operations of exposure, development, and the like on the printing plate precursor as necessary. In a case of the printing key plate precursor, operations of exposure and development are not necessarily required.

A printing plate precursor according to the embodiment of the present invention is a printing plate precursor which includes a support, a layer containing a polymer on a printing surface side on the support, and a layer containing tabular particles on a non-printing surface side opposite to the layer containing a polymer in a state of sandwiching the support therebetween.

One feature of the printing plate precursor according to the embodiment of the present invention is that the planographic printing plate includes a layer containing tabular particles on a non-printing surface side opposite to the layer containing a polymer in a state of sandwiching the support therebetween.

[Layer Containing Tabular Particles]

The printing plate precursor according to the embodiment of the present invention includes a layer containing tabular particles (hereinafter, also referred to as a “back coat layer” or a “rear surface layer”) on a non-printing surface side (hereinafter, also simply referred to as a “non-printing surface side”) opposite to the layer containing a polymer in a state of sandwiching the support therebetween.

It is considered that since the printing plate precursor according to the embodiment of the present invention contains tabular particles of the back coat layer, the surface of the back coat layer becomes hard, and thus scratch and peeling of the rear surface layer can be prevented in a step of transporting and attaching a printing plate which has been transported and produced in a producing step of the printing plate precursor or a setter, vendor, or stocker plate-making step to a printing press.

The present invention includes an embodiment in which the back coat layer contains tabular particles and an embodiment in which the back coat layer contains tabular particles and particles other than the tabular particles. In both embodiments, the surface of the back coat layer becomes hard. Therefore, scratches to the rear surface layer and peeling of the rear surface layer can be prevented as described above.

(Tabular Particles)

As the tabular particles, optional particles can be used as long as the aspect ratio thereof is 5 or greater.

The aspect ratio thereof is preferably 10 or greater, more preferably 50 or greater, and particularly preferably 100 or greater.

Here, the aspect ratio is defined as a ratio of the long diameter to the thickness of a particle. As the aspect ratio increases, the effect to be obtained increases.

Specifically, the aspect ratio (Z) is represented by a relationship of “Z=L/a”. L represents a long diameter of a particle. L indicates a number average particle diameter of particles acquired according to a dynamic light scattering method carried out using a dynamic light scattering particle size distribution measuring device (manufactured by Horiba, Ltd., LB-500 type) while the particles are dispersed in a solvent.

a represents a unit thickness of a particle. The unit thickness a is a value which can be calculated by measuring a diffraction peak of a particle according to a powder X-ray diffraction method. The unit thickness a can be measured using a powder-ray diffraction device (manufactured by Rigaku Corporation, SmartLab SE).

(Thickness of Tabular Particle)

It is preferable that the thickness of each tabular particle having an aspect ratio of 5 or greater is smaller than the thickness of the layer containing tabular particles.

It is preferable that the thickness of each tabular particle is smaller than the thickness of the layer containing tabular particles from the viewpoint that the tabular particles are unlikely to fall off and contamination does not occur during the step.

The thickness of each tabular particle is not particularly limited, but is preferably 100 nm, more preferably 50 nm or less, and still more preferably 10 nm or less.

Further, the thickness of each tabular particle is expressed as the unit thickness (a) of the tabular particle.

(Composition of Tabular Particle)

Examples of the tabular particles include tabular particles that do not have silicon atoms and oxygen atoms such as graphite; and tabular particle having silicon atoms and oxygen atoms such as mica, bentonite containing montmorillonite as a main component, montmorillonite classified as smectite, beidellight, nontronite, saponite, hectorite, sauconite, stevensite, the vermiculite group, and the illite group, but the present invention is not limited thereto.

As the tabular particles, tabular particles having silicon atoms and oxygen atoms are preferable, and smectite, bentonite, or mica is more preferable.

Examples of the mica include the mica group such as natural mica represented by Formula: A(B,C)₂₋₅D₄O₁₀(OH,F,O)₂ [here, A represents any of K, Na, or Ca, B and C represent any of Fe(II), Fe(III), Mn, Al, Mg, or V, and D represents Si or Al] and synthetic mica.

Examples of the natural mica include muscovite, soda mica, phlogopite, biotite, and lepidolite. Examples of the synthetic mica include non-swelling mica such as fluorine phlogopite KMg₃(AlSi₃O₁₀)F₂ or potassium tetrasilicon mica KMg_{2.5}(Si₄O₁₀)F₂; and swelling mica such as Na tetrasilicic mica NaMg_{2.5}(Si₄O₁₀)F₂, Na or Li teniolite (Na,Li)Mg₂Li(Si₄O₁₀)F₂.

In the present invention, among examples of the mica, fluorine-based swelling mica is particularly useful. That is, the swelling synthetic mica has a laminated structure formed of a unit crystal lattice layer having a thickness of approximately 100 to 150 nm (10 to 15 Å), and the metal atom substitution in the lattice is significantly larger than that of any other viscosity mineral. As the result, the lattice layer becomes deficient in a positive charge, and cations such as Na⁺, Ca²⁺, and Mg²⁺ are adsorbed between layers in order to compensate for the deficiency. The cations interposed between these layers are referred to as exchangeable cations and exchanged for various cations. Particularly, in a case where the cations between the layers are Li or Na⁺, since the ionic radius is small, bonds between layered crystal lattices are weak and greatly swollen with water. Cleavage easily occurs at the time of application of a shear force in this state, and a stabilized sol is formed in water. The swelling synthetic mica has such a strong tendency and thus is useful in the present invention. Particularly, from the viewpoint that particles with a uniform quality are available, the swelling synthetic mica is preferably used.

Montmorillonite: Si₈(Al_{3.34}Mg_{0.66})O₂₀(OH)₄ contained in bentonite or smectite is a laminated structure formed of thin tabular crystals having a thickness of approximately 1 nm and a width of approximately 50 to 1000 nm. Cations such as Na⁺, Ca²⁺, K⁺, and Mg²⁺ are interposed between layers. Since montmorillonite having a large amount of Na⁺ ions in interlayer ions has a weak electrical attraction of unit layers resulting from the Na⁺ ions, in a case where the montmorillonite is dispersed in water, Na⁺ ions and water molecules are hydrated, the montmorillonite is swollen, and the unit layers are separated. Cleavage easily occurs at the time of application of a shear force in this state, and a stabilized sol is formed in water.

Interlayer cations of mica, bentonite, and smectite can be simply ion-exchanged for other cations. In a case where the cations are exchanged for cations such as quaternary ammonium ions, particles are unlikely to be dispersed in water. However, the particles have an affinity for an organic solvent and dispersed therein.

Specific examples of the mica, bentonite, and smectite include SOMASIF MEB-3 of mica (manufactured by Katakura Chikkarin Co., Ltd.), KUNIPIA-F, KUNIPIA-GS KUNIPIA-G4, or KUNIPIA-G10 of bentonite, and SUMECTON-SA, SUMECTON-ST, SUMECTON-SW, SUMECTON-SWN, or SUMECTON-SWF of smectite, MOISTNITE-U, MOISTNITE-S, or MOISTNITE-HC of bentonite (manufactured by Kunimine Industries Co., Ltd.).

As described above, interlayer cations of mica, bentonite, and smectite can be simply ion-exchanged for other cations. In a case where the cations are exchanged for cations such as quaternary ammonium ions, particles are unlikely to be dispersed in water. However, the particles have an affinity for an organic solvent and can be dispersed therein. Specific examples thereof include SOMASIF MAE, SOMASIF MTE, or SOMASIF MEE of organic mica (manufactured by Katakura Chikkarin Co., Ltd.), KUNIBIS-110, KUNIBIS-127, or MOISTNITE-WO of organic bentonite, and SUMECTON-SAN, SUMECTON-SAN-P, SUMECTON-STN, OR SUMECTON-SEN of organic smectite (manufactured by Kunimine Industries Co., Ltd.). Further, the types of organic solvents suitable for dispersion vary.

The content of the tabular particles in the layer containing tabular particles is preferably in a range of 1 to 1000 mg/m², more preferably in a range of 5 to 800 mg/m², and still more preferably in a range of 10 to 600 mg/m².

The tabular particles may be used alone or in combination of two or more kinds thereof.

It is preferable that the layer containing tabular particles contain a polymer or a metal oxide obtained by hydrolyzing and polycondensing an organic metal compound or an inorganic metal compound.

(Polymer)

It is preferable that the layer containing tabular particles contains a polymer. It is preferable that the layer containing tabular particles contains an organic polymer as a base polymer that forms the layer. A polymer that forms a uniformly coated-film and has high adhesiveness to the support is preferable.

Hereinafter, examples of the polymer which is preferably used as a base polymer are described below, but the present invention is not limited thereto.

Suitable examples thereof include polybutene, polybutadiene, polyamide, a polyester resin, polyurethane, polyurea, polyimide, polysiloxane, polycarbonate, an epoxy resin, chlorinated polyethylene, an aldehyde condensation resin of alkylphenols, polyvinyl chloride, polyvinylidene chloride, polystyrene, an acrylic resin, and copolymer resins thereof, hydroxy cellulose, polyvinyl alcohol, a polyvinyl acetal resin, a vinylidene chloride copolymer resin, a phenoxy resin, cellulose acetate, carboxy methyl cellulose, a novolac resin, and a pyrogallol acetone resin.

The content of the polymer with respect to the total solid content of the layer containing tabular particles is preferably in a range of 99.99% to 50% by mass, more preferably in a range of 99.9% to 60% by mass, and particularly preferably in a range of 99.5% to 70% by mass.

(Metal Oxide Obtained by Hydrolyzing and Polycondensing Organic Metal Compound or Inorganic Metal Compound)

It is preferable that the layer containing tabular particles contain a metal oxide obtained by hydrolyzing and polycondensing an organic metal compound or an inorganic metal compound.

It is preferable that the metal oxide (hereinafter, also simply referred to as a metal oxide) obtained by hydrolyzing and polycondensing the organic metal compound or the inorganic metal compound described above is a so-called sol-gel reaction solution obtained by hydrolyzing and polycondensing an organic metal compound or an inorganic metal compound in water and an organic solvent using a catalyst such as an acid or an alkali.

Examples of the organic metal compound or the inorganic metal compound include a metal alkoxide, a metal acetylacetonate, a metal acetate, a metal oxalate, a metal nitrate, a metal sulfate, a metal carbonate, a metal oxychloride, a metal chloride, and a condensate obtained by partially hydrolyzing and oligomerizing these.

The metal alkoxide is a compound represented by M(OR)ₙ (in the formula, M represents a metal element, R represents an alkyl group, and n represents the oxidation number of the metal element). Specific examples thereof include Si(OCH₃)₄, Si(OC₂H₅)₄, Si(OC₃H₇)₄, Si(OC₄H₉)₄, Al(OCH₃)₃, Al(OC₂H₅)₃, Al(OC₃H₇)₃, Al(OC₄H₉)₃, B(OCH₃)₃, B(OC₂H₅)₃, B(OC₃H₇)₃, B(OC₄H₉)₃, Ti(OCH₃)₄, Ti(OC₂H₅)₄, Ti(OC₃H₇)₄, Ti(OC₄H₉)₄, Zr(OCH₃)₄, Zr(OC₂H₅)₄, Zr(OC₃H₇)₄, and Zr(OC₄H₉)₄; and other examples thereof include alkoxides of atoms such as Ge, Li, Na, Fe, Ga, Mg, P, Sb, Sn, Ta, and V. In addition, monosubstituted silicon alkoxides such as CH₃Si(OCH₃)₃, C₂H₅Si(OCH₃)₃, CH₃Si(OC₂H₉)₃, and C₂H₅Si(OC₂H₅)₃ can be also used.

Among the organic metal compounds or the inorganic metal compounds, a metal alkoxide is preferable from the viewpoints of being rich in reactivity and easily generating a polymer from a metal-oxygen bond. Among the examples, alkoxide compounds of silicon such as Si(OCH₃)₄, Si(OC₂H₅)₄, Si(OC₃H₇)₄, and Si(OC₄H₉)₄ are particularly preferable from the viewpoints of low cost, availability, and excellent coatability of metal oxides obtained from these. Further, oligomers obtained by hydrolyzing and condensing these alkoxide compounds of silicon are also preferable, and examples thereof include an ethyl silicate oligomer of an average pentamer oligomer which contains approximately 40% by mass of SiO₂.

The organic metal compound or the inorganic metal compound can be used alone or in combination of two or more kinds thereof.

Further, it is also preferable that a so-called silane coupling agent obtained by substituting one or two alkoxy groups in a tetraalkoxy compound of the silicon with an alkyl group or a group having reactivity is used in combination with a metal alkoxide. Examples of the silane coupling agent include a silane coupling agent obtained by substituting one or two alkoxy groups in a tetraalkoxy compound of the silicon with a hydrophobic substituent such as a long chain alkyl group having 4 to 20 carbon atoms or a fluorine-substituted alkyl group. Among these, a silane coupling agent containing a fluorine-substituted alkyl group is particularly preferable. Specific examples of the silane coupling agent include CF₃CH₂CH₂Si(OCH₃)₃, CF₃CF₂CH₂CH₂Si(OCH₃)₃, and CF₃CH₂CH₂Si(OC₂H₅)₃, and examples of the commercially available products thereof include LS-1090 (manufactured by Shin-Etsu Chemical Co., Ltd.). The content of the silane coupling agent is preferably in a range of 5% to 90% by mass and more preferably in a range of 10% to 80% by mass with respect to the total solid content of the back coat layer.

As a catalyst useful for forming a sol-gel reaction solution, an organic or inorganic acid and an alkali are used. Examples thereof include an inorganic acid such as hydrochloric acid, sulfuric acid, sulfurous acid, nitric acid, nitrous acid, hydrofluoric acid, phosphoric acid, or phosphorous acid; an organic acid such as formic acid, acetic acid, propionic acid, butyric acid, glycolic acid, chloroacetic acid, dichloroacetic acid, trichloroacetic acid, fluoroacetic acid, bromoacetic acid, methoxyacetic acid, oxaloacetic acid, citric acid, oxalic acid, succinic acid, malic acid, tartaric acid, fumaric acid, maleic acid, malonic acid, ascorbic acid, benzoic acid, substituted benzoic acid such as 3,4-dimethoxybenzoic acid, phenoxyacetic acid, phthalic acid, picric acid, nicotinic acid, picolinic acid, pyrazine, pyrazole, dipicolinic acid, adipic acid, p-toluic acid, terephthalic acid, 1,4-cyclohexene-2,2-dicarboxylic acid, erucic acid, lauric acid, or n-undecanoic acid; and an alkali such as a hydroxide of an alkali metal or an alkaline earth metal, ammonia, ethanolamine, diethanolamine, or triethanolamine.

Other preferred examples of the catalyst include sulfonic acids, sulfinic acids, alkylsulfuric acids, phosphonic acids, and phosphoric esters. Specifically, an organic acid such as p-toluenesulfonic acid, dodecylbenzenesulfonic acid, p-toluenesulfinic acid, ethylsulfuric acid, phenylphosphonic acid, phenylphosphinic acid, phenyl phosphate, or diphenyl phosphate can also be used.

The catalyst can be used alone or in combination of two or more kinds thereof. The amount of the catalyst is preferably in a range of 0.001% to 10% by mass and more preferably in a range of 0.05% to 5% by mass with respect to the amount of the metal compound in a raw material. In a case where the amount of the catalyst is in the above-described range, the initiation of the sol-gel reaction is satisfactorily performed, a rapid reaction is suppressed, and generation of non-uniform sol-gel particles can be prevented.

An appropriate amount of water is required to initiate the sol-gel reaction. The amount of water to be added is preferably in a range of 0.05 to 50 molar times and preferably in a range of 0.5 to 30 molar times of the amount to be required for completely hydrolyzing the metal compound in the raw material. In a case where the amount of water is in the above-described range, the hydrolysis proceeds satisfactorily.

A solvent is added to the sol-gel reaction solution. The solvent is not limited as long as the solvent dissolves the metal compound in the raw material and dissolves or disperses the sol-gel particles generated by the reaction, and examples thereof include lower alcohols such as methanol, ethanol, propanol, and butanol; and ketones such as acetone, methyl ethyl ketone, and diethyl ketone. Further, mono- or dialkyl ether or acetic acid ester of glycols such as ethylene glycol, diethylene glycol, triethylene glycol, propylene glycol, or dipropylene glycol can be used for the purpose of improving the quality of the coating surface of the back coat layer. As the solvent, lower alcohols which can be mixed with water are preferable. The concentration of the sol-gel reaction solution is adjusted to be suitable for coating using a solvent, but the hydrolysis reaction is unlikely to proceed because the raw material is diluted in a case where the total amount of solvent is added to the reaction solution from the beginning. Therefore, a method of adding a part of the solvent to the sol-gel reaction solution and then adding the remaining solvent after the reaction proceeds is preferable.

(Other Components)

For the purpose of imparting the flexibility, adjusting the slipperiness, and improving the coating surface state, a plasticizer, a surfactant, and other additives can be added to the layer containing tabular particles as necessary within a range where the effects of the present invention are not impaired.

Examples of effective plasticizers include phthalic acid esters such as dimethyl phthalate, diethyl phthalate, dibutyl phthalate, diisobutyl phthalate, dioctyl phthalate, octyl capryl phthalate, dicyclohexyl phthalate, ditridecyl phthalate, butyl benzyl phthalate, diisodecyl phthalate, and diallyl phthalate; glycol esters such as dimethyl glycol phthalate, ethyl phthalyl ethyl glycolate, methyl phthalyl ethyl glycolate, butyl phthalyl butyl glycolate, and triethylene glycol dicaprylic acid ester; phosphoric acid esters such as tricresyl phosphate and triphenyl phosphate; aliphatic dibasic acid esters such as diisobutyl adipate, dioctyl adipate, dimethyl sebacate, dibutyl sebacate, dioctyl azelate, dibutyl maleate; polyglycidyl methacrylate, triethyl citrate, glycerin triacetyl ester, and butyl laurate.

The amount of the plasticizer to be added to the layer containing tabular particles varies depending on the type of the polymer used in the layer containing tabular particles, but it is preferable that the plasticizer is added thereto within a range where the glass transition temperature thereof does not reach 60° C. or lower.

Examples of the surfactant include anionic surfactants, cationic surfactants, nonionic surfactants, and amphoteric surfactants. Specific examples thereof include nonionic surfactants such as polyoxyethylene alkyl ethers, polyoxyethylene alkyl phenyl ethers, polyoxyethylene polystyryl phenyl ethers, polyoxyethylene polyoxypropylene alkyl ethers, glycerin fatty acid partial esters, sorbitan fatty acid partial esters, pentaerythritol fatty acid partial esters, propylene glycol monofatty acid esters, sucrose fatty acid partial esters, polyoxyethylene sorbital fatty acid partial esters, polyoxyethylene sorbitol fatty acid partial esters, polyethylene glycol fatty acid esters, polyglycerin fatty acid partial esters, polyoxyethylenated castor oils, polyoxyethylene glycerin fatty acid partial esters, fatty acid diethanol amides, N,N-bis-2-hydroxyalkylamines, polyoxyethylene alkylamine, triethanolamine fatty acid ester, and trialkylamine oxide; anionic surfactants such as fatty acid salts, abietates, hydroxyalkane sulfonates, alkane sulfonates, dialkylsulfosuccinic acid ester salts, linear alkylbenzene sulfonates, branched alkylbenzene sulfonates, alkyl naphthalene sulfonates, alkylphenoxy polyoxyethylene propyl sulfonates,

polyoxyethylene alkylsulfophenyl ether salts, N-methyl-N-oleyl taurine sodium salt, N-alkylsulfusuccinic acid monoamide disodium salt, petroleum sulfonates, sulfated tallow oil, sulfuric acid esters of fatty acid alkyl ester, alkyl sulfuric acid ester salts, polyoxyethylene alkyl ether sulfuric acid ester salts, fatty acid monoglyceride sulfuric acid ester salts, polyoxyethylene alkyl phenyl ether sulfuric acid ester salts, polyoxyethylene styryl phenyl ether sulfuric acid ester salts, alkyl phorphoric acid ester salts, polyoxyethylene alkyl ether phosphoric acid ester salts, polyoxyethylene alkyl phenyl ether phosphoric acid ester salts, partially saponified products of a styrene/maleic acid anhydride copolymer, partially saponified products of an olefin/maleic acid anhydride copolymer, and naphthalenesulfonic acid salt formalin condensates; cationic surfactants such as alkylamine salts, quaternary ammonium salts, polyoxyethylene alkylamine salts, and polyethylene polyamine derivatives; and amphoteric surfactants such as carboxy betaines, aminocarboxylic acids, sulfobetaines, aminosulfuric acid esters, and imidazolines.

Among these surfactants exemplified above, polyoxyethylene can also be read as polyoxyalkylene such as polyoxyethylene, polyoxypropylene, or polyoxybutylene and surfactants thereof are also included.

As the surfactant, a fluorine-based surfactant containing a perfluoroalkyl group in a molecule is more preferable. Examples of the fluorine-based surfactant include anionic surfactants such as a perfluoroalkyl carboxylate, a perfluoroalkyl sulfonate, and perfluoroalkyl phosphoric acid ester; amphoteric surfactants such as perfluoroalkylbetaine; cationic surfactants such as a perfluoroalkyl trimethyl ammonium salt; and nonionic surfactants such as perfluoroalkylamine oxide, a perfluoroalkylethylene oxide adduct, an oligomer containing a perfluoroalkyl group and a hydrophilic group, an oligomer containing a perfluoroalkyl group and a lipophilic group, a perfluoroalkyl group, an oligomer containing a hydrophilic group and a lipophilic group, and urethane containing a perfluoroalkyl group and a lipophilic group.

The surfactant can be used alone or in combination of two or more kinds thereof, and the content of the surfactant with respect to the total solid content of the layer containing tabular particles is preferably in a range of 0.001% to 10% by mass and more preferably in a range of 0.01% to 5% by mass.

In a case where the layer containing tabular particles contains a polymer, a dye for coloring, a silane coupling agent for improving the adhesiveness to an aluminum support, a diazo resin formed of a diazonium salt, organic phosphonic acid, organic phosphoric acid, a cationic polymer, a wax typically used as a slip agent, a higher fatty acid, higher fatty acid amide, a silicone compound formed of dimethylsiloxane, modified dimethylsiloxane, or polyethylene powder can be appropriately added to the layer.

The coating amount of the layer containing tabular particles is preferably in a range of 0.01 to 30 g/m², more preferably in a range of 0.1 to 10 g/m², and particularly preferably in a range of 0.2 to 5 g/m².

(Particles Other than Tabular Particles)

It is preferable that the layer containing tabular particles further contain particles other than the tabular particles (hereinafter, also referred to as “non-tabular particles”).

It is preferable that the layer contains non-tabular particles from the viewpoint that scratches to the rear surface layer and peeling of the rear surface layer are unlikely to occur.

Here, optional particles can be used as the non-tabular particles as long as the particles do not belong to the range of the tabular particles described above.

That is, the aspect ratio of the particles other than the tabular particles is less than 5 and typically 1 or greater. The aspect ratio thereof is preferably in a range of 1 to 3 and more preferably 1 or 2.

As the particles other than the tabular particles, organic resin particles, inorganic particles, organic-inorganic composite particles, or the like can be used.

Preferred examples of the organic resin particles include particles formed of synthetic resins such as poly(meth)acrylic acid esters, polystyrene and a derivative thereof, polyamides, polyimides, polyolefins such as low-density polyethylene, high-density polyethylene, and polypropylene, polyurethane, polyurea, and polyesters; and particles formed of natural polymers such as chitin, chitosan, cellulose, cross-linked starch, and cross-linked cellulose.

Among these, synthetic resin particles have advantages of easily controlling the particle size and easily controlling desired surface characteristics through surface modification.

Among examples of the method of producing organic resin particles, a method of granulation according to a crushing method can be used in a case of a relatively hard resin such as PMMA, but a method of synthesizing particles according to an emulsification and suspension polymerization method is preferably employed from the viewpoints of ease of controlling the particle diameter and the precision.

The method of producing organic resin particles is specifically described in “Ultrafine Particles and Materials” edited by Materials Science Society of Japan, published by SHOKABO Co., Ltd., in 1993 and “Manufacturing & Application of Microspheres & Powders” supervised by Haruma Kawaguchi, published by CMC Publishing Co., Ltd., in 2005.

The organic resin particles are also available as commercially available products, and examples thereof include acrylic particles such as ART PEARL J-6PF (manufactured by Negami Chemical Industrial Co., Ltd.); cross-linked acrylic resins such as MX-300, MX-500, MX-1000, MX-1500H, MR-2HG MR-7HG MR-10HG MR-3GSN, MR-5GSN, MR-7G MR-10G MR-5C, and MR-7GC; styryl resins such as SX-350H and SX-500H (all manufactured by Soken Chemical & Engineering Co., Ltd.); acrylic resins such as MBX-5, MBX-8, MBX-12, MBX-15, MBX-20, MB20X-5, MB30X-5, MB30X-8, MB30X-20, SBX-6, SBX-8, SBX-12, and SBX-17 (all manufactured by Sekisui Plastics Co., Ltd.); and polyolefin resins such as CHEMIPEARL W100, W200, W300, W308, W310, W400, W401, W405, W410, W500, WF640, W700, W800, W900, W950, and WP100 (all manufactured by Mitsui Chemicals, Inc.).

Examples of the inorganic particles include silica, alumina, zirconia, titania, carbon black, graphite, TiO₂, BaSO₄, ZnS, MgCO₃, CaCO₃, ZnO, CaO, WS₂, MoS₂, MgO, SnO₂, Al₂O₃, α-Fe₂O₃, α-FeOOH, SiC, CeO₂, BN, SiN, MoC, BC, WC, titanium carbide, corundum, artificial diamond, garnet, silica stone, tripolite, diatomaceous earth, and dolomite.

The organic-inorganic composite particles are not particularly limited, but organic resin particles which have been subjected to inorganic surface modification or inorganic particles which have been subjected to organic surface modification are preferable.

Hereinafter, the organic resin particles which have been subjected to inorganic surface modification will be described in detail using organic resin particles coated with silica (hereinafter, also referred to as “silica-coated organic resin particles”) as an example, and the organic resin particles which have been subjected to inorganic surface modification in the present invention are not limited thereto.

(Silica-Coated Organic Resin Particles)

The silica-coated organic resin particle is a particle which is formed of an organic resin and has a surface coated with silica. It is preferable that the organic resin particles constituting a core are not softened or become sticky due to the moisture in the air or the temperature.

Examples of the organic resin constituting the organic resin particles of the silica-coated organic resin particles include a polyacrylic resin, a polyurethane-based resin, a polystyrene-based resin, a polyester-based resin, an epoxy-based resin, a phenol resin, and a melamine resin.

As a material forming the silica layer covering the surface of the silica-coated organic resin particles, a compound containing an alkoxysilyl group such as a condensate of an alkoxysiloxane-based compound, particularly, a siloxane-based material, and specifically, silica particles such as silica sol, colloidal silica, and silica nanoparticles are preferably exemplified.

The configuration of the silica-coated organic resin particles may be a configuration in which a silica particle adheres to the surface of an organic resin particle as a solid component or a configuration in which a siloxane-based compound layer is formed on the surface of an organic resin particle by performing a condensation reaction on an alkoxysiloxane-based compound.

Silica does not necessarily cover the entire surface of the organic resin particles, and the effects of the present invention can be easily obtained in a case where the surface thereof is coated with at least 0.5% by mass or greater of silica with respect to the mass of the organic resin particles. In other words, in a case where silica is present on at least a part of the surface of the organic resin particles, improvement in affinity of surface of organic particles for a coexisting water-soluble polymer such as PVA is achieved, falling off of the particles is suppressed even in a case where external stress is applied thereto, and excellent scratch resistance and adhesion resistance can be maintained. Accordingly, the expression “coated with silica” in the present invention includes a state in which silica is present on at least a part of the surface of the organic resin particles as described above.

The state of the surface being coated with silica can be confirmed by morphological observation using a scanning electron microscope (SEM) or the like. Further, the coating amount of silica can be confirmed by detecting Si atoms through elemental analysis such as fluorescent X-ray analysis and calculating the amount of silica present therein.

A method of producing silica-coated organic resin particles is not particularly limited, and examples thereof include a method of forming a silica surface coating layer simultaneously with formation of organic resin particles by allowing silica particles or a silica precursor compound to coexist with a monomer component which becomes the raw material of the organic resin particles; and a method of forming organic resin particles, physically adhering silica particles to the surface of the organic resin particles, and then fixing the silica particles thereto.

Hereinafter, an example of the method of producing the silica-coated organic resin particles will be described. First, silica and a raw material resin (more specifically, a raw material resin such as a monomer capable of suspension polymerization, a pre-polymer capable of suspension cross-linking, or a resin liquid, constituting the above-described organic resin) are added to water containing a suspension stabilizer appropriately selected from a water-soluble polymer such as polyvinyl alcohol, methyl cellulose, or polyacrylic acid and an inorganic suspending agent such as calcium phosphate or calcium carbonate, and stirred and mixed with the water to prepare a suspension in which silica and a raw material resin are dispersed. At this time, a suspension having a target particle diameter can be formed by adjusting the type, the concentration, and the stirring rotation speed of the suspension stabilizer. Next, the suspension is heated to initiate the reaction, and resin particles are generated by performing suspension polymerization or suspension cross-linking of the resin raw material. At this time, the coexisting silica is fixed to the resin particles cured by the polymerization or the cross-linking reaction, particularly, the vicinity of the surface of the resin particles due to the physical properties thereof. Thereafter, the suspension is subjected to solid-liquid separation, the suspension stabilizer adhering to the particles is removed by washing, and the particles are dried. In this manner, silica-coated organic resin particles to which silica is fixed and which have a desired particle diameter and a substantially spherical shape can be obtained.

Silica-coated organic resin particles having a desired particle diameter may be obtained by controlling the conditions during the suspension polymerization as described above, or the suspension cross-linking or silica-coated organic resin particles may be generated without strictly controlling the conditions and then silica-coated organic particles having a desired size is obtained by a mesh filtration method or the like.

In regard to the amount of the raw material to be added to the mixture during the production of the silica-coated organic particles according to the above-described method, in a case where the total amount of the raw material resin and the silica is 100 parts by weight, first, 0.1 to 20 parts by weight of the suspension stabilizer is added to 200 to 800 parts by weight of water serving as a dispersion medium, and sufficiently dissolved or dispersed therein, 100 parts by weight of a mixture of the raw material resin and the silica is put into the solution, the solution is stirred while the stirring speed is adjusted such that the dispersed particles have a predetermined particle size, the solution temperature is increased to 30° C. to 90° C. after the adjustment of the particle size, and then a reaction is performed for 1 to 8 hours.

The above-described method is merely an example of the method of producing silica-coated organic resin particles and silica-coated organic resin particles obtained by the methods specifically described in JP2002-327036A, JP2002-173410A, JP2004-307837A, JP2006-038246A, and the like can be also suitably used in the present invention.

Further, the silica-coated organic resin particles are also available as commercially available products, and specific examples of silica-melamine composite fine particles include OPTBEADS 2000M, OPTBEADS 3500M, OPTBEADS 6500M, OPTBEADS 10500M, OPTBEADS 3500S, and OPTBEADS 6500S (all manufactured by Nissan Chemical Industries, Ltd.). Specific examples of silica-acrylic composite particles include ART PEARL G-200 transparent, ART PEARL G-400 transparent, ART PEARL G-800 transparent, ART PEARL GR-400 transparent, ART PEARL GR-600 transparent, ART PEARL GR-800 transparent, ART PEARL J-4P, J-5P, J-7P, J-3PY, J-4PY, and J-7PY (all manufactured by Negami Chemical Industrial Co., Ltd.). Specific examples of silica-urethane composite particles include ART PEARL C-400 transparent, C-800 transparent, P-800T, U-600T, U-800T, CF-600T, CF800T (all manufactured by Negami Chemical Industrial Co., Ltd.) and DYNAMIC BEADS CN5070D and DANPLACOAT THU (both manufactured by Dainichiseika Color & Chemicals Mfg. Co., Ltd.).

Hereinbefore, the organic resin particles used for the back coat layer of the present invention have been described using the example of the silica-coated organic resin particles, and the same applies to organic resin particles coated with alumina, titania, or zirconia by using alumina, titania, or zirconia in place of silica.

Further, inorganic particles which have been subjected to organic surface modification can also be used. Examples of the commercially available products thereof include, as methyl group-modified silica particles, TOSPEARL 120, TOSPEARL 130, TOSPEARL 145, TOSPEARL 2000B, TOSPEARL 1110, and TOSPEARL 240 (manufactured by Momentive Performance Materials Japan LLC).

It is preferable that the average particle diameter of the non-tabular particles is greater than the thickness of the layer (back coat layer) containing tabular particles. It is preferable that the average particle diameter of the non-tabular particles is greater than the thickness of the back coat layer by 0.1 μm or greater.

The average particle diameter of the non-tabular particles is preferably 0.1 μm or greater, more preferably in a range of 0.3 to 30 μm, still more preferably in a range of 0.5 to 15 μm, and particularly preferably in a range of 1 to 10 μm. In a case where the average particle diameter thereof is in the above-described range, a spacer function can be sufficiently exhibited, the particles are easily fixed to the back coat layer, and an excellent holding function with respect to contact stress from the outside is exhibited.

In the present invention, the average particle diameter of the non-tabular particles indicates the volume average particle diameter which has been typically used, and such a volume average particle diameter can be measured using a laser diffraction scattering particle size distribution meter. Examples of the measuring device include a particle size distribution measuring device “Microtrac MT-3300II” (manufactured by Nikkiso Co., Ltd.).

In a case where the layer containing tabular particles further contains the particles other than the tabular particles, it is preferable that the average particle diameter of the particles other than the tabular particles is 0.1 μm or greater and is greater than the thickness of the layer containing tabular particles.

The content of the non-tabular particles in the layer containing tabular particles is preferably in a range of 5 to 1000 mg/m², more preferably in a range of 10 to 500 mg/m², and still more preferably in a range of 20 to 300 mg/m².

The thickness of the layer containing tabular particles is preferably in a range of 0.01 to 30 Gm, more preferably in a range of 0.1 to 10 Gm, and still more preferably in a range of 0.2 to 5 μm. Here, it is preferable that the thickness of the back coat layer is smaller than the average particle diameter of the non-tabular particles which can be contained in the back coat layer.

The thickness of the back coat layer can be measured by coating a smooth aluminum support which has not been subjected to a surface treatment with a back coat layer coating solution, observing the cross section thereof using a scanning electron microscope (SEM), measuring the film thicknesses of five sites in smooth regions where particles are not present, and acquiring the average value of the obtained thicknesses.

The arithmetic average height Sa of the layer containing tabular particles is preferably in a range of 0.1 to 20 μm, more preferably in a range of 0.3 to 15 μm, and still more preferably in a range of 0.5 to 10 μm.

In the present invention, the arithmetic average height Sa is measured in conformity with the method described in ISO 25178. That is, three or more sites are selected from the same sample using MICROMAP MM3200-M100 (manufactured by Mitsubishi Chemical Systems, Inc.), the heights thereof are measured, and the average value thereof is set as the arithmetic average height Sa. As the measurement range, a range with a size of 1 cm×1 cm randomly selected from the sample surface is measured.

The back coat layer can be produced by adjusting the metal oxide and fine particles and a back coat layer coating solution containing other additives as necessary, coating the support with the back coat layer coating solution, and drying the support. The support is coated with the back coat layer according to a known coating method such as bar coater coating. The support is preferably dried at 50° C. to 200° C. for approximately 10 seconds to 5 minutes.

[Printing Plate Precursor]

A printing plate precursor according to the embodiment of the present invention includes a layer containing a polymer on a printing surface side.

Hereinafter, a planographic printing plate precursor which is a preferred embodiment of the printing plate precursor will be described.

[Planographic Printing Plate Precursor]

The planographic printing plate precursor of the present invention has an image recording layer on a support. The image recording layer of the planographic printing plate precursor corresponds to the layer containing a polymer in the printing plate precursor. The image recording layer of the planographic printing plate precursor may have an undercoat layer between the support and the image recording layer and a protective layer on the image recording layer as necessary.

[Image Recording Layer]

According to one preferred embodiment, the image recording layer is an image recording layer of which a non-image area is removed by at least one of acidic to alkaline dampening water or printing ink on a printing press.

According to one embodiment, the image recording layer is an image recording layer (hereinafter, also referred to as an image recording layer A) that contains an infrared absorbent, a polymerization initiator, a polymerizable compound, and a binder polymer.

According to another embodiment, the image recording layer is an image recording layer (hereinafter, also referred to as an image recording layer B) that contains an infrared absorbent, a polymerization initiator, a polymerizable compound, and a polymer compound having a particle shape.

According to still another embodiment, the image recording layer is an image recording layer (hereinafter, also referred to as an image recording layer C) that contains an infrared absorbent and thermoplastic polymer particles.

(Image Recording Layer A)

The image recording layer A contains an infrared absorbent, a polymerization initiator, a polymerizable compound, and a binder polymer. Hereinafter, the constituent components of the image recording layer A will be described.

<Infrared Absorbent>

An infrared absorbent has a function of converting absorbed infrared rays into heat, a function of electron transfer to a polymerization initiator described below through excitation by infrared rays, and/or a function of energy transfer thereto. As the infrared absorbent used in the present invention, a dye or a pigment having maximum absorption at a wavelength of 760 to 1,200 nm is preferable and a dye is more preferable.

As the dye, dyes described in paragraphs 0082 to 0088 of JP2014-104631A can be used.

The particle diameter of the pigment is preferably in a range of 0.01 to 1 μm and more preferably in a range of 0.01 to 0.5 μm. A known dispersion technique used to produce inks or toners can be used for dispersion of the pigment. The details are described in “Latest Pigment Application Technology” (CMC Publishing Co., Ltd., published in 1986) and the like.

The infrared absorbent may be used alone or in combination of two or more kinds thereof.

The content of the infrared absorbent is preferably in a range of 0.05 to 30 parts by mass, more preferably in a range of 0.1 to 20 parts by mass, and particularly preferably in a range of 0.2 to 10 parts by mass with respect to 100 parts by mass of the total solid content of the image recording layer.

<Polymerization Initiator>

The polymerization initiator indicates a compound that initiates and promotes polymerization of a polymerizable compound. As the polymerization initiator, a known thermal polymerization initiator, a compound having a bond with small bond dissociation energy, or a photopolymerization initiator can be used. Specifically, radical polymerization initiators described in paragraphs 0092 to 0106 of JP2014-104631A can be used.

Preferred examples of compounds in the polymerization initiators include onium salts such as iodonium salts and sulfonium salts. Specific preferred examples of the compounds in each of the salts are the compounds described in paragraphs 0104 to 0106 of JP2014-104631A.

The content of the polymerization initiator is preferably in a range of 0.1% to 50% by mass, more preferably in a range of 0.5% to 30% by mass, and particularly preferably in a range of 0.8% to 20% by mass with respect to the total solid content of the image recording layer. In a case where the content thereof is in the above-described range, improved sensitivity and improved stain resistance of a non-image area at the time of printing are obtained.

<Polymerizable Compound>

A polymerizable compound is an addition polymerizable compound having at least one ethylenically unsaturated double bond and is selected from compounds having at least one and preferably two or more terminal ethylenically unsaturated bonds. These have chemical forms such as a monomer, a pre-polymer, that is, a dimer, a trimer, an oligomer, and a mixture of these. Specifically, polymerizable compounds described in paragraphs 0109 to 0113 of JP2014-104631A can be used.

Among the examples described above, from the viewpoint that the balance between hydrophilicity associated with on-press developability and polymerization ability associated with printing durability is excellent, isocyanuric acid ethylene oxide-modified acrylates such as tris(acryloyloxyethyl) isocyanurate and bis(acryloyloxyethyl)hydroxyethyl isocyanurate are particularly preferable.

The details of the structures of these polymerizable compounds, whether to be used alone or in combination, and the usage method such as the addition amount can be arbitrarily set according to the final performance design of a planographic printing plate precursor. The content of the above-described polymerizable compound to be used is preferably in a range of 5% to 75% by mass, more preferably in a range of 10% to 70% by mass, and particularly preferably in a range of 15% to 60% by mass with respect to the total solid content of the image recording layer.

<Binder Polymer>

A binder polymer can be mainly used to improve the film hardness of the image recording layer. As the binder polymer, known polymers of the related art can be used and polymers having coated-film properties are preferable. Among examples thereof, an acrylic resin, a polyvinyl acetal resin, and a polyurethane resin are preferable.

Preferred examples of the binder polymers include polymers having a cross-linking functional group in the main chain or side chain, preferably in the side chain, for improving coated-film hardness of an image area as described in JP2008-195018A. Cross-linking occurs between polymer molecules by a cross-linking group so that curing is promoted.

Preferred examples of the cross-linking functional group include an ethylenically unsaturated group such as a (meth)acryl group, a vinyl group, an allyl group, or a styryl group and an epoxy group, and the cross-linking functional group can be introduced into a polymer by a polymer reaction or copolymerization. For example, a reaction between an acrylic polymer having a carboxy group in the side chain thereof or polyurethane and glycidyl methacrylate or a reaction between a polymer having an epoxy group and ethylenically unsaturated group-containing carboxylic acid such as methacrylic acid can be used.

The content of the cross-linking group in the binder polymer is preferably in a range of 0.1 to 10.0 mmol, more preferably in a range of 0.25 to 7.0 mmol, and particularly preferably in a range of 0.5 to 5.5 mmol with respect to 1 g of the binder polymer.

Moreover, it is preferable that the binder polymer includes a hydrophilic group. The hydrophilic group contributes to imparting on-press developability to the image recording layer. Particularly, in the coexistence of a cross-linking group and a hydrophilic group, both of printing durability and on-press developability can be achieved.

Examples of the hydrophilic group include a hydroxy group, a carboxy group, an alkylene oxide structure, an amino group, an ammonium group, an amide group, a sulfo group, and a phosphoric acid group. Among these, an alkylene oxide structure having 1 to 9 alkylene oxide units having 2 or 3 carbon atoms is preferable. A monomer having a hydrophilic group may be copolymerized in order to impart a hydrophilic group to a binder polymer.

In addition, in order to control the impressing property, a lipophilic group such as an alkyl group, an aryl group, an aralkyl group, or an alkenyl group can be introduced into the binder polymer. For example, a lipophilic group-containing monomer such as methacrylic acid alkyl ester may be copolymerized.

The mass average molecular weight (Mw) of the binder polymer is preferably 2,000 or greater, more preferably 5,000 or greater, and still more preferably in a range of 10,000 to 300,000.

The content of the binder polymer is practically in a range of 3% to 90% by mass, preferably in a range of 5% to 80% by mass, and more preferably in a range of 10% to 70% by mass with respect to the total solid content of the image recording layer.

As a preferred example of the binder polymer, a polymer compound having a polyoxyalkylene chain in the side chain is exemplified. In a case where the image recording layer contains a polymer compound having a polyoxyalkylene chain in the side chain (hereinafter, also referred to as a POA chain-containing polymer compound), permeability of dampening water is promoted and on-press developability is improved.

Examples of the resin constituting the main chain of the POA chain-containing polymer compound include an acrylic resin, a polyvinyl acetal resin, a polyurethane resin, a polyurea resin, a polyimide resin, a polyamide resin, an epoxy resin, a methacrylic resin, a polystyrene resin, a novolac type phenolic resin, a polyester resin, synthetic rubber, and natural rubber. Among these, an acrylic resin is particularly preferable.

The POA chain-containing polymer compound does not substantially contain a perfluoroalkyl group. The expression “does not substantially contain a perfluoroalkyl group” means that the mass ratio of a fluorine atom present as a perfluoroalkyl group in a polymer compound is less than 0.5% by mass, and it is preferable that the polymer compound does not contain a fluorine atom. The mass ratio of the fluorine atom is measured by an elemental analysis method.

In addition, the “perfluoroalkyl group” is a group in which all hydrogen atoms of the alkyl group are substituted with fluorine atoms.

As alkyleneoxide (oxyalkylene) in a polyoxyalkylene chain, alkylene oxide having 2 to 6 carbon atoms is preferable, ethyleneoxide (oxyethylene) or propyleneoxide (oxypropylene) is more preferable, and ethyleneoxide is still more preferable.

The repetition number of the alkyleneoxide in a polyoxyalkylene chain, that is, a poly(alkyleneoxide) moiety is preferably in a range of 2 to 50 and more preferably in a range of 4 to 25.

In a case where the repetition number of the alkyleneoxide is 2 or greater, the permeability of dampening water is sufficiently improved. Further, from the viewpoint that printing durability is not degraded due to abrasion, it is preferable that the repetition number thereof is 50 or less.

As the poly(alkyleneoxide) moiety, structures described in paragraphs 0060 to 0062 of JP2014-104631A are preferable.

The POA chain-containing polymer compound may have cross-linking properties in order to improve coated-film hardness of an image area. Examples of the POA chain-containing polymer compounds having cross-linking properties are described in paragraphs 0063 to 0072 of JP2014-104631A.

The proportion of repeating units having a poly(alkyleneoxide) moiety in the total repeating units constituting the POA chain-containing polymer compound is not particularly limited, but is preferably in a range of 0.5 to 80 mol % and more preferably in a range of 0.5 to 50 mol %. Specific examples of the POA chain-containing polymer compounds are described in paragraphs 0075 and 0076 of JP2014-104631A.

As the POA chain-containing polymer compound, hydrophilic polymer compounds such as polyacrylic acid and polyvinyl alcohol described in JP2008-195018A can be used in combination as necessary. Further, a lipophilic polymer compound and a hydrophilic polymer compound can be used in combination.

In addition to the presence of the POA chain-containing polymer compound in the image recording layer as a binder that has a function of connecting image recording layer components with each other, the specific polymer compound may be present in the form of particles. In a case where the specific polymer compound is present in the form of particles, the average particle diameter is in a range of 10 to 1,000 nm, preferably in a range of 20 to 300 nm, and particularly preferably in a range of 30 to 120 nm.

The content of the POA chain-containing polymer compound is preferably in a range of 3% to 90% by mass and more preferably in a range of 5% to 80% by mass with respect to the total solid content of the image recording layer. In a case where the content thereof is in the range of 3% to 90% by mass, both of permeability of dampening water and image formability can be reliably achieved.

Other preferred examples of the binder polymer include a polymer compound (hereinafter, also referred to as a “star type polymer compound”) which has a polymer chain bonded to a nucleus through a sulfide bond by means of using a polyfunctional, in a range of hexa- to deca-functional, thiol as the nucleus and in which the polymer chain has a polymerizable group. As the star type polymer compound, for example, compounds described in JP2012-148555A can be preferably used.

Examples of the star type polymer compound include compounds having a polymerizable group such as an ethylenically unsaturated bond in the main chain or in the side chain, preferably in the side chain, for improving coated-film hardness of an image area as described in JP2008-195018A. Cross-linking occurs between polymer molecules by a polymerizable group so that curing is promoted.

Preferred examples of the polymerizable group include an ethylenically unsaturated group such as a (meth)acryl group, a vinyl group, an allyl group, or a styryl group and an epoxy group. Among these, from the viewpoint of polymerization reactivity, a (meth)acryl group, a vinyl group, or a styryl group is more preferable and a (meth)acryl group is particularly preferable. These groups can be introduced into a polymer by a polymer reaction or copolymerization. For example, a reaction between a polymer having a carboxy group in the side chain thereof and glycidyl methacrylate or a reaction between a polymer having an epoxy group and ethylenically unsaturated group-containing carboxylic acid such as methacrylic acid can be used. These groups may be used in combination.

The content of the cross-linking group in the star type polymer compound is preferably in a range of 0.1 to 10.0 mmol, more preferably in a range of 0.25 to 7.0 mmol, and most preferably in a range of 0.5 to 5.5 mmol with respect to 1 g of the star type polymer compound.

Moreover, it is preferable that the star type polymer compound further includes a hydrophilic group. The hydrophilic group contributes to imparting on-press developability to the image recording layer. Particularly, in the coexistence of a polymerizable group and a hydrophilic group, both of printing durability and developability can be achieved.

Examples of the hydrophilic group include —SO₃M¹, —OH, —CONR¹R² (M¹ represents hydrogen, a metal ion, an ammonium ion, or a phosphonium ion, R¹ and R² each independently represent a hydrogen atom, an alkyl group, an alkenyl group, or an aryl group, and R¹ and R² may be bonded to each other to form a ring), —N⁺R³R⁴R⁵X⁻ (R³ to R⁵ each independently represent an alkyl group having 1 to 8 carbon atoms and X⁻ represents a counter anion), a group represented by the following Formula (1), and a group represented by the following Formula (2).

—(CH₂CH₂O)ₙR formula (1)

—(C₃H₆O)ₘR formula (2)

In the above-described formulae, n and m each independently represent an integer of 1 to 100 and R's each independently represent a hydrogen atom or an alkyl group having 1 to 18 carbon atoms.

Here, in a case where the star type polymer compound is a star type polymer compound having a polyoxyalkylene chain (for example, a group represented by the above-described Formula (1) or (2)) in the side chain, such a star type polymer compound is a polymer compound having the above-described polyoxyalkylene chain in the side chain.

Among these hydrophilic groups, —CONR¹R², groups represented by Formula (1), and groups represented by Formula (2) are preferable, —CONR¹R² and groups represented by Formula (1) are more preferable, and groups represented by Formula (1) are particularly preferable. Among the groups represented by Formula (1), n represents preferably 1 to 10 and particularly preferably 1 to 4. Further, R represents more preferably a hydrogen atom or an alkyl group having 1 to 4 carbon atoms and particularly preferably a hydrogen atom or a methyl group. These hydrophilic groups may be used in combination of two or more kinds thereof.

Further, it is preferable that the star type polymer compound does not substantially include a carboxylic acid group, a phosphoric acid group, or a phosphonic acid group. Specifically, the amount of these acid groups is preferably less than 0.1 mmol/g, more preferably less than 0.05 mmol/g, and particularly preferably 0.03 mmol/g or less. In a case where the amount of these acid groups is less than 0.1 mmol/g, developability is further improved.

In order to control impressing property, a lipophilic group such as an alkyl group, an aryl group, an aralkyl group, or an alkenyl group can be introduced into the star type polymer compound. Specifically, a lipophilic group-containing monomer such as methacrylic acid alkyl ester may be copolymerized.

Specific examples of the star type polymer compound include compounds described in paragraphs 0153 to 0157 of JP2014-104631A.

The star type polymer compound can be synthesized, using a known method, by performing radical polymerization on the above-described monomers constituting a polymer chain in the presence of the above-described polyfunctional thiol compound.

The mass average molecular weight of the star type polymer compound is preferably in a range of 5,000 to 500,000, more preferably in a range of 10,000 to 250,000, and particularly preferably in a range of 20,000 to 150,000. In a case where the mass average molecular weight thereof is in the above-described range, the on-press developability and the printing durability are more improved.

The star type polymer compound may be used alone or in combination of two or more kinds thereof. Further, the star type polymer compound may be used in combination with a typical linear binder polymer.

The content of the star type polymer compound is preferably in a range of 5% to 95% by mass, more preferably in a range of 10% to 90% by mass, and particularly preferably in a range of 15% to 85% by mass with respect to the total solid content of the image recording layer.

From the viewpoint of promoting the permeability of dampening water and improving the on-press developability, star type polymer compounds described in JP2012-148555A are particularly preferable.

<Other Components>

The image recording layer A can contain other components described below as necessary.

(1) Low-Molecular Weight Hydrophilic Compound

In order to improve the on-press developability without degrading the printing durability, the image recording layer may contain a low-molecular weight hydrophilic compound.

As the low-molecular weight hydrophilic compound, examples of a water-soluble organic compound include glycols such as ethylene glycol, diethylene glycol, triethylene glycol, propylene glycol, dipropylene glycol, and tripropylene glycol and ether or ester derivatives thereof; polyols such as glycerin, pentaerythritol, and tris(2-hydroxyethyl) isocyanurate; organic amines such as triethanolamine, diethanolamine, and monoethanolamine and salts thereof; organic sulfonic acids such as alkylsulfonic acid, toluenesulfonic acid, and benzenesulfonic acid and salts thereof; organic sulfamic acids such as alkyl sulfamic acid and salts thereof; organic sulfuric acids such as alkyl sulfuric acid and alkyl ether sulfuric acid and salts thereof; organic phosphonic acids such as phenyl phosphonic acid and salts thereof; organic carboxylic acids such as tartaric acid, oxalic acid, citric acid, malic acid, lactic acid, gluconic acid, and amino acids and salts thereof; and betaines.

Among these, it is preferable that the image recording layer contains at least one selected from the group consisting of polyols, organic sulfates, organic sulfonates, and betaines.

Specific examples of the compounds of the organic sulfonates include compounds described in paragraphs 0026 to 0031 of JP2007-276454A and paragraphs 0020 to 0047 of JP2009-154525A. The salt may be potassium salt or lithium salt.

Examples of the organic sulfates include compounds described in paragraphs 0034 to 0038 of JP2007-276454A.

As betaines, compounds having 1 to 5 carbon atoms of hydrocarbon substituents to nitrogen atoms are preferable. Specific examples thereof include trimethyl ammonium acetate, dimethyl propyl ammonium acetate, 3-hydroxy-4-trimethyl ammonio butyrate, 4-(1-pyridinio)butyrate, 1-hydroxyethyl-1-imidazolioacetate, trimethyl ammonium methane sulfonate, dimethyl propyl ammonium methane sulfonate, 3-trimethylammonio-1-propane sulfonate, and 3-(1-pyridinio)-1-propane sulfonate.

Since the low-molecular weight hydrophilic compound has a small structure of a hydrophobic portion, hydrophobicity or coated-film hardness of an image area is not degraded by dampening water permeating into an image recording layer exposed area (image area) and ink receptivity or printing durability of the image recording layer can be maintained satisfactorily.

The amount of the low-molecular weight hydrophilic compounds to be added to the image recording layer is preferably in a range of 0.5% to 20% by mass with respect to the total solid content of the image recording layer. The amount thereof is more preferably in a range of 1% to 15% by mass and still more preferably in a range of 2% to 10% by mass. In a case where the amount thereof is in the above-described range, excellent on-press developability and printing durability can be obtained.

These compounds may be used alone or in combination of two or more kinds thereof.

(2) Oil Sensitizing Agent

In order to improve the impressing property, an oil sensitizing agent such as a phosphonium compound, a nitrogen-containing low-molecular weight compound, or an ammonium group-containing polymer can be used for the image recording layer. Particularly, in a case where a protective layer contains an inorganic layered compound, the above-described compounds function as a surface coating agent of the inorganic layered compound and prevent a degradation in impressing property due to the inorganic layered compound during the printing.

The phosphonium compound, the nitrogen-containing low-molecular weight compound, and the ammonium group-containing polymer are described in paragraphs 0184 to 0190 of JP2014-104631A in detail.

The content of the oil sensitizing agent is preferably in a range of 0.01% to 30.0% by mass, more preferably in a range of 0.1% to 15.0% by mass, and still more preferably in a range of 1% to 10% by mass with respect to the total solid content of the image recording layer.

(3) Other Components

The image recording layer may further contain other components such as a surfactant, a coloring agent, a printing-out agent, a polymerization inhibitor, a higher fatty acid derivative, a plasticizer, inorganic particles, an inorganic layered compound, a co-sensitizer, and a chain transfer agent. Specifically, the compounds and the addition amounts described in paragraphs 0114 to 0159 of JP2008-284817A, paragraphs 0023 to 0027 of JP2006-091479A, and paragraph 0060 of US2008/0311520A can be preferably used.

<Formation of Image Recording Layer A>

The image recording layer A is formed by dispersing or dissolving each of the above-described required components in a known solvent to prepare a coating solution, coating a support with the coating solution directly or through an undercoat layer using a known method such as a bar coater coating method, and drying the resultant, as described in paragraphs 0142 and 0143 of JP2008-195018A. The coating amount of the image recording layer (solid content) on the support to be obtained after the coating and the drying varies depending on the applications thereof, but is preferably in a range of 0.3 to 3.0 g/m². In a case where the coating amount thereof is in the above-described range, excellent sensitivity and excellent film-coating characteristics of the image recording layer are obtained.

(Image Recording Layer B)

The image recording layer B contains an infrared absorbent, a polymerization initiator, a polymerizable compound, and a polymer compound having a particle shape. Hereinafter, the constituent components of the image recording layer B will be described.

Similarly, the infrared absorbent, the polymerization initiator, and the polymerizable compound described in the image recording layer A can be used as an infrared absorbent, a polymerization initiator, and a polymerizable compound in the image recording layer B.

<Polymer Compound Having Particle Shape>

It is preferable that the polymer compound having a particle shape is selected from thermoplastic polymer particles, thermally reactive polymer particles, polymer particles having a polymerizable group, a microcapsule encapsulating a hydrophobic compound, and a microgel (cross-linked polymer particles). Among these, polymer particles having a polymerizable group and a microgel are preferable. According to a particularly preferred embodiment, the polymer compound having a particle shape includes at least one ethylenically unsaturated polymerizable group. Because of the presence of the polymer compound having a particle shape, effects of improving the printing durability of an exposed area and the on-press developability of an unexposed area are obtained.

Preferred examples of the thermoplastic polymer particles include thermoplastic polymer particles described in Research Disclosure No. 33303 on January, 1992, JP1997-123387A (JP-H09-123387A), JP1997-131850A (JP-H09-131850A), JP1997-171249A (JP-H09-171249A), JP1997-171250A (JP-H09-171250A), and EP931647B.

Specific examples of a polymer constituting thermoplastic polymer particles include homopolymers or copolymers of monomers such as acrylate or methacrylate having structures of ethylene, styrene, vinyl chloride, methyl acrylate, ethyl acrylate, methyl methacrylate, ethyl methacrylate, vinylidene chloride, acrylonitrile, vinyl carbazole, and polyalkylene, and mixtures of these. Among these, polystyrene, styrene, a copolymer containing acrylonitrile, and polymethyl methacrylate are more preferable. The average particle diameter of the thermoplastic polymer particles is preferably in a range of 0.01 to 3.0 μm. The average particle diameter is calculated according to a laser light scattering method.

Examples of the thermally reactive polymer particles include polymer particles having a thermally reactive group. The thermally reactive polymer particles are cross-linked by a thermal reaction and have hydrophobic regions formed by a change in functional groups during the cross-linking.

As the thermally reactive group in polymer particles having a thermally reactive group, a functional group that performs any reaction may be used as long as a chemical bond is formed, but a polymerizable group is preferable. Preferred examples of the polymerizable group include an ethylenically unsaturated group that performs a radical polymerization reaction (such as an acryloyl group, a methacryloyl group, a vinyl group, or an allyl group); a cationic polymerizable group (such as a vinyl group, a vinyloxy group, an epoxy group, or an oxetanyl group); an isocyanate group that performs an addition reaction or a block body thereof, an epoxy group, a vinyloxy group, and a functional group having active hydrogen atom as a reaction partner of these (such as an amino group, a hydroxy group, or a carboxy group); a carboxy group that performs a condensation reaction and a hydroxy group or an amino group as a reaction partner thereof; and an acid anhydride that performs a ring-opening addition reaction and an amino group or a hydroxy group as a reaction partner thereof.

The microcapsule is a microcapsule in which at least a part of constituent components of the image recording layer is encapsulated as described in JP2001-277740A and JP2001-277742A. Further, the constituent components of the image recording layer may be contained in a portion other than the microcapsule. Moreover, a preferred embodiment of the image recording layer containing the microcapsule is an embodiment in which hydrophobic constituent components are encapsulated in a microcapsule and hydrophilic constituent components are contained in a portion other than the microcapsule.

The microgel (cross-linked polymer particles) may contain a part of the constituent components of the image recording layer in at least one of the surface or the inside of the microgel. From the viewpoints of image forming sensitivity and printing durability, a reactive microgel having a radical polymerizable group on the surface thereof is particularly preferable.

The constituent components of the image recording layer can be made into microcapsules or microgels using a known method.

Further, from the viewpoints of the printing durability and the solvent resistance, it is preferable that the polymer compound having a particle shape has a hydrophobic main chain and both of a constitutional unit (i) which contains a pendant-cyano group directly bonded to the hydrophobic main chain and a constitutional unit (ii) which contains a pendant group having a hydrophilic polyalkylene oxide segment.

Preferred examples of the hydrophobic main chain include an acrylic resin chain.

Preferred examples of the pendant-cyano group include —[CH₂CH(C≡N)—] and —[CH₂C(CH₃)(C≡N)—].

Further, the constitutional unit having a pendant-cyano group can be easily derived from an ethylene-based unsaturated monomer such as acrylonitrile or methacrylonitrile or a combination of these.

Further, as the alkylene oxide in the hydrophilic polyalkylene oxide segment, ethylene oxide or propylene oxide is preferable and ethylene oxide is more preferable.

The repetition number of alkylene oxide structures in the hydrophilic polyalkylene oxide segment is preferably in a range of 10 to 100, more preferably in a range of 25 to 75, and still more preferably in a range of 40 to 50.

As the resin particles which have a hydrophobic main chain and both of a constitutional unit (i) containing a pendant-cyano group directly bonded to the hydrophobic main chain and a constitutional unit (ii) containing a pendant group having a hydrophilic polyalkylene oxide segment, those described in paragraphs 0039 to 0068 of JP2008-503365A are preferably exemplified.

The average particle diameter of the polymer compound having a particle shape is preferably in a range of 0.01 to 3.0 μm, more preferably in a range of 0.03 to 2.0 μm, and still more preferably in a range of 0.10 to 1.0 μm. In a case where the average particle diameter thereof is in the above-described range, excellent resolution and temporal stability are obtained. The average particle diameter is calculated according to a laser light scattering method.

The content of the polymer compound having a particle shape is preferably in a range of 5% to 90% by mass with respect to the total solid content of the image recording layer.

<Other Components>

The image recording layer B can contain the other components described in the above-described image recording layer A as necessary.

<Formation of Image Recording Layer B>

The image recording layer B can be formed in the same manner as the image recording layer A described above.

(Image Recording Layer C)

The image recording layer C contains an infrared absorbent and thermoplastic polymer particles. Hereinafter, the constituent components of the image recording layer C will be described.

<Infrared Absorbent>

The infrared absorbent contained in the image recording layer C is preferably a dye or a pigment having maximum absorption at a wavelength of 760 to 1,200 nm. A dye is more preferable.

As the dye, commercially available dyes and known dyes described in the literatures (for example, “Dye Handbook” edited by The Society of Synthetic Organic Chemistry, Japan, published in 1970, “Near-Infrared Absorbing Coloring agent” of “Chemical Industry”, p. 45 to 51, published on May, 1986, and “Development and Market Trend of Functional Dyes in 1990's” Section 2.3 of Chapter 2 (CMC Publishing Co., Ltd., published in 1990)) and the patents can be used. Specific preferred examples thereof include infrared absorbing dyes such as an azo dye, a metal complex salt azo dye, a pyrazolone azo dye, an anthraquinone dye, a phthalocyanine dye, a carbonium dye, a quinone imine dye, a polymethine dye, and a cyanine dye.

Among these, infrared absorbing dyes having a water-soluble group are particularly preferable from the viewpoint of addition to the image recording layer.

Specific examples of the infrared absorbing dyes are described below, but the present invention is not limited thereto.

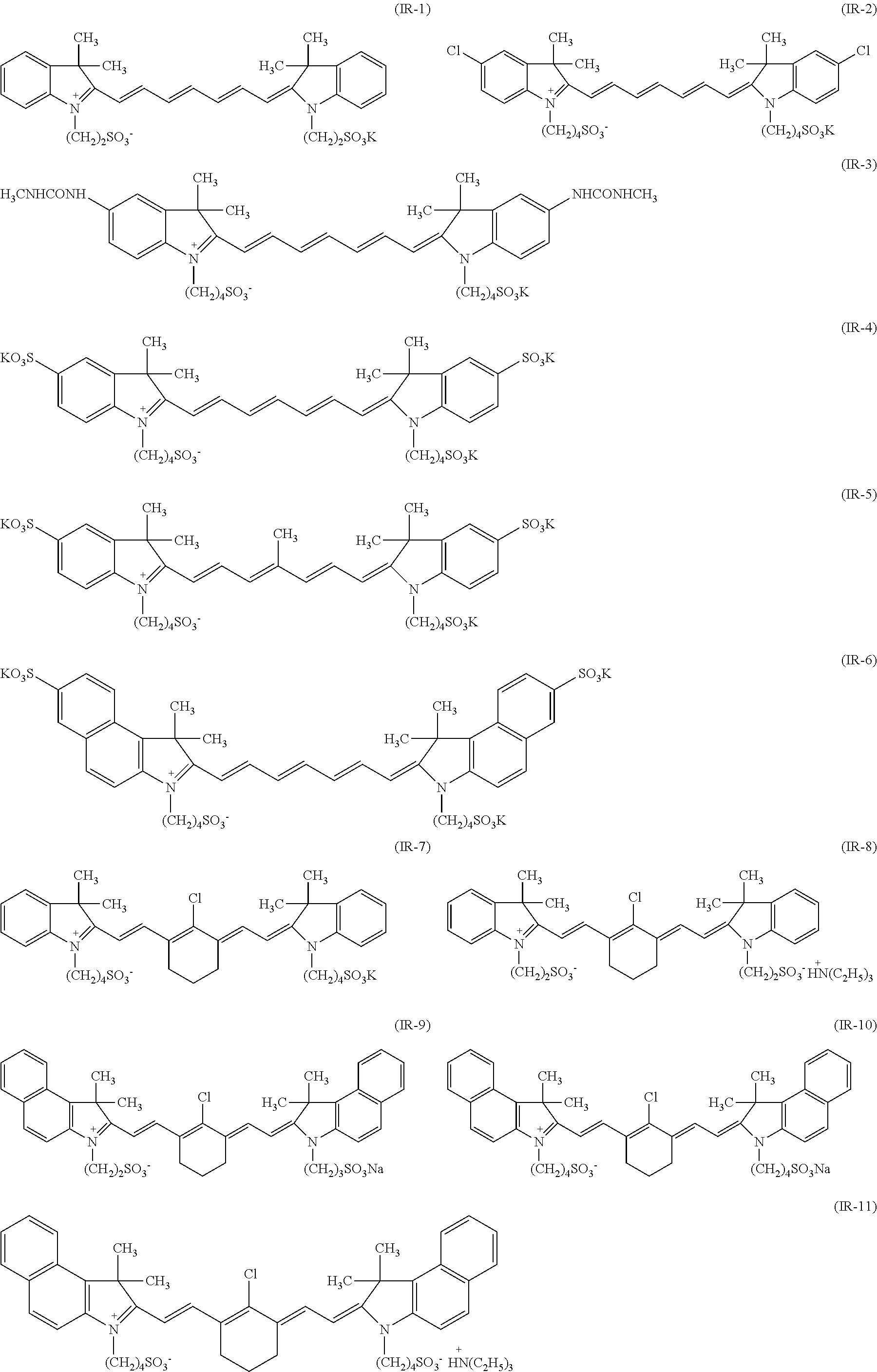

As the pigments, commercially available pigments and pigments described in Color Index (C. I.) Handbook, “Latest Pigment Handbook” (edited by Japan Pigment Technology Association, published in 1977), “Latest Pigment Application Technology” (CMC Publishing Co., Ltd., published in 1986), and “Printing Ink Technology” (CMC Publishing Co., Ltd., published in 1984) can be used.

The particle diameter of the pigment is preferably in a range of 0.01 to 1 μm and more preferably in a range of 0.01 to 0.5 μm. A known dispersion technique used to produce inks or toners can be used as a method of dispersing the pigment. The details are described in “Latest Pigment Application Technology” (CMC Publishing Co., Ltd., published in 1986).

The content of the infrared absorbent is preferably in a range of 0.1% to 30% by mass, more preferably in a range of 0.25% to 25% by mass, and particularly preferably in a range of 0.5% to 20% by mass with respect to the solid content of the image recording layer. In a case where the content thereof is in the above-described range, excellent sensitivity is obtained without damaging the film hardness of the image recording layer.

<Thermoplastic Polymer Particles>

The glass transition temperature (Tg) of the thermoplastic polymer particles is preferably in a range of 60° C. to 250° C. Tg of the thermoplastic polymer particles is more preferably in a range of 70° C. to 140° C. and still more preferably in a range of 80° C. to 120° C.

Preferred examples of the thermoplastic polymer particles having a Tg of 60° C. or higher include thermoplastic polymer particles described in Research Disclosure No. 33303 on January, 1992, JP1997-123387A (JP-H09-123387A), JP1997-131850A (JP-H09-131850A), JP1997-171249A (JP-H09-171249A), JP1997-171250A (JP-H09-171250A), and EP931647B.

Specific examples thereof include homopolymers or copolymers formed of monomers such as ethylene, styrene, vinyl chloride, methyl acrylate, ethyl acrylate, methyl methacrylate, ethyl methacrylate, vinylidene chloride, acrylonitrile, and vinyl carbazole, and mixtures of these. Among these, polystyrene and polymethyl methacrylate are preferable.

The average particle diameter of the thermoplastic polymer particles is preferably in a range of 0.005 to 2.0 μm from the viewpoints of the resolution and the temporal stability. This value is used as the average particle diameter in a case where two or more kinds of thermoplastic polymer particles are mixed with each other. The average particle diameter thereof is more preferably in a range of 0.01 to 1.5 μm and particularly preferably in a range of 0.05 μm to 1.0 μm. The polydispersity in a case where two or more kinds of thermoplastic polymer particles are mixed with each other is preferably 0.2 or greater. The average particle diameter and the polydispersity are calculated according to a laser light scattering method.

The thermoplastic polymer particles may be used in combination of two or more kinds thereof. Specifically, at least two kinds of thermoplastic polymer particles with different particle sizes or at least two kinds of thermoplastic polymer particles with different Tg's may be exemplified. When two or more kinds of thermoplastic polymer particles are used in combination, coated-film curing properties of an image area are further improved and printing durability in a case where a planographic printing plate is obtained is further improved.

For example, in a case where thermoplastic polymer particles having the same particle size are used, voids are present between the thermoplastic polymer particles to some extent and thus the curing properties of the coated-film are not desirable in some cases even when the thermoplastic polymer particles are melted and solidified by image exposure. Meanwhile, in a case where thermoplastic polymer particles having different particle sizes are used, the void volume between the thermoplastic polymer particles can be decreased and thus the coated-film curing properties of the image area after image exposure can be improved.

Further, in a case where thermoplastic polymer particles having the same Tg are used, the thermoplastic polymer particles are not sufficiently melted and solidified in some cases when an increase in temperature of the image recording layer resulting from image exposure is insufficient, and thus the curing properties of the coated-film are not desirable. Meanwhile, in a case where thermoplastic polymer particles having different Tg's are used, the coated-film curing properties of the image area can be improved even in a case where an increase in temperature of the image recording layer resulting from image exposure is insufficient.

In a case where two or more kinds of thermoplastic polymer particles having different Tg's are used in combination, the Tg of at least one thermoplastic polymer particle is preferably 60° C. or higher. At this time, a difference in Tg is preferably 10° C. or higher and still more preferably 20° C. or higher. In addition, it is preferable that the content of the thermoplastic polymer particles having a Tg of 60° C. or higher is 70% by mass or greater with respect to the total amount of all thermoplastic polymer particles.

The thermoplastic polymer particles may include a cross-linking group. In a case where thermoplastic polymer particles having a cross-linking group are used, the cross-linking group is thermally reacted due to heat generated by an image-exposed area so as to be cross-linked between the polymers, and thus coated-film hardness of the image area is improved and printing durability becomes more excellent. As the cross-linking group, a functional group that performs any reaction may be used as long as a chemical bond is formed, and examples thereof include an ethylenically unsaturated group that performs a polymerization reaction (such as an acryloyl group, a methacryloyl group, a vinyl group, or an allyl group); an isocyanate group that performs an addition reaction or a block body thereof, and a group having active hydrogen atom as a reaction partner of these (such as an amino group, a hydroxy group, or a carboxyl group); an epoxy group that performs an addition reaction and an amino group, a carboxyl group or a hydroxy group as a reaction partner thereof; a carboxyl group that performs a condensation reaction and a hydroxy group or an amino group; and an acid anhydride that performs a ring-opening addition reaction and an amino group or a hydroxy group.

Specific examples of the thermoplastic polymer particles having a cross-linking group include thermoplastic polymer particles having a cross-linking group such as an acryloyl group, a methacryloyl group, a vinyl group, an allyl group, an epoxy group, an amino group, a hydroxy group, a carboxyl group, an isocyanate group, an acid anhydride, and a protecting group of these. These cross-linking groups may be introduced into polymers at the time of polymerization of polymer particles or may be introduced using a polymer reaction after polymerization of the polymer particles.

In a case where a cross-linking group is introduced to a polymer at the time of polymerization of polymer particles, it is preferable that a monomer having a cross-linking group may be subjected to an emulsion polymerization or a suspension polymerization. Specific examples of the monomer having a cross-linking group include allyl methacrylate, allyl acrylate, vinyl methacrylate, vinyl acrylate, glycidyl methacrylate, glycidyl acrylate, 2-isocyanate ethyl methacrylate or a block isocyanate resulting from alcohol thereof, 2-isocyanate ethyl acrylate or a block isocyanate resulting from alcohol thereof, 2-aminoethyl methacrylate, 2-aminoethyl acrylate, 2-hydroxyethyl methacrylate, 2-hydroxyethyl acrylate, acrylic acid, methacrylic acid, maleic acid anhydride, difunctional acrylate, and difunctional methacrylate.

Examples of the polymer reaction used in a case where a cross-linking group is introduced after polymerization of polymer particles include polymer reactions described in WO96/034316A.

Polymer particles may react with each other through a cross-linking group or the thermoplastic polymer particles may react with a polymer compound or a low-molecular weight compound added to the image recording layer.

The content of the thermoplastic polymer particles is preferably in a range of 50% to 95% by mass, more preferably in a range of 60% to 90% by mass, and particularly preferably in a range of 70% to 85% by mass with respect to the solid content of the image recording layer.

<Other Components>

The image recording layer C may further contain other components as necessary.

<Surfactant Having Polyoxyalkylene Group or Hydroxy Group>

As the surfactant having a polyoxyalkylene group (hereinafter, also referred to as a “POA group”) or a hydroxy group, a surfactant having a POA group or a hydroxy group may be suitably used, but an anionic surfactant or a non-ionic surfactant is preferable. Among anionic surfactants or non-ionic surfactants having a POA group or a hydroxy group, anionic surfactants or non-ionic surfactants having a POA group are preferable.

As the POA group, a polyoxyethylene group, a polyoxypropylene group, or a polyoxybutylene group is preferable and a polyoxyethylene group is particularly preferable.

The average degree of polymerization of an oxyalkylene group is practically in a range of 2 to 50 and preferably in a range of 2 to 20.

The number of hydroxy groups is practically 1 to 10 and preferably in a range of 2 to 8. Here, the number of terminal hydroxy groups in the oxyalkylene group is not included in the number of hydroxy groups.

(Anionic Surfactant Having POA Group or Hydroxy Group)

The anionic surfactant having a POA group is not particularly limited, and examples thereof include polyoxyalkylene alkyl ether carboxylates, polyoxyalkylene alkyl sulfosuccinates, polyoxyalkylene alkyl ether sulfuric acid ester salts, alkyl phenoxy polyoxyalkylene propyl sulfonates, polyoxyalkylene alkyl sulfophenyl ethers, polyoxyalkylene aryl ether sulfuric acid ester salts, polyoxyalkylene polycyclic phenylether sulfuric acid ester salts, polyoxyalkylene styryl phenyl ether sulfuric acid ester salts, polyoxyalkylene alkyl ether phosphoric acid ester salts, polyoxyalkylene alkyl phenyl ether phosphoric acid ester salts, and polyoxyalkylene perfluoroalkyl ether phosphoric acid ester salts.

The anionic surfactant having a hydroxy group is not particularly limited, and examples thereof include hydroxy carboxylates, hydroxy alkyl ether carboxylates, hydroxy alkane sulfonates, fatty acid monoglyceride sulfuric acid ester salts, and fatty acid monoglyceride acid ester salts.

The content of the surfactant having a POA group or a hydroxy group is preferably in a range of 0.05% to 15% by mass and more preferably in a range of 0.1% to 10% by mass with respect to the solid content of the image recording layer.

Hereinafter, specific examples of the surfactant having a POA group or a hydroxy group will be described, but the present invention is not limited thereto. A surfactant A-12 described below is a trade name of Zonyl FSP and available from Dupont. Further, a surfactant N-11 described below is a trade name of Zonyl FSO 100 and available from Dupont.

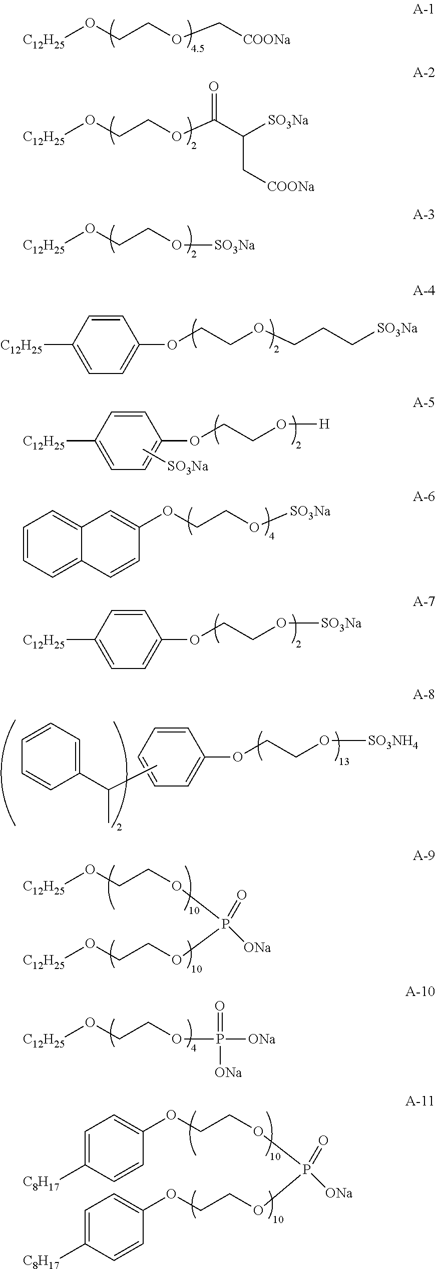

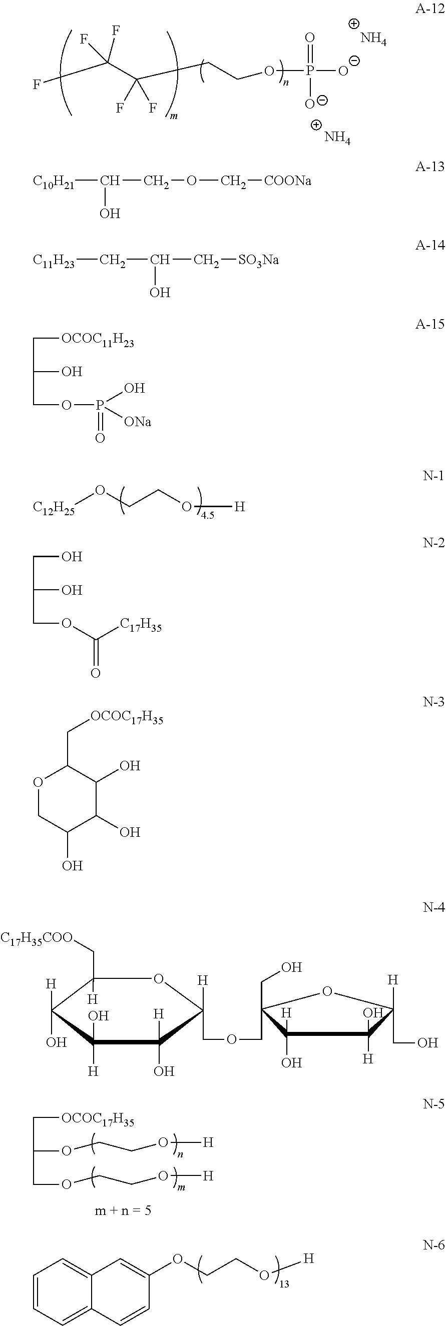

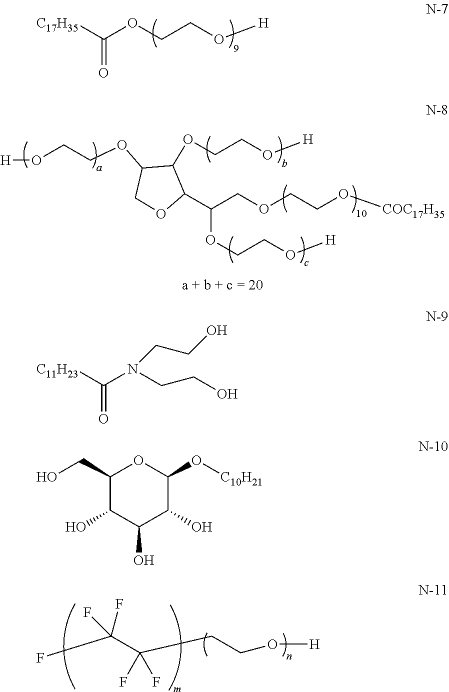

For the purpose of ensuring coating uniformity of the image recording layer, the image recording layer may contain an anionic surfactant that does not have a polyoxyalkylene group or a hydroxy group.

The anionic surfactant is not particularly limited as long as the above-described purpose is achieved. Among the examples of the anionic surfactants, alkyl benzene sulfonic acid or a salt thereof, alkyl naphthalene sulfonic acid or a salt thereof, (di)alkyl diphenyl ether (di)sulfonic acid or a salt thereof, or alkyl sulfuric acid ester salt is preferable.

The addition amount of the anionic surfactant that does not have a polyoxyalkylene group or a hydroxy group is preferably in a range of 1% to 50% by mass and more preferably in a range of 1% to 30% by mass with respect to the surfactant which has a polyoxyalkylene group or a hydroxy group.

Hereinafter, specific examples of the anionic surfactant that does not have a polyoxyalkylene group or a hydroxy group will be described, but the present invention is not limited thereto.

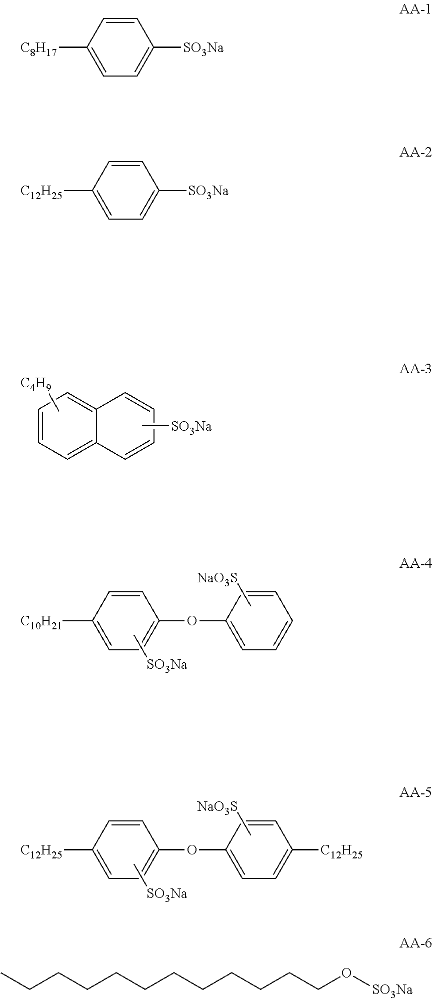

Further, for the purpose of ensuring coating uniformity of the image recording layer, a non-ionic surfactant that does not have a polyoxyalkylene group or a hydroxy group or a fluorine-based surfactant may be used. For example, fluorine-based surfactants described in JP1987-170950A (JP-S62-170950A) are preferably used.

The image recording layer may contain a hydrophilic resin. Preferred examples of the hydrophilic resin include resins having a hydrophilic group such as a hydroxy group, a hydroxyethyl group, a hydroxypropyl group, an amino group, an aminoethyl group, an aminopropyl group, a carboxyl group, a carboxylate group, a sulfo group, a sulfonate group, and a phosphoric acid group.

Specific examples of the hydrophilic resin include gum Arabic, casein, gelatin, a starch derivative, carboxy methyl cellulose and sodium salt thereof, cellulose acetate, sodium alginate, vinyl acetate-maleic acid copolymers, styrene-maleic acid copolymers, polyacrylic acids and salts of these, polymethacrylic acids and salts of these, a homopolymer and a copolymer of hydroxy ethyl methacrylate, a homopolymer and a copolymer of hydroxyethyl acrylate, a homopolymer and a copolymer of hydroxypropyl methacrylate, a homopolymer and a copolymer of hydroxypropyl acrylate, a homopolymer and a copolymer of hydroxybutyl methacrylate, a homopolymer and a copolymer of hydroxybutyl acrylate, polyethylene glycols, hydroxy propylene polymers, polyvinyl alcohols, hydrolyzed polyvinyl acetate having a degree of hydrolysis of at least 60% and preferably at least 80%, polyvinyl formal, polyvinyl butyral, polyvinyl pyrrolidone, a homopolymer and a copolymer of acrylamide, a homopolymer and a copolymer of methacrylamide, and a homopolymer and a copolymer of N-methylol acrylamide.

The mass average molecular weight of the hydrophilic resin is preferably 2,000 or greater from the viewpoints of obtaining sufficient coated-film hardness or printing durability.

The content of the hydrophilic resin is preferably in a range of 0.5% to 50% by mass and more preferably in a range of 1% to 30% by mass with respect to the solid content of the image recording layer.

The image recording layer may contain inorganic particles. Preferred examples of the inorganic particles include silica, alumina, magnesium oxide, titanium oxide, magnesium carbonate, calcium alginate, and a mixture of these. The inorganic particles can be used for the purpose of improving coated-film hardness.

The average particle diameter of the inorganic particles is preferably in a range of 5 nm to 10 μm and more preferably in a range of 10 nm to 1 μm. In a case where the average particle diameter thereof is in the above-described range, the thermoplastic polymer particles are stably dispersed, the film hardness of the image recording layer is sufficiently held, and a non-image area with excellent hydrophilicity in which printing stain is unlikely to occur can be formed.

The inorganic particles are available as commercial products such as a colloidal silica dispersion.

The content of the inorganic particles is preferably in a range of 1.0% to 70% by mass and more preferably in a range of 5.0% to 50% by mass with respect to the solid content of the image recording layer.

The image recording layer may contain a plasticizer in order to impart flexibility and the like to a coated film. Examples of the plasticizer include polyethylene glycol, tributyl citrate, diethyl phthalate, dibutyl phthalate, dihexyl phthalate, dioctyl phthalate, tricresyl phosphate, tributyl phosphate, trioctyl phosphate, and tetrahydrofurfuryl oleate.

The content of the plasticizer is preferably in a range of 0.1% to 50% by mass and more preferably in a range of 1% to 30% by mass with respect to the solid content of the image recording layer.

In a case where polymer particles having a thermally reactive functional group (cross-linking group) are used for the image recording layer, a compound that initiates or promotes a reaction of the thermally reactive functional group (cross-linking group) can be added to the image recording layer as necessary. As the compound that initiates or promotes a reaction of the thermally reactive functional group, a compound that generates a radical or a cation by heating may be exemplified. Examples of the compound include a lophine dimer, a trihalomethyl compound, a peroxide, an azo compound, onium salts including diazonium salts and diphenyl iodonium salts, acyl phosphine, and imide sulfonate. The amount of the compound to be added to the image recording layer is preferably in a range of 1% to 20% by mass and more preferably in a range of 1% to 10% by mass with respect to the solid content of the image recording layer. In a case where the amount thereof is in the above-described range, on-press developability is not degraded and excellent effects for initiating or promoting a reaction are obtained.

<Formation of Image Recording Layer C>

The image recording layer C is formed by dissolving or dispersing each of the above-described required components in a suitable solvent to prepare a coating solution, coating a support with the coating solution directly or through an undercoat layer. As the solvent, water or a mixed solvent of water and an organic solvent is used, and a mixed solvent of water and an organic solvent is preferable from the viewpoint of the excellent surface state after coating. Since the amount of the organic solvent varies depending on the type of organic solvent, the amount thereof cannot be specified unconditionally, but the amount of the organic solvent in the mixed solvent is preferably in a range of 5% to 50% by volume. Here, it is necessary that the amount of the organic solvent to be used is set to such that the thermoplastic polymer particles are not aggregated. The concentration of solid contents of the image recording layer coating solution is preferably in a range of 1% to 50% by mass.

As the organic solvent used as a solvent of the coating solution, a water-soluble organic solvent is preferable. Specific examples thereof include alcohol solvents such as methanol, ethanol, propanol, isopropanol, or 1-methoxy-2-propanol, ketone solvents such as acetone or methyl ethyl ketone, glycol ether solvents such as ethylene glycol dimethyl ether, γ-butyrolactone, N,N-dimethylformamide, N,N-dimethylacetamide, tetrahydrofuran, and dimethylsulfoxide. Particularly, an organic solvent having a boiling point of 120° C. or lower and a solubility (amount of a solvent to be dissolved in 100 g of water) of 10 g or greater in water is preferable and an organic solvent having a solubility of 20 g or greater is more preferable.

As a coating method of the image recording layer coating solution, various methods can be used. Examples of the methods include a bar coater coating method, a rotary coating method, a spray coating method, a curtain coating method, a dip coating method, an air knife coating method, a blade coating method, and a roll coating method. The coating amount (solid content) of the image recording layer on the support obtained after the coating and the drying varies depending on the applications thereof, but is preferably in a range of 0.5 to 5.0 g/m² and more preferably in a range of 0.5 to 2.0 g/m².

The image recording layer of the planographic printing plate precursor according to the present invention may be an image recording layer of which non-image area is removed by a developer. Such an image recording layer includes image recording layers of many planographic printing plate precursors known as a so-called development treatment type planographic printing plate precursor.

According to one embodiment of the image recording layer to be removed by a developer, the image recording layer may be a negative type image recording layer containing a sensitizing dye, a polymerization initiator, a polymerizable compound, and a binder polymer. Such a negative type image recording layer is described as a “recording layer” in paragraphs 0057 to 0154 of JP2008-015503A.

According to one embodiment of the image recording layer to be removed by a developer, the image recording layer is a positive type image recording layer containing a water-insoluble and alkali-soluble resin and an infrared absorbent. Such a positive type image recording layer is described as a “recording layer” in paragraphs 0055 to 0132 of JP2007-148940A.

Hereinafter, other constituent elements of the planographic printing plate precursor will be described.

[Undercoat Layer]

The planographic printing plate precursor may be provided with an undercoat layer between the image recording layer and the support as necessary. Since intimate attachment of the support to the image recording layer becomes stronger in an exposed area and the support is easily peeled off from the image recording layer in an unexposed area, the undercoat layer contributes to improvement of on-press developability without degrading printing durability. Further, in a case of infrared laser exposure, the undercoat layer functions as a heat insulating layer so that a degradation in sensitivity due to heat, generated by the exposure, being diffused in the support is prevented.

Examples of the compound used for the undercoat layer include a silane coupling agent having an ethylenic double bond reactive group, which is an addition-polymerizable group, described in JP1998-282679A (JP-H10-282679A); and a phosphorus compound having an ethylenic double bond reactive group described in JP1990-304441A (JP-H02-304441A). Preferred examples thereof include polymer compounds having an adsorptive group, which can be adsorbed to the surface of the support, a hydrophilic group, and a cross-linking group, as described in JP2005-125749A and JP2006-188038A. As such a polymer compound, a copolymer of a monomer having an adsorptive group, a monomer having a hydrophilic group, and a monomer having a cross-linking group is preferable. Specific examples thereof include a copolymer of a monomer having an adsorptive group such as a phenolic hydroxy group, a carboxy group, —PO₃H₂, —OPO₃H₂, —CONHSO₂—, —SO₂NHSO₂—, or —COCH₂COCH₃, a monomer having a hydrophilic group such as a sulfo group, and a monomer having a polymerizable cross-linking group such as a methacryl group or an allyl group. The polymer compound may have a cross-linking group introduced by forming salts between a polar substituent of the polymer compound and a compound that includes a substituent having the opposite charge of the polar substituent and an ethylenically unsaturated bond. Further, monomers other than the above-described monomers, preferably hydrophilic monomers may be further copolymerized.

The content of the unsaturated double bond in the polymer compound for an undercoat layer is preferably in a range of 0.1 to 10.0 mmol and more preferably in a range of 2.0 to 5.5 mmol with respect to 1 g of the polymer compound.

The mass average molecular weight of the polymer compound for an undercoat layer is preferably 5,000 or greater and more preferably in a range of 10,000 to 300,000.

For the purpose of preventing stain over time, the undercoat layer may contain a chelating agent, a secondary or tertiary amine, a polymerization inhibitor, a compound that includes an amino group or a functional group having polymerization inhibiting ability and a group interacting with the surface of an aluminum support, and the like (for example, 1,4-diazabicyclo[2,2,2]octane (DABCO), 2,3,5,6-tetrahydroxy-p-quinone, chloranil, sulfophthalic acid, hydroxyethyl ethylene diamine triacetic acid, dihydroxyethyl ethylene diamine diacetic acid, or hydroxyethyl imino diacetic acid) in addition to the compounds for an undercoat layer described above.

The undercoat layer is applied according to a known method. The coating amount (solid content) of the undercoat layer is preferably in a range of 0.1 to 100 mg/m² and more preferably in a range of 1 to 30 mg/m².

[Support]

A known support is used as the support of the planographic printing plate precursor. Among examples of the known support, an aluminum plate subjected to a roughening treatment and an anodizing treatment using a known method is preferable.

The aluminum plate can be subjected to a treatment appropriately selected from an expansion treatment or a sealing treatment of micropores of an anodized film described in JP2001-253181A or JP2001-322365A or a surface hydrophilization treatment using alkali metal silicate described in U.S. Pat. Nos. 2,714,066A, 3,181,461A, 3,280,734A, and 3,902,734A or polyvinyl phosphonic acid described in U.S. Pat. Nos. 3,276,868A, 4,153,461A, and 4,689,272A as necessary.

The center line average roughness of the support is preferably in a range of 0.10 to 1.2 μm.

The rear surface of the support may be provided with an organic polymer compound described in JP1993-045885A (JP-H05-045885A) and a back coat layer containing an alkoxy compound of silicon described in JP1994-035174A (JP-H06-035174A) as necessary.

[Protective Layer]

A protective layer may be provided on the image recording layer of the planographic printing plate precursor as necessary. The protective layer has a function of preventing generation of damage to the image recording layer and a function of preventing ablation at the time of high illuminance laser exposure, in addition to a function of suppressing a reaction of inhibiting image formation through oxygen blocking.

As the protective layer having such functions, a protective layer described in paragraphs 0202 to 0204 of JP2014-104631A can be used.

The protective layer is applied according to a known method. The coating amount of the protective layer after the drying is preferably in a range of 0.01 to 10 g/m², more preferably in a range of 0.02 to 3 g/m², and particularly preferably in a range of 0.02 to 1 g/m².

The planographic printing plate precursor can be produced by applying a coating solution of each configuration layer according to a typical method, performing drying, and forming each configuration layer. The coating solution can be applied according to a die coating method, a dip coating method, an air knife coating method, a curtain coating method, a roller coating method, a wire bar coating method, a gravure coating method, or a slide coating method.

Hereinafter, a printing key plate precursor which is another preferred embodiment of the printing plate precursor will be described.

The printing key plate precursor is a precursor for producing a printing key plate by performing the same plate-making step (here, image exposure is not performed) as that for the planographic printing plate precursor and basically does not have photosensitivity. As well-known in the printing industry, the printing key plate is used by being attached to a plate cylinder in a case where it is necessary to print a part of the paper surface with two colors or one color in color newspaper printing (multicolor printing).

[Printing Key Plate Precursor]

A printing key plate precursor according to the present invention includes a non-photosensitive layer on a side (in the specification of the present application, referred to as a “printing surface side”) of the support to which ink and dampening water are supplied during printing. The non-photosensitive layer in the printing key plate precursor corresponds to the layer containing a polymer in the printing plate precursor. The printing key plate precursor may include an undercoat layer between the support and the non-photosensitive layer and a hydrophilic layer on the non-photosensitive layer as necessary.

It is preferable that the non-photosensitive layer in the printing key plate precursor contains a water-soluble binder polymer or a water-insoluble and alkali-soluble binder polymer (hereinafter, also referred to as a “binder polymer”). Further, the non-photosensitive layer may contain a colorant having maximum absorption at a wavelength of 350 to 550 nm and a low-molecular-weight acidic compound.

The binder contained in the non-photosensitive layer of the printing key plate precursor is described in, for example, paragraphs 0069 to 0074 of JP2012-218778A.

The non-photosensitive layer of the printing key plate precursor and the method of forming the same are described in, for example, paragraphs 0021 to 0054 of JP2012-218778A.

The hydrophilic layer of the printing key plate precursor contains a binder.

The hydrophilic layer can be formed by coating the non-photosensitive layer with a hydrophilic layer coating solution prepared by mixing a binder and various additives such as a colorant, a water-soluble plasticizer, and a surfactant to be added depending on the purpose thereof and stirring the solution according to a method described in, for example, U.S. Pat. No. 3,458,311A or JP1980-049729A (JP-S55-049729A). The coating amount of the hydrophilic layer is preferably in a range of 0.2 to 5.0 g/m² and more preferably in a range of 0.3 to 3.0 g/m².

The binder contained in the hydrophilic layer of the printing key plate precursor is described in, for example, paragraphs 0069 to 0074 of JP2012-218778A.

The plate-making of the printing plate precursor according to the embodiment of the present invention will be described below. The plate-making of the printing plate precursor according to the embodiment of the present invention basically includes an image exposure step and a development treatment step. In the printing plate precursor according to the embodiment of the present invention, the development treatment step is performed without performing the image exposure step in a case of the printing key plate precursor.

[Image Exposure Step]

The image exposure of the planographic printing plate precursor can be performed in conformity with an image exposure operation for a typical planographic printing plate precursor.

The image exposure is performed by laser exposure through a transparent original picture having a line image, a halftone image, and the like or by laser beam scanning using digital data. The wavelength of a light source is preferably in a range of 700 to 1,400 nm. As the light source having a wavelength of 700 to 1,400 nm, a solid-state laser or a semiconductor laser that radiates infrared rays is preferable. The output of the infrared laser is preferably 100 mW or greater, the exposure time per one pixel is preferably less than 20 microseconds, and the irradiation energy quantity is preferably in a range of 10 to 300 mJ/cm². For the purpose of reducing the exposure time, it is preferable to use a multi-beam laser device. The exposure mechanism may be any of an internal drum system, an external drum system, a flat bed system, and the like. The image exposure can be performed using a plate setter according to a usual method.

[Development Treatment Step]

The development treatment can be performed using a typical method. In a case of on-press development, a printing ink receiving unit having a lipophilic surface is formed by the image recording layer cured by light exposure in the exposed area of the image recording layer in a case where dampening water and printing ink are supplied to the image-exposed planographic printing plate precursor on a printing press. Meanwhile, in an unexposed area, a non-cured image recording layer is dissolved or dispersed by supplied dampening water and/or printing ink and then removed, a hydrophilic surface is exposed to the portion. As the result, dampening water is exposed and adheres to the hydrophilic surface, the printing ink is impressed on the image recording layer of the exposed region, and then the printing is started.

Here, either of dampening water or printing ink may be initially supplied to the surface of the planographic printing plate precursor, but it is preferable that dampening water is initially supplied thereto so that the on-press developability is promoted by permeation of the dampening water.

The development treatment using a developer can be performed by a usual method. The development treatment of a development treatment type negative type planographic printing plate precursor is described in, for example, paragraphs 0197 to 0220 of JP2008-015503A. The development treatment of the development treatment type positive type planographic printing plate precursor is described in, for example, paragraphs 0157 to 0160 of JP2007-148040A.

[Printing Plate Precursor Laminate and Printing Plate Laminate]

A printing plate precursor laminate according to the embodiment of the present invention is a laminate obtained by laminating the printing plate precursors according to the embodiment of the present invention and is formed by laminating a plurality of the printing plate precursors according to the embodiment of the present invention. Further, it is preferable that the printing plate precursor laminate is a laminate obtained by bringing the outermost layer on the surface where the layer containing a polymer is provided into direct contact with the outermost layer on the surface where the layer containing tabular particles is provided so that the layers are laminated on each other.

A printing plate precursor laminate according to the embodiment of the present invention is a laminate formed by directly laminating a plurality (typically, 2 to 500 sheets) of printing plate precursors according to the embodiment of the present invention without sandwiching interleaving paper between the precursors.

The printing plate precursor laminate according to the embodiment of the present invention has an excellent property of preventing scratches to the back coat layer and preventing peeling of the back coat layer because of the effects of the tabular particles of the back coat layer included in the printing plate precursor according to the embodiment of the present invention.

A printing plate laminate according to the present invention is a laminate formed by directly laminating a plurality of sheets of planographic printing plates or printing key plates without sandwiching interleaving paper between the plates. Such a laminate is formed by laminating a plurality of sheets of planographic printing plates or printing key plates and placing the laminate in an appropriate place in a case where there is a gap in time for about several hours to several days after the plate-making to starting of printing.

### EXAMPLES

Hereinafter, the present invention will be described in detail with reference to examples, but the present invention is not limited thereto. Further, in a polymer compound, the molecular weight indicates the mass average molecular weight (Mw) and the proportion of repeating units indicates mole percentage unless otherwise specified. Further, the mass average molecular weight (Mw) is a value in terms of polystyrene obtained by performing measurement using gel permeation chromatography (GPC).

<Production of Support 1>

As a roughening treatment, the following treatments (a) to (e) were performed. In addition, a water washing treatment was performed between all the treatment steps.

(a) Alkali Etching Treatment

An aluminum plate (material JIS 1052) having a thickness of 0.3 mm was subjected to an etching treatment by spraying an aqueous solution in which the concentration of caustic soda was 25% by mass and the concentration of aluminum ions was 100 g/L using a spray tube at a temperature of 60° C. The etching amount of the surface of the aluminum plate to be subjected to an electrochemical roughening treatment was 3 g/m².

(b) Desmutting Treatment

Next, a desmutting treatment was performed by spraying a sulfuric acid aqueous solution (concentration of 300 g/L) at a temperature of 35° C. for 5 seconds using the spray tube.

(c) Electrolytic Roughening Treatment

Thereafter, an electrochemical roughening treatment was continuously performed using an electrolyte (solution temperature of 35° C.) obtained by dissolving aluminum chloride in a 1% by mass of hydrochloric acid aqueous solution and adjusting the aluminum ion concentration to 4.5 g/L, a 60 Hz AC power source, and a flat cell type electrolytic cell. A sine wave was used as the waveform of the AC power source. In the electrochemical roughening treatment, the current density of the aluminum plate during the anodic reaction at the peak of the alternating current was 30 A/dm². The ratio between the sum total of electric quantity at the time of the anodic reaction and the sum total of electric quantity at the time of the cathodic reaction of the aluminum plate was 0.95. The electric quantity was set to 480 C/dm² in terms of the sum total of electric quantity at the time of the anodic reaction of the aluminum plate. The electrolyte was circulated using a pump so that the stirring inside the electrolytic cell was performed.

(d) Alkali Etching Treatment

The aluminum plate was subjected to an etching treatment by spraying an aqueous solution at a temperature of 35° C. in which the concentration of caustic soda was 5% by mass and the concentration of aluminum ions was 5 g/L using a spray tube. The etching amount of the surface of the aluminum plate on which the electrolytic roughening treatment had been performed was 0.05 g/m².

(e) Desmutting Treatment

Next, a desmutting treatment was performed by spraying an aqueous solution at a solution temperature of 35° C. with a sulfuric acid concentration of 300 g/L and an aluminum ion concentration of 5 g/L using the spray tube for 5 seconds.

The aluminum plate on which the roughening treatment had been performed was subjected to an anodizing treatment at a treatment temperature of 38° C. and a current density of 15 A/dm² using a 22% by mass of phosphoric acid aqueous solution as an electrolyte. Thereafter, washing with water by spraying was performed. The final amount of the oxide film was 1.5 g/m². The surface of the substrate was imaged at a magnification of 150000 times using an electronic microscope and the average pore diameter in a case of n=90 was actually measured, and the value was 30 nm.

<Production of Support 2>

An aluminum plate having a thickness of 0.19 mm was immersed in a 40 g/L sodium hydroxide aqueous solution at 60° C. for 8 seconds so as to be degreased and then washed with demineralized water for 2 seconds. Next, the aluminum plate was subjected to an electrochemical roughening treatment in an aqueous solution containing 12 g/L of hydrochloric acid and 38 g/L of aluminum sulfate (18 hydrates) at a temperature of 33° C. and at a current density of 130 A/dm² using an AC for 15 seconds. Next, the aluminum plate was washed with demineralized water for 2 seconds, subjected to a desmutting treatment by being etched using 155 g/L of a sulfuric acid aqueous solution at 70° C. for 4 seconds, and washed with demineralized water at 25° C. for 2 seconds. The aluminum plate was subjected to an anodizing treatment in 155 g/L of a sulfuric acid aqueous solution for 13 seconds at a temperature of 45° C. and at a current density of 22 A/dm² and washed with demineralized water for 2 seconds. Further, the aluminum plate was treated at 40° C. for 10 seconds using 4 g/L of a polyvinyl phosphonic acid aqueous solution, washed with demineralized water at 20° C. for 2 seconds, and then dried, thereby producing a support. The surface roughness Ra of the obtained support was 0.21 μm and the amount of the anodized film was 4 g/m².

<Production of Support 3>

An aluminum alloy plate having a thickness of 0.3 mm and having a composition listed in Table A was subjected to the following treatments (a) to (m), whereby a support 3 was produced. Moreover, during all treatment steps, a water washing treatment was performed, and liquid cutting was performed using a nip roller after the water washing treatment.

TABLE A
Composition (% by mass)

| Si | Fe | Cu | Mn | Mg | Zn | Ti | Al |
|---|---|---|---|---|---|---|---|
| 0.085 | 0.303 | 0.037 | 0 | 0 | 0 | 0.018 | Remainder |

(a) Mechanical Roughening Treatment (Brush Grain Method)

While supplying a suspension of pumice (specific gravity of 1.1 g/cm³) to the surface of an aluminum plate as a polishing slurry liquid, a mechanical roughening treatment was performed using rotating bundle bristle brushes.

The mechanical roughening treatment was performed under conditions in which the median diameter of a polishing material pumice was 30 μm, the number of the bundle bristle brushes was four, and the rotation speed of the bundle bristle brushes was set to 250 rpm. The material of the bundle bristle brushes was nylon 6-10, the diameter of the brush bristles was 0.3 mm, and the bristle length was 50 mm. The bundle bristle brushes were produced by implanting bristles densely into holes in a stainless steel cylinder having a diameter of φ300 mm. The distance between two support rollers (φ200 mm) of the lower portion of the bundle bristle brushes was 300 mm. The bundle bristle brushes were pressed until the load of a driving motor for rotating the brushes became 10 kW plus with respect to the load before the bundle bristle brushes were pressed against the aluminum plate. The rotation direction of the bundle bristle brushes was the same as the moving direction of the aluminum plate.

(b) Alkali Etching Treatment

The aluminum plate was subjected to an etching treatment by spraying a caustic soda aqueous solution in which the concentration of caustic soda was 26% by mass and the concentration of aluminum ions was 6.5% by mass using a spray tube at a temperature of 70° C. Thereafter, washing with water by spraying was performed. The amount of aluminum dissolved was 10 g/m².

(c) Desmutting Treatment in Acidic Aqueous Solution

Next, a desmutting treatment was performed in a nitric acid aqueous solution. As the nitric acid aqueous solution used in the desmutting treatment, a nitric acid electrolyte used in electrochemical roughening of the subsequent step was used. The solution temperature was 35° C. The desmutting treatment was performed for 3 seconds by spraying the desmutting liquid using a spray.

(d) Electrochemical Roughening Treatment

An electrochemical roughening treatment was continuously performed using an AC voltage of 60 Hz. An electrolyte which had been adjusted to have a concentration of aluminum ions of 4.5 g/L by adding aluminum nitrate to a nitric acid aqueous solution having a concentration of 10.4 g/L at a temperature of 35° C. was used. Using a trapezoidal rectangular waveform AC having a time tp, until the current value reached a peak from zero, of 0.8 msec and the duty ratio of 1:1 as the AC power source waveform, the electrochemical roughening treatment was performed using a carbon electrode as a counter electrode. As an auxiliary anode, ferrite was used. The current density was 30 A/dm² as the peak current value, and 5% of the current from the power source was separately flowed to the auxiliary anode. The electric quantity was 185 C/dm² as the sum total of electric quantity at the time of anodization of the aluminum plate. Thereafter, washing with water by spraying was performed.

(e) Alkali Etching Treatment

The aluminum plate was subjected to an etching treatment by spraying a caustic soda aqueous solution in which the concentration of caustic soda was 5% by mass and the concentration of aluminum ions was 0.5% by mass using a spray tube at a temperature of 50° C. Thereafter, washing with water by spraying was performed. The amount of aluminum dissolved was 0.5 g/m².

(f) Desmutting Treatment in Acidic Aqueous Solution

Next, a desmutting treatment was performed in a sulfuric acid aqueous solution. As the sulfuric acid aqueous solution used in the desmutting treatment, a solution in which the concentration of sulfuric acid was 170 g/L and the concentration of aluminum ions was 5 g/L was used. The solution temperature was 60° C. The desmutting treatment was performed for 3 seconds by spraying the desmutting liquid using a spray.

(g) Electrochemical Roughening Treatment

An electrochemical roughening treatment was continuously performed using an AC voltage of 60 Hz. An electrolyte which had been adjusted to have a concentration of aluminum ions of 4.5 g/L by adding aluminum chloride to a hydrochloric acid aqueous solution having a concentration of 6.2 g/L at a solution temperature of 35° C. was used. Using a trapezoidal rectangular waveform AC having a time tp, until the current value reached a peak from zero, of 0.8 msec and the duty ratio of 1:1 as the AC power source waveform, the electrochemical roughening treatment was performed using a carbon electrode as a counter electrode. As an auxiliary anode, ferrite was used. The current density was 25 A/dm² as the peak current value, and the electric quantity in the hydrochloric acid electrolysis was 63 C/dm² as the sum total of electric quantity at the time of anodization of the aluminum plate. Thereafter, washing with water by spraying was performed.

(h) Alkali Etching Treatment

The aluminum plate was subjected to an etching treatment by spraying a caustic soda aqueous solution in which the concentration of caustic soda was 5% by mass and the concentration of aluminum ions was 0.5% by mass using a spray tube at a temperature of 50° C. Thereafter, washing with water by spraying was performed. The amount of aluminum dissolved was 0.1 g/m².

(i) Desmutting Treatment in Acidic Aqueous Solution

Next, a desmutting treatment was performed in a sulfuric acid aqueous solution. The desmutting treatment was performed at a solution temperature of 35° C. for 4 seconds using the sulfuric acid aqueous solution (aluminum ions having a concentration of 5 g/L were contained in a sulfuric acid aqueous solution having a concentration of 170 g/L) used for the anodizing treatment step. The desmutting treatment was performed for 3 seconds by spraying the desmutting liquid using a spray.

(j) First Anodizing Treatment

A first step of an anodizing treatment was performed with an anodizing device using DC electrolysis. An anodized film having a predetermined film thickness was formed by performing an anodizing treatment under conditions listed in Table B. An aqueous solution containing components listed in Table B was used as the electrolyte. In Tables B to D, the “component concentration” indicates the concentration (g/L) of each component described in the column of “liquid component”.

TABLE B
First anodizing treatment

| | | Component | | | | Film |
|---|---|---|---|---|---|---|
| | | con- | Tem- | Current | | thick- |
| Liquid | Liquid | centration | perature | density | Time | ness |
| type | component | (g/L) | (° C.) | (A/dm²) | (s) | (nm) |
| Sulfuric | H₂SO₄/Al | 170/5 | 55 | 90 | 0.40 | 110 |
| acid | | | | | | |

(k) Second Anodizing Treatment

A second step of an anodizing treatment was performed with an anodizing device using DC electrolysis. An anodized film having a predetermined film thickness was formed by performing an anodizing treatment under conditions listed in Table C. An aqueous solution containing components listed in Table C was used as the electrolyte.

TABLE C
Second anodizing treatment

| | | | | | | Film |
|---|---|---|---|---|---|---|
| | Liquid | Component | Temperature | Current density | Time | thickness |
| Liquid type | component | concentration (g/L) | (° C.) | (A/dm²) | (s) | (nm) |
| Sulfuric acid | H₂SO₄/Al | 170/5 | 54 | 15 | 13 | 900 |

(l) Third Anodizing Treatment

A third step of an anodizing treatment was performed with an anodizing device using DC electrolysis. An anodized film having a predetermined film thickness was formed by performing an anodizing treatment under conditions listed in Table D. An aqueous solution containing components listed in Table D was used as the electrolyte.

TABLE D
Third anodizing treatment

| | | Component | | | | Film |
|---|---|---|---|---|---|---|
| | Liquid | concentration | Temperature | Current density | Time | thickness |
| Liquid type | component | (g/L) | (° C.) | (A/dm²) | (s) | (nm) |
| Sulfuric acid | H₂SO₄/Al | 170/5 | 54 | 50 | 0.4 | 100 |

(m) Hydrophilization Treatment

In order to ensure hydrophilicity of a non-image area, the non-image area was subjected to a silicate treatment by being dipped in 2.5% by mass of a No. 3 sodium silicate aqueous solution at 50° C. for 7 seconds. The adhesion amount of Si was 8.5 mg/m². Thereafter, washing with water by spraying was performed.

The average diameter (average diameter of surface layer) of a large-diameter hole portion on the surface of the anodized film having micropores obtained in the above-described manner, the average diameter (average diameter of bottom portion) of the large-diameter hole portion in a communication position, the average diameter (diameter of small-diameter hole portion) of a small-diameter hole portion in the communication position, the average depth of the large-diameter hole portion and the small-diameter hole portion, the thickness (thickness of barrier layer) of the anodized film from the bottom portion of the small-diameter hole portion to the surface of the aluminum plate, the density of the small-diameter hole portion, and the like are listed in Table E. The small-diameter hole portion includes a first small-diameter hole portion and a second small-diameter hole portion with depths different from each other and a small-diameter hole portion which is deeper than the other is referred to as the first small-diameter hole portion.

TABLE E
(part 1)
Micropores
Large-diameter hole portion

| Average | Average | | | | |
|---|---|---|---|---|---|
| diameter | diameter | | | | |
| of surface | of bottom | Average | Average depth/ | Average depth/ | |
| layer | portion | depth | Average diameter of | Average diameter of | |
| (nm) | (nm) | (nm) | surface layer | bottom portion | Shape |
| 12 | 25 | 98 | 8.2 | 3.9 | Reversely |
| | | | | | tapered shape |

(part 2)
Micropores

| Small-diameter hole portion | | | | | | | |
|---|---|---|---|---|---|---|---|
| | | Density of | Average | Minimum | Density of | | Ratio (Average diameter |
| Average | | communication | thickness of | thickness of | micropores | Increase | of surface layer/Diameter |
| diameter | Average | portion | barrier layer | barrier layer | (pieces/ | magnification | of small-diameter hole |
| (nm) | depth (nm) | (pieces/μm²) | (nm) | (nm) | pieces/μm²) | of surface area | portion) |
| 9.8 | 888, 968 | 800 (650) | 17 | 16 | 500 | 4.0 | 1.22 |

In Table E, the average value and the minimum value of the barrier layer thickness are shown. The average value is obtained by measuring 50 thicknesses of the anodized film from the bottom portion of the first small-diameter hole portion to the surface of the aluminum plate and arithmetically averaging the values.

The average diameter of micropores (average diameter of large-diameter hole portion and small-diameter hole portion) is a value obtained by observing four sheets (N=4) of the surfaces of the large-diameter hole portion and the surfaces of the small-diameter hole portion using FE-SEM at a magnification of 150,000, measuring the diameters of micropores (the large-diameter hole portion and the small-diameter hole portion) present in a range of 400×600 nm² in the obtained images of four sheets, and averaging the values. Further, in a case where the depth of the large-diameter hole portion is deep and the diameter of the small-diameter hole portion is unlikely to be measured, the upper portion of the anodized film is cut and then various kinds of diameters are acquired.

The average depth of the large-diameter hole portion is a value obtained by observing the cross section of the support (anodized film) using FE-TEM at a magnification of 500,000, measuring 60 cases (N=60) of distances from the surface of an arbitrary micropore to the communication position in the obtained image, and averaging the values. Further, the average depth of the small-diameter hole portion is a value obtained by observing the cross section of the support (anodized film) using FE-SEM (at a magnification of 50,000), measuring 25 depths of arbitrary micropores in the obtained image, and averaging the values.

The “density of the communication portion” indicates the density of the small-diameter hole portion of the cross section of the anodized film in the communication position. The “increase magnification of the surface area” indicates the value calculated based on the following Equation (A).

Increase magnification of surface area=1+pore density′((π×(average diameter of surface layer/2+average diameter of bottom portion/2)×((average diameter of bottom portion/2−average diameter of surface layer/2)²+depth A²)^{1/2}+π×(average diameter of bottom portion/2)²−π×(average diameter of surface layer/2)²)) Equation (A)

In the column of the “average depth (nm)” of the small-diameter hole portion, the average depth of the second small-diameter hole portion is shown on the left side and the average depth of the first small-diameter hole portion is shown on the right side. In the column of the “density of communication portion” of the small-diameter hole portion in Table E, the density of the first small-diameter hole portion is shown in parentheses together with the density of the communication portion of the small-diameter hole portion.

In addition, the average diameter of the first small-diameter hole portion positioning from the bottom portion of the second small-diameter hole portion to the bottom portion of the first small-diameter hole portion was approximately 12 nm.

### Example 1

<Formation of Back Coat Layer>

(Preparation of Back Coat Layer Coating Solution (1))
Polyvinyl alcohol (PVA-405, manufactured by KURARAY CO., LTD., 212.03 g saponification degree: 81.5 mol %, degree of polymerization: 500), 6% by mass of aqueous solution
SOMASIF MEB-3, manufactured by Katakura Chikkarin Co., Ltd., 8% by mass of aqueous solution: 11.61 g

The components were mixed and stirred, thereby a back coat layer coating solution (1) was prepared.

The surface of the support 1 on the back coat layer side (non-printing surface side) was bar-coated with the back coat layer coating solution (1) with the composition described above and dried at 100° C. for 120 seconds, thereby forming a back coat layer having a thickness of 1.2 μm.

<Formation of Undercoat Layer>

The other surface (printing surface side) of the support 1 was coated with an undercoat layer coating solution (1) with the following composition such that the drying coating amount thereof reached 20 mg/m², thereby forming an undercoat layer.

(Undercoat Layer Coating Solution (1))
Compound for undercoat layer (UC-1) (the following structure) 0.18 g
Hydroxyethyl imino diacetic acid 0.05 g
Surfactant (EMALEX 710, manufactured by Nihon Emulsion Co., Ltd.) 0.03 g
Water 28.0 g

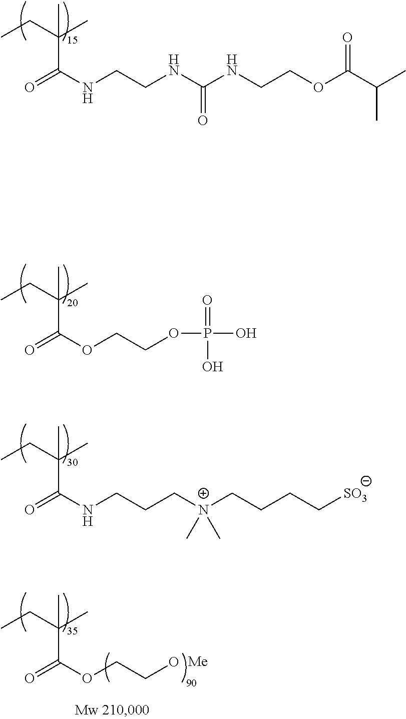

compound for undercoat layer (UC-1)

<Formation of Image Recording Layer>

An undercoat layer of the support including a back coat layer and an undercoat layer was bar-coated with an image recording layer coating solution (2) with the following composition and dried in an oven at 70° C. for 60 seconds to form an image recording layer (polymer-containing layer 1) having a drying coating amount of 0.6 g/m², thereby producing a planographic printing plate precursor.

(Image Recording Layer Coating Solution (2))
Thermoplastic polymer particles aqueous dispersion liquid (described below) 20.0 g
Infrared absorbent (2) (the following structure) 0.2 g
Polymerization initiator (IRGACURE 250, manufactured by Ciba Specialty Chemicals, Inc.) 0.4 g
Polymerization initiator (2) (the following structure) 0.15 g
Polymerizable compound SR-399 (manufactured by Sartomer Japan Inc.) 1.50 g
Mercapto-3-triazole 0.2 g
Byk336 (manufactured by BYK Chemie GmbH) 0.4 g
Klucel M (manufactured by Hercules, Inc.) 4.8 g
ELVACITE 4026 (manufactured by Ineos Acrylics Ltd.) 2.5 g
Anionic surfactant 1 (the following structure) 0.15 g
n-propanol 55.0 g
2-butanone 17.0 g

The compounds described with the trade names in the composition above as follows.
IRGACURE 250: (4-methylphenyl)[4-(2-methylpropyl)phenyl]iodonium=hexafluorophosphate (75% by mass propylene carbonate solution)
SR-399: dipentaerythritolpentaacrylate
Byk336: modified dimethyl polysiloxane copolymer (25% by mass xylene/methoxy propyl acetate solution)
Klucel M: hydroxypropyl cellulose (2% by mass of aqueous solution)
ELVACITE 4026: highly branched polymethyl methacrylate (10% by mass 2-butanone solution)

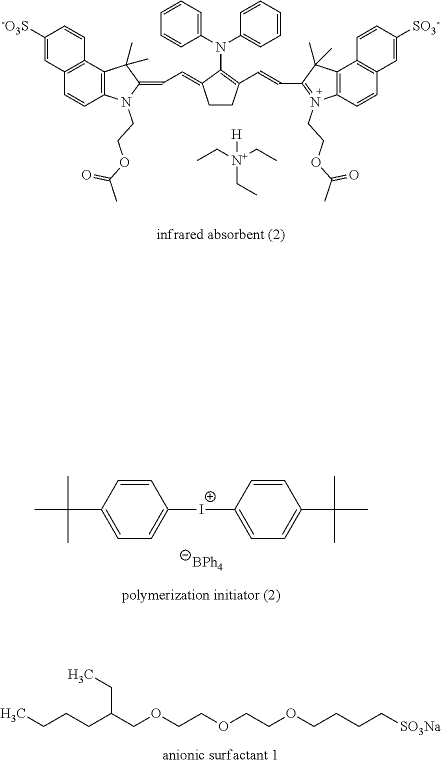

(Production of Thermoplastic Polymer Particles Aqueous Dispersion Liquid)

Nitrogen gas was introduced into a 1,000 ml four-necked flask equipped with a stirrer, a thermometer, a dropping funnel, a nitrogen introduction pipe, and a reflux condenser, deoxygenation was performed, 10 g of polyethylene glycol methyl ether methacrylate (PEGMA, average number of repeating units of ethylene glycol: 20), 200 g of distilled water, and 200 g of n-propanol were added thereto, and then the mixture was heated until the internal temperature thereof was set to 70° C. Next, a mixture of 10 g of styrene (St), 80 g of acrylonitrile (AN), and 0.8 g of 2,2′-azobisisobutyronitrile prepared in advance was added dropwise thereto for 1 hour. After dropwise addition was finished, the reaction was allowed to be continued for 5 hours, 0.4 g of 2,2′-azobisisobutyronitrile was added thereto, and the mixture was heated until the internal temperature was set to 80° C. Subsequently, 0.5 g of 2,2′-azobisisobutyronitrile was added for 6 hours. The total degree of polymerization at the step of the continued reaction for 20 hours was 98% or greater, and a thermoplastic polymer particles aqueous dispersion liquid having PEGMA, St, and AN at a mass ratio of 10/10/80 was obtained. The particle size distribution of the thermoplastic polymer particles has a maximum value at 150 nm of the volume average particle diameter.

Here, the particle size distribution was acquired by imaging an electron micrograph of polymer particles, measuring the total number of 5,000 particle diameters of particles on the photograph, dividing the interval from the maximum value of the obtained measured value of the particle diameter to 0 into the logarithmic scale of 50, and plotting the appearance frequency of each particle diameter. Further, as a non-spherical particle, the particle diameter of a spherical particle having the same particle area as the particle area of the non-spherical particle on the photograph was set to the particle diameter.

### Example 2

A back coat layer, an undercoat layer, and an image recording layer were formed in the same manner as in Example 1 except that the back coat layer coating solution (1) of Example 1 was changed to a back coat layer coating solution (2), thereby a planographic printing plate precursor was produced.

(Preparation of Back Coat Layer Coating Solution (2))
Polyvinyl alcohol (PVA-405, manufactured by KURARAY CO., LTD., 212.03 g saponification degree: 81.5 mol %, degree of polymerization: 500), 6% by mass of aqueous solution
SUMECTON-SWF, manufactured by Kunimine Industries Co., Ltd.: 0.93 g

The components were mixed and stirred, thereby a back coat layer coating solution (2) was prepared.

### Examples 3 to 9

Back coat layers, undercoat layers, and image recording layers were formed in the same manner as in Example 2 except that the tabular particles in the back coat layer coating solution (2) of Example 2 were changed to the tabular particles listed in Table 1, thereby producing planographic printing plate precursors.

### Example 10

A back coat layer, an undercoat layer, and an image recording layer were formed in the same manner as in Example 1 except that the back coat layer coating solution (1) of Example 1 was changed to a back coat layer coating solution (10), thereby a planographic printing plate precursor was produced.

(Preparation of Back Coat Layer Coating Solution (10))
Polystyrene (manufactured by Wako Pure Chemical Industries, Ltd., degree of polymerization: 2000): 12.71 g
SUMECTON-SAN, manufactured by Kunimine Industries Co., Ltd.: 0.93 g
Ethyl acetate 85.43 g

The components were mixed and stirred, thereby a back coat layer coating solution (10) was prepared.

### Example 11

A back coat layer, an undercoat layers, and an image recording layers were formed in the same manner as in Example 10 except that the tabular particles in the back coat layer coating solution (10) of Example 10 were changed to the tabular particles listed in Table 1, thereby producing a planographic printing plate precursor.

### Example 12

A back coat layer, an undercoat layer, and an image recording layer were formed in the same manner as in Example 1 except that the back coat layer coating solution (1) of Example 1 was changed to a back coat layer coating solution (12), thereby a planographic printing plate precursor was produced.

(Preparation of Back Coat Layer Coating Solution (12))
Polyvinyl alcohol (manufactured by Kuraray Co., Ltd.), KURARAY POVAL LM-20 (the following chemical formula): 12.71 g
SUMECTON-SEN, manufactured by Kunimine Industries Co., Ltd.: 0.93 g
Methanol 85.43 g

The components were mixed and stirred, thereby a back coat layer coating solution (12) was prepared.

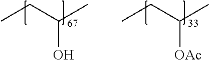

### Example 13

A back coat layer, an undercoat layer, and an image recording layer were formed in the same manner as in Example 1 except that the back coat layer coating solution (1) of Example 1 was changed to a back coat layer coating solution (13), thereby a planographic printing plate precursor was produced.

(Preparation of Back Coat Layer Coating Solution (13))
Methyl methacrylate/methacrylic acid copolymer, Mw=40000 (the following structure): 12.71 g (MMA/MMA copolymer)
SOMASIF MEE, manufactured by Katakura Chikkarin Co., Ltd.: 0.93 g
2-butanone 76.89 g
1-methoxy-2-propanol 8.54 g

The components were mixed and stirred, thereby a back coat layer coating solution (13) was prepared.

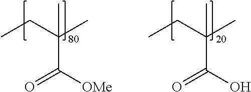

### Examples 14 to 20

Back coat layers, undercoat layers, and image recording layers were formed in the same manner as in Example 13 except that the thickness of the back coat layer, the kind of the tabular particles in the back coat layer coating solution (1), and the amount of the tabular particles to be added in Example 13 were changed as listed in Table 1, thereby producing planographic printing plate precursors.

### Example 21

A back coat layer, an undercoat layer, and an image recording layer were formed in the same manner as in Example 1 except that the back coat layer coating solution (1) of Example 1 was changed to a back coat layer coating solution (21), thereby a planographic printing plate precursor was produced.

(Preparation of Back Coat Layer Coating Solution (21))
Tetraethyl silicate (metal oxide) 50 parts by mass
Water 20 parts by mass
Methanol 15 parts by mass
Phosphoric acid 0.05 parts by mass

After the above-described components were mixed and stirred, heat generation was started in approximately 5 minutes. The mixture was reacted for 60 minutes, and a liquid described below was added thereto, thereby preparing a back coat layer coating solution (21).
Pyrogallol-formaldehyde condensation resin (Mw: 2000) 4 parts by mass
Dimethyl phthalate 5 parts by mass
Fluorine-based surfactant (N-butyl perfluorooctane sulfonamide ethyl acrylate/polyoxyethylene acrylate copolymer (Mw: 20000)) 0.7 parts by mass
SUMECTON-STN, manufactured by Kunimine Industries Co., Ltd. 80 parts by mass
Methanol 800 parts by mass

### Examples 22 to 25

Back coat layers, undercoat layers, and image recording layers were formed in the same manner as in Example 21 except that the thickness of the back coat layer and the amount of the tabular particles added to the back coat layer coating solution (21) in Example 21 were changed as listed in Table 1, thereby producing planographic printing plate precursors.

[Production of Example 26]

A back coat layer, an undercoat layer, and an image recording layer were formed in the same manner as in Example 1 except that the back coat layer coating solution (1) of Example 1 was changed to a back coat layer coating solution (26), thereby a planographic printing plate precursor was produced.

(Preparation of Back Coat Layer Coating Solution (26))
Tetraethyl silicate 50 parts by mass
Water 20 parts by mass
Methanol 15 parts by mass
Phosphoric acid 0.05 parts by mass

After the above-described components were mixed and stirred, heat generation was started in approximately 5 minutes. The mixture was reacted for 60 minutes, and a liquid described below was added thereto, thereby preparing a back coat layer coating solution (26).
Pyrogallol-formaldehyde condensation resin (Mw: 2000) 4 parts by mass
Dimethyl phthalate 5 parts by mass
Fluorine-based surfactant (N-butyl perfluorooctane sulfonamide ethyl acrylate/polyoxyethylene acrylate copolymer (Mw: 20000)) 0.7 parts by mass
Silica-coated acrylic resin particles ART PEARL J-7P (particles other than tabular particles), manufactured by Negami Chemical Industrial Co., Ltd. 25 parts by mass
SUMECTON-STN, manufactured by Kunimine Industries Co., Ltd.: 50 parts by mass
Methanol 800 parts by mass

[Production of Example 27]

A back coat layer, an undercoat layers, and an image recording layers were formed in the same manner as in Example 26 except that the kind of the particles other than the tabular particles in the back coat layer coating solution (26) of Example 26 were changed as listed in Table 1, thereby producing a planographic printing plate precursor.

As the particles other than the tabular particles, SILYSIA 440 (manufactured by Fuji Silysia Chemical Ltd.) was used.

### Example 28

A back coat layer, an undercoat layer, and an image recording layer were formed in the same manner as in Example 1 except that the back coat layer coating solution (1) of Example 1 was changed to a back coat layer coating solution (28), thereby a planographic printing plate precursor was produced.

(Preparation of Back Coat Layer Coating Solution (28))
Methyl methacrylate/methacrylic acid copolymer, Mw=40000 (the following structure): 12.71 g
SUMECTON-STN, manufactured by Kunimine Industries Co., Ltd.: 0.93 g
Silica-coated melamine resin particles OPTBEADS 3500M, manufactured by Nissan Chemical Industries, Ltd.: 0.47 g

(Particles Other than Tabular Particles)
2-butanone 76.89 g
1-methoxy-2-propanol 8.54 g

The components were mixed and stirred, thereby a back coat layer coating solution (28) was prepared.

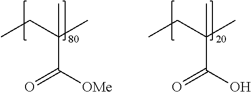

### Examples 29 to 36

Back coat layers, undercoat layers, and image recording layers were formed in the same manner as in Example 28 except that the thickness of the back coat layer, the amount of the tabular particles added to the back coat layer coating solution (28), the kind of particles other than the tabular particles, and the amount of the particles to be added in Example 28 were changed as listed in Table 1, thereby producing planographic printing plate precursors.

The particles other than the tabular particles are described below.

TOSPEARL 145 (manufactured by Momentive Performance Materials Japan LLC)

ART PEARL J-6PF (manufactured by Negami Chemical Industrial Co., Ltd.)

OPTBEADS 6500M (manufactured by Nissan Chemical Industries, Ltd.)

### Example 37

The surface of the support 2 on the back coat layer side (non-printing surface side) was bar-coated with the back coat layer coating solution of Example 17 and dried at 100° C. for 120 seconds, thereby forming a back coat layer having a thickness of 1.2 Gm.

<Formation of Image Recording Layer>

An image recording layer aqueous coating solution containing thermoplastic polymer particles, an infrared absorbent, and polyacrylic acid described below was prepared, the pH thereof was adjusted to 3.6, and the surface of the support 2 on the printing surface side was coated with the coating solution and dried at 50° C. for 1 minute to form and produce an image recording layer. The coating amount after the drying of each component is shown below.

Thermoplastic polymer particles: 0.7 g/m²

Infrared absorbent IR-01: 1.20×10⁻⁴ g/m²

Polyacrylic acid: 0.09 g/m²

The thermoplastic polymer particles, the infrared absorbent IR-01, and the polyacrylic acid used for the image recording layer coating solution are as follows.

Thermoplastic polymer particles: styrene-acrylonitrile copolymer (molar ratio of 50:50), Tg: 99° C., volume average particle diameter: 60 nm

Infrared absorbent IR-01: infrared absorbent having the following structure

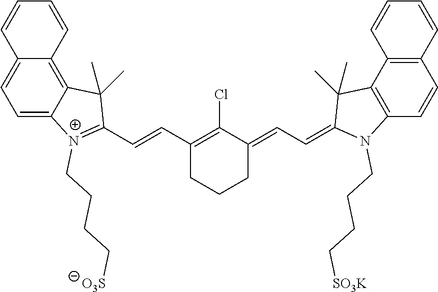

Polyacrylic acid Mw: 250,000

### Example 38

The surface of the support 3 on the back coat layer side (non-printing surface side) was bar-coated with the back coat layer coating solution of Example 17 and dried at 100° C. for 120 seconds, thereby forming a back coat layer having a thickness of 1.2 Gm.

<Formation of Undercoat Layer>

The surface of the support 3 on the printing surface side was coated with the undercoat layer coating solution (1) such that the drying coating amount thereof reached 20 mg/m², thereby forming an undercoat layer.

The undercoat layer was bar-coated with an image recording layer coating solution (3) with the following composition and dried in an oven at 1000 for 60 seconds, thereby forming an image recording layer having a drying coating amount of 1.0 g/m².

The image recording layer coating solution (3) was obtained by mixing a photosensitive solution (1) and a microgel solution (1) described below immediately before the coating and then stirring the solution.

(Image Recording Layer Coating Solution (3))

(Photosensitive Solution (1))
Binder polymer (1) (the following structure, Mw: 55,000 and n (number of ethylene oxide (EO) repeating units): 2): 0.240 parts
Infrared absorbent (1) (the following structure): 0.020 parts
Borate compound (1) (Sodium tetraphenylborate): 0.010 parts
Polymerization initiator (1) (the following structure): 0.162 parts
Polymerizable compound (tris(acryloyloxyethyl) isocyanurate, NK ESTER A-9300, manufactured by Shin-Nakamura Chemical Co., Ltd.): 0.192 parts
Anionic surfactant 1 (the above-described structure): 0.050 parts
Fluorine-based surfactant (1) (the following structure): 0.008 parts
2-butanone: 1.091 parts
1-methoxy-2-propanol: 8.609 parts

(Microgel Solution (1))
Microgel (1): 2.640 parts
Distilled water: 2.425 parts

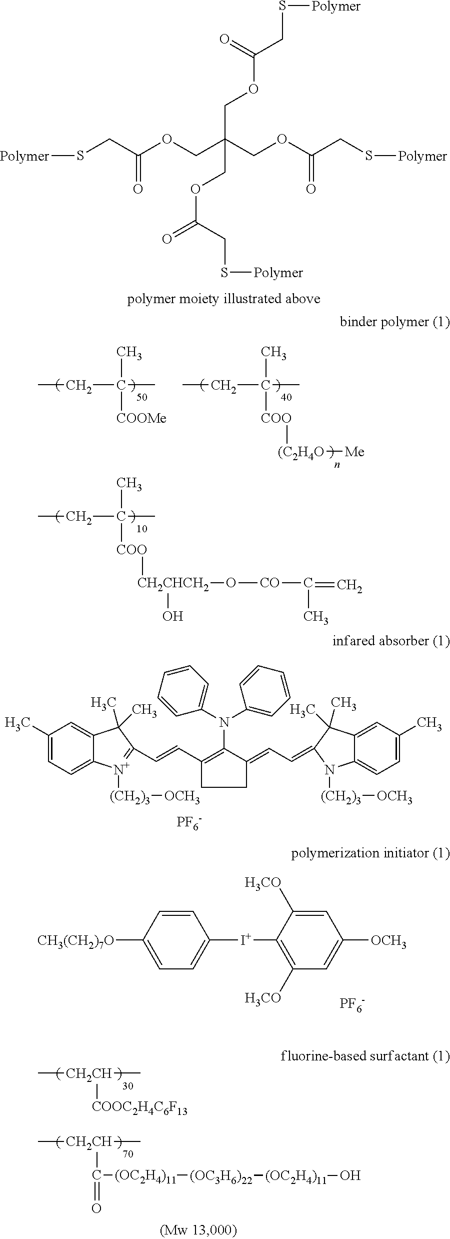

(Production of Microgel (1))

A method of preparing a microgel (1) used for the microgel solution will be described below.

<Preparation of Polyvalent Isocyanate Compound (1)>

0.043 parts of bismuth tris(2-ethylhexanoate) (NEOSTANN U-600, manufactured by NITTO KASEI CO., LTD.) was added to an ethyl acetate (25.31 parts) suspension solution of 17.78 parts (80 molar equivalent) of isophorone diisocyanate and 7.35 parts (20 molar equivalent) of the following polyhydric phenol compound (1), and the solution was stirred. The reaction temperature was set to 50° C. at the time of heat generation being subsided, and the solution was stirred for 3 hours, thereby obtaining an ethyl acetate solution (50% by mass) of a polyvalent isocyanate compound (1).

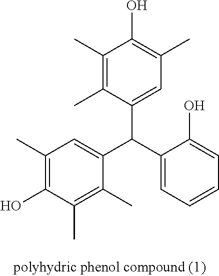 [SMILES: Cc1cc(C(c2ccccc2O)c2cc(C)c(O)c(C)c2C)c(C)c(C)c1O]

<Preparation of Microgel (1)>

The following oil phase components and the water phase component were mixed with each other and emulsified at 12,000 rpm for 10 minutes using a homogenizer. The obtained emulsion was stirred at 45° C. for 4 hours, 5.20 parts of a 10% by mass of aqueous solution of 1,8-diazabicyclo[5.4.0]undeca-7-ene-octylate (U-CAT SA102, manufactured by San-Apro Ltd.) was added thereto, and the solution was stirred at room temperature for 30 minutes and allowed to stand at 45° C. for 24 hours. The concentration of solid contents was adjusted to 20% by mass using distilled water, thereby obtaining an aqueous dispersion liquid of the microgel (1). The volume average particle diameter was measured using a dynamic light scattering type particle size distribution measuring device LB-500 (manufactured by Horiba Ltd.) according to a light scattering method, and the value was 0.28 μm.

(Oil Phase Components)
(Component 1) ethyl acetate: 12.0 parts
(Component 2) adduct (50% by mass of ethyl acetate solution, manufactured by Mitsui Chemicals, Inc.) obtained by adding trimethylolpropane (6 mol) and xylene diisocyanate (18 mol) and adding methyl one-terminal polyoxyethylene (1 mol, repetition number of oxyethylene units: 90) thereto: 3.76 parts
(Component 3) polyvalent isocyanate compound (1) (as 50% by mass of ethyl acetate solution): 15.0 parts
(Component 4) 65% by mass of solution of dipentaerythritol pentaacrylate (SR-399, manufactured by Sartomer Japan Inc.) in ethyl acetate: 11.54 parts
(Component 5) 10% solution of sulfonate type surfactant (PIONINE A-41-C, manufactured by TAKEMOTO OIL & FAT Co., Ltd.) in ethyl acetate: 4.42 parts

(Water Phase Component)

Distilled water: 46.87 parts

<Formation of Protective Layer>

The image recording layer was bar-coated with a protective layer coating solution (1) with the following composition and dried in an oven at 1200 for 60 seconds to form a protective layer having a drying coating amount of 0.15 g/m², thereby producing a planographic printing plate precursor.

(Protective Layer Coating Solution (1))
Inorganic layered compound dispersion liquid (1) (described below) 1.5 g
Hydrophilic polymer (1) (the following structure, Mw: 30,000) (solid content) 0.03 g
Polyvinyl alcohol (CKS50, manufactured by Nippon Synthetic Chemical Industry Co., Ltd., 0.10 g sulfonic acid-modified, saponification degree: 99 mol % or greater, degree of polymerization: 300) 6% by mass of aqueous solution
Polyvinyl alcohol (PVA-405, manufactured by KURARAY CO., LTD., 0.03 g saponification degree: 81.5 mol %, degree of polymerization: 500), 6% by mass of aqueous solution
Surfactant (EMALEX 710, the following structure, manufactured by Nihon Emulsion Co., Ltd.) (the following structure) 1% by mass of aqueous solution: 0.86 g
Ion exchange water 6.0 g

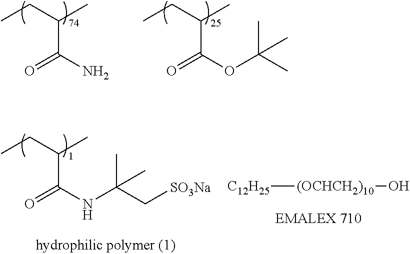

(Preparation of Inorganic Layered Compound Dispersion Liquid (1))

6.4 g of synthetic mica Somasif ME-100 (manufactured by CO-OP CHEMICAL CO., LTD.) was added to 193.6 g of ion exchange water and dispersed such that the volume average particle diameter (laser scattering method) was set to 3 rpm using a homogenizer. The aspect ratio of the obtained dispersed particles was 100 or greater.

### Examples 39

<Formation of Undercoat Layer>

The surface of the support 3 having the back coat layer used for production of Example 38 on the printing surface side was coated with an undercoat layer coating solution (2) with the following composition using a wire bar and dried at 90° C. for 30 seconds. The coating amount thereof was 10 mg/m².

(Undercoat Layer Coating Solution (2))
Polymer compound A (the following structure) (mass average molecular weight: 30,000) 0.05 g
Methanol 27 g
Ion exchange water 3 g

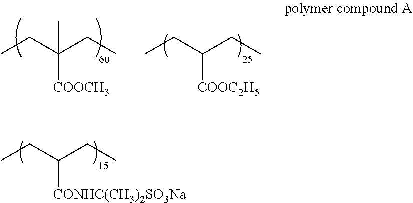

<Formation of Image Recording Layer>

The undercoat layer was coated with the image recording layer coating solution (4) with the following composition using a wire bar and dried at 115° C. for 34 seconds using a hot air dryer. The coating amount after the drying was 1.4 g/m².

(Image Recording Layer Coating Solution (4))
Infrared absorbent (IR-1) (the following structure) 0.074 g
Polymerization initiator (OS-12) (the following structure) 0.280 g
Additive (PM-1) (the following structure) 0.151 g
Polymerizable compound (AM-1) (the following structure) 1.00 g
Binder polymer (BT-1) (the following structure) 1.00 g
Ethyl violet (C-1) (the following structure) 0.04 g
Fluorine-based surfactant 0.015 g (MEGAFACE F-780-F, manufactured by DIC Corporation, 30% by mass of solution of methyl isobutyl ketone (MIBK)
Methyl ethyl ketone 10.4 g
Methanol 4.83 g
1-methoxy-2-propanol 10.4 g

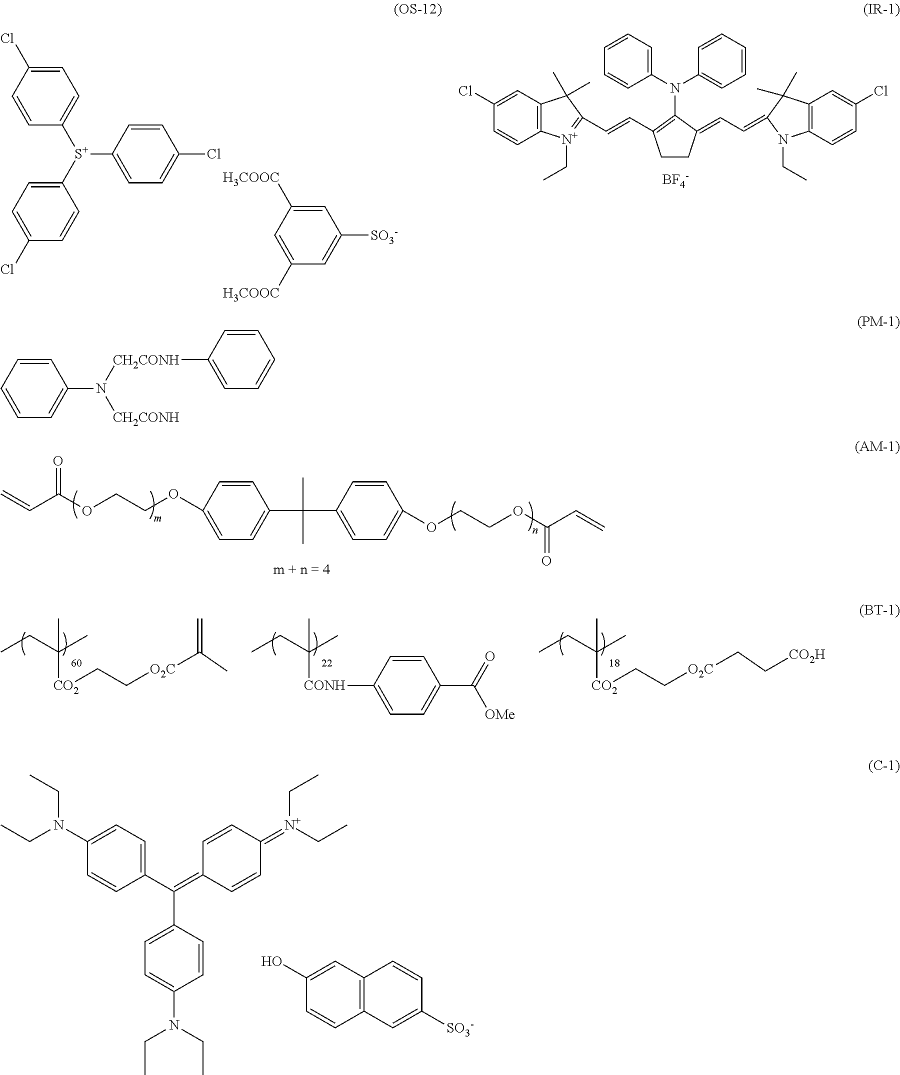

<Formation of Protective Layer>

The image recording layer was coated with the protective layer coating solution (2) with the following composition using a wire bar and dried at 125° C. for 75 seconds using a hot air dryer, thereby forming a protective layer. The coating amount after the drying was 1.6 g/m². In this manner, a negative type planographic printing plate precursor of Example 39 was produced.

<Protective Layer Coating Solution (2)>
Synthetic mica (SOMASIF ME-100, manufactured by CO-OP CHEMICAL CO., LTD., 8% aqueous dispersion liquid) 94 g
Polyvinyl alcohol (CKS-50, manufactured by Nippon Synthetic Chemical Industry Co, Ltd., degree of saponification of 99 mol %, degree of polymerization of 300) 58 g
Carboxy methyl cellulose (CELOGEN PR, manufactured by DKS Co., Ltd.) 24 g
Surfactant-1 (PLURONIC P-84, manufactured by BASF SE) 2.5 g
Surfactant-2 (EMALEX 710, manufactured by Nihon Emulsion Co., Ltd.) 5 g
Pure water 1364 g

### Example 40

<Formation of Undercoat Layer>

The surface of the support 3 having the back coat layer used for production of Example 38 on the printing surface side was coated with an undercoat layer coating solution (3) with the following composition using a bar coater and dried at 80° C. for 15 seconds, thereby forming an undercoat layer having a coating amount of 18 mg/m² after the drying of the solution.

(Undercoat Layer Coating Solution (3))

Polymer compound (the following structure) 0.3 g
Methanol 100 g

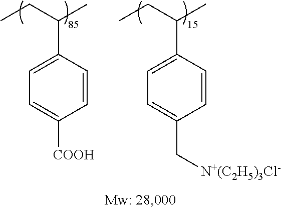

<Formation of Image Recording Layer>

The undercoat layer was coated with an underlayer coating solution with the following composition using a bar coater such that the coating amount after the drying was set to 0.85 g/m², dried at 160° C. for 44 seconds, and immediately cooled with cold air in a temperature range of 17° C. to 20° C. until the temperature of the support was set to 35° C., thereby forming an underlayer. Thereafter, the underlayer was coated with an upper layer coating solution with the following composition using a bar coater such that the coating amount after the drying was set to 0.22 g/m², dried at 148° C. for 25 seconds, and gradually cooled with air in a temperature range of 20° C. to 26° C., thereby forming an upper layer. In this manner, a positive type planographic printing plate precursor of Example 40 was produced.

(Underlayer Coating Solution)
N-(4-aminosulfonylphenyl)methacrylamide/acrylonitrile/methyl methacrylate 2.1 g (36/34/30% by mass: mass average molecular weight of 50000, acid value of 2.65)
m,p-cresol novolac 0.1 g (m/p ratio=6/4, mass average molecular weight of 4500, containing 0.8% by mass of unreacted cresol, Tg: 75° C.)
Cyanine dye A (the following structure) 0.13 g
4,4′-bishydroxyphenylsulfone 0.13 g
Tetrahydrophthalic anhydride 0.19 g
p-toluenesulfonic acid 0.008 g
3-methoxy-4-diazodiphenylamine hexafluorophosphate 0.032 g
Dye obtained by changing counter ion of ethyl violet into 6-hydroxy-2-naphthalenesulfonic acid 0.078 g
Fluorine-based surfactant B (the following structure) 0.007 g
Methyl ethyl ketone 25.0 g
1-methoxy-2-propanol 13.0 g
γ-butyrolactone 13.0 g

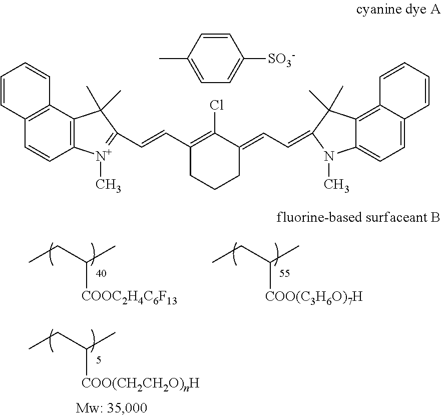

(Upper Layer Coating Solution)
Phenol/m-cresol/p-cresol novolac 0.35 g
   (molar ratio=5/3/2, mass average molecular weight: 5000, content of unreacted cresol: 1.2% by mass, Tg: 70° C.)
Acrylic resin C (the following structure) 0.042 g
Cyanine dye A (the above structure) 0.019 g
Ammonium compound D (the following structure) 0.004 g
Sulfonium compound G (the following structure) 0.032 g
Fluorine-based surfactant B (the above structure) 0.0045 g
Fluorine-based surfactant E (the following structure) 0.0033 g
Fluorine-based polymer F (the following structure) 0.018 g
Methyl ethyl ketone 10.0 g
1-methoxy-2-propanol 20.0 g

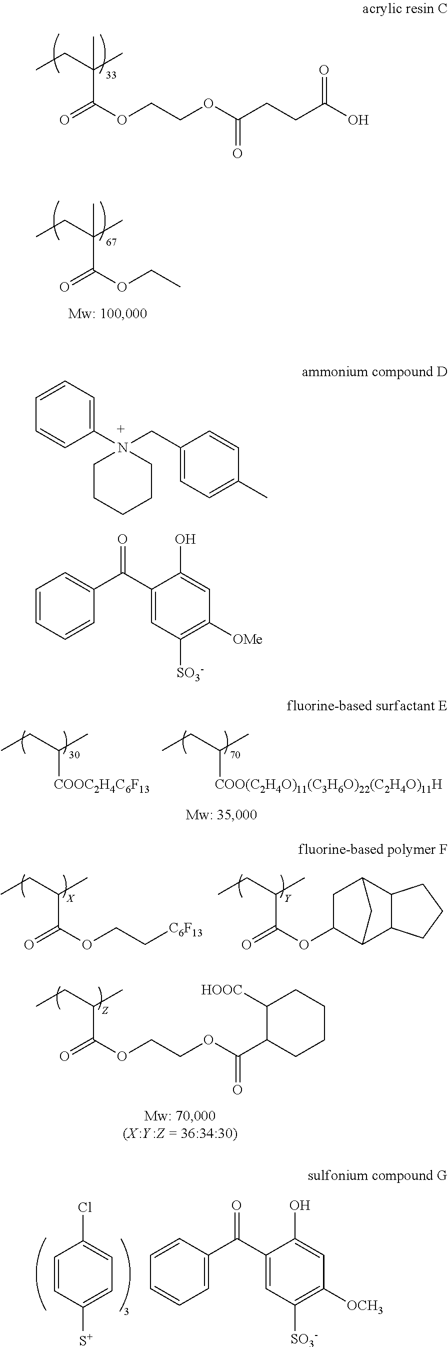

### Example 41

<Formation of Undercoat Layer>

The surface of the support 3 having the back coat layer used for production of Example 38 on the printing surface side was coated with an undercoat layer coating solution (4) with the following composition using a bar coater and dried at 80° C. for 15 seconds, thereby forming an undercoat layer having a coating amount of 18 mg/m² after the drying of the solution.

<Undercoat Layer Coating Solution (4)>
Polymer (the following structure) 0.3 parts by mass
Pure water 60.0 parts by mass
Methanol 939.7 parts by mass

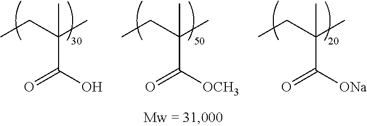

<Formation of Non-Photosensitive Layer>

The undercoat layer was bar-coated with a non-photosensitive layer coating solution (1) with the following composition and dried at 100° C. for 60 seconds, thereby forming a non-photosensitive layer. The coating amount after the drying was 1.0 mg/m².

(Non-Photosensitive Layer Coating Solution (1))
Binder polymer A (described below) 2.465 parts by mass
Phosphoric acid (85% by mass of aqueous solution) 0.08 parts by mass
Sulfophthalic acid (50% by mass of aqueous solution) 0.017 parts by mass
Tricarballylic acid 0.017 parts by mass
Colorant (VPB-Naps (naphthalene sulfonate of Victoria Pure Blue, manufactured by Hodogaya Chemical Co., Ltd.) 0.0014 parts by mass
Fluorine-based surfactant (MEGAFACE F-780-F, manufactured by DIC Corporation, 30% by mass of solution of MEK) 0.009 parts by mass
Methyl ethyl ketone (MEK) 7.93 parts by mass
Methanol 6.28 parts by mass
1-methoxy-2-propanol (MFG) 2.01 parts by mass

The binder polymer A is a 16% by mass of solution having MFG and MEK at a mixing ratio of 1:1 for a condensation reaction product (mass average molecular weight: 85,000, acid content: 1.64 meq/g) of four types of monomers (1) to (4) described below.

(1) 4,4-diphenylmethane diisocyanate 37.5 mol %
(2) hexamethylene diisocyanate 12.5 mol %
(3) 2,2-bis(hydroxymethyl)propionic acid 32.5 mol %
(4) tetraethylene glycol 17.5 mol %

<Formation of Hydrophilic Layer>

The non-photosensitive layer was bar-coated with a hydrophilic layer coating solution (1) having the following composition and dried at 125° C. for 75 seconds, thereby forming a hydrophilic layer. The coating amount after the drying was 1.6 mg/m². In this manner, a printing key plate precursor of Example 41 was produced.

(Hydrophilic Layer Coating Solution (1))
Synthetic mica (SOMASIF ME-100, manufactured by CO-OP CHEMICAL CO., LTD., 8% aqueous dispersion liquid) 94 parts by mass
Polyvinyl alcohol (CKS-50, manufactured by Nippon Synthetic Chemical Industry Co, Ltd., degree of saponification: 99 mol %, degree of polymerization: 300) 58 parts by mass
Carboxy methyl cellulose (CELOGEN PR, manufactured by DKS Co., Ltd.) 24 parts by mass
Surfactant-1 (PLURONIC P-84, manufactured by BASF SE) 2.5 parts by mass
Surfactant-2 (EMALEX 710, manufactured by Nihon Emulsion Co., Ltd.) 5 parts by mass
Pure water 1364 parts by mass

PLURONIC P-84 described above is an ethylene oxide-propylene oxide block copolymer and EMALEX 710 is a polyoxyethylene lauryl ether.

### Example 42

<Formation of Undercoat Layer>

A printing key plate precursor of Example 42 was produced in the same manner as in the production of Example 38 except that the infrared absorbent (1) and the polymerization initiator (1) were removed from the image recording layer coating solution (3).

### Examples 43 to 48

Planographic printing plate precursors of Examples 43 to 46 and printing key plate precursors of Examples 47 and 48 were produced by adding ART PEARL J-6PF to each back coat layer of Examples 37 to 42 as particles other than the tabular particles listed in Table 1.

### Comparative Examples 1 to 6

Planographic printing plate precursors of Comparative Example 1, Comparative Example 2, Comparative Example 3, Comparative Example 4, Comparative Example 5, and Comparative Example 6 were respectively produced by coating each back coat layer with each back coat layer coating solution of Example 1, Example 10, Example 12, Example 13, Example 22, and Example 26, from which the tabular particles had been removed.

### Comparative Example 7

A back coat layer was formed to produce a planographic printing plate precursor in the same manner as in Example 1 except that the back coat layer coating solution of the back coat layer of Example 1 was changed to the back coat layer coating solution (107).

(Preparation of Back Coat Layer Coating Solution (107))
Styrene-methyl methacrylate copolymer 12.71 g
SILYSIA 436, manufactured by Fuji Silysia Chemical Ltd. 0.93 g
2-butanone 85.43 g

### Comparative Examples 8 to 14

In Comparative Examples 8 to 14, planographic printing plate precursors of Comparative Examples 8 to 12 and printing key plate precursors of Comparative Examples 13 and 14 were respectively produced in the same manner as described above except that the tabular particles were removed from each back coat layer of Examples 37 to 42.

[Evaluation of Printing Plate Precursor]

The printing plate precursors (the planographic printing plate precursors and the printing key plate precursors) obtained in each example and each comparative example were evaluated in the following manner.

<Scratch Resistance>

The scratch resistance was evaluated by performing a scratch test on the plate surface of the printing plate precursor on the back coat layer side. In other words, the scratch test was performed by applying a load of 10 to 100 g on the back coat layer of the printing plate precursor by increasing 10 g each time using a continuous load type scratch strength tester (SB-53, manufactured by Shinto Scientific Co., Ltd.) under conditions of a sapphire needle having a diameter of 0.1 mm and a needle moving speed of 10 cm/sec, the load of occurrence of scratches was visually observed, and the scratch resistance was evaluated based on the following standards. The value of 3 is a practical lower limit level and the value of 2 or less is a practically unacceptable level.

5: The back coat layer was not scratched even at a load of 100 g.

4: The back coat layer was scratched at a load of 80 to 100 g.

3: The back coat layer was scratched at a load of 50 to 70 g.

2: The back coat layer was scratched at a load of 20 to 40 g.

1: The back coat layer was scratched at a load of 10 g.

<Abrasion Resistance>

After the humidity of the printing plate precursor was adjusted in an environment of 25° at 60% RH for 2 hours, the precursor was punched into a size of 2.5 cm×2.5 cm and attached to a continuous load type scratch resistance strength tester TYPE: 18 (manufactured by Shinto Scientific Co., Ltd.), the printing surface side of the punched printing plate precursor was set on the surface of the back coat layer of the printing plate precursor which had not been punched such that the printing surface side thereof was brought into contact with the surface of the back coat layer, and several sites of the printing plate precursor were damaged at a load of 0 to 1000 gf. The degree of damage to the back coat layer was visually observed. The evaluation was performed based on the following standard. The value of 3 is a practical lower limit level and the value of 2 or less is a practically unacceptable level.

5: Peeling was not found.

4: Although peeling was not visually confirmed, peeling which was able to be confirmed using a 50 magnification loupe was found at one site.

3: Although peeling was not visually confirmed, peeling which was able to be confirmed using a 50 magnification loupe was found at several sites.

2: Peeling which was able to be visually confirmed was found at several sites.

1: Peeling was found at several sites over the entire surface.

<Measurement of Arithmetic Average Height Sa of Layer Containing Tabular Particles>

The arithmetic average height Sa of the layer containing tabular particles was measured in conformity with the method described in ISO 25178. In other words, three or more sites were selected from the same sample using MICROMAP MM3200-M100 (manufactured by Mitsubishi Chemical Systems, Inc.), the heights thereof were measured, and the average value thereof was set as the arithmetic average height Sa. As the measurement range, a range with a size of 1 cm×1 cm randomly selected from the sample surface was measured.

The evaluation results were listed in Table 1.

TABLE 1

| | | | | Non-printing surface side | | | | | | |
|---|---|---|---|---|---|---|---|---|---|---|
| | | Printing surface side | | | | | Tabular particles | | | |
| | | Layer | | Layer component | | | | | Thick- | As- |
| | Support | containing | Protective | | | Thickness | | | ness | pect |
| | Type | polymer | layer | Type | Detail | (nm) | Type | Detail | (nm) | ratio |
| Example 1 | 1 | Layer 1 | None | PVA-405 | Polyvinyl | 1.2 | SOMASIF MEB-3 | Mica | 10 | 300 |
| | | | | | alcohol | | | | | |
| Example 2 | 1 | Layer 1 | None | PVA-405 | Polyvinyl | 1.2 | SUMECTON-SWF | Smectite | 1 | 50 |
| | | | | | alcohol | | | | | |
| Example 3 | 1 | Layer 1 | None | PVA-405 | Polyvinyl | 1.2 | SUMECTON-SWN | Smectite | 1 | 50 |
| | | | | | alcohol | | | | | |
| Example 4 | 1 | Layer 1 | None | PVA-405 | Polyvinyl | 1.2 | SUMECTON-ST | Smectite | 1 | 50 |
| | | | | | alcohol | | | | | |
| Example 5 | 1 | Layer 1 | None | PVA-405 | Polyvinyl | 1.2 | SUMECTON-SA | Smectite | 1 | 50 |
| | | | | | alcohol | | | | | |
| Example 6 | 1 | Layer 1 | None | PVA-405 | Polyvinyl | 1.2 | MOISTNITE-U | Bentonite | 1 | 100 |
| | | | | | alcohol | | | | | |
| Example 7 | 1 | Layer 1 | None | PVA-405 | Polyvinyl | 1.2 | MOISTNITE-S | Bentonite | 1 | 100 |
| | | | | | alcohol | | | | | |
| Example 8 | 1 | Layer 1 | None | PVA-405 | Polyvinyl | 1.2 | MOISTNITE-HC | Bentonite | 1 | 100 |
| | | | | | alcohol | | | | | |
| Example 9 | 1 | Layer 1 | None | PVA-405 | Polyvinyl | 1.2 | KUNIPIA-F | Bentonite | 1 | 100 |
| | | | | | alcohol | | | | | |
| Example 10 | 1 | Layer 1 | None | Polystyrene | Polystyrene | 1.2 | SUMECTON-SAN | Organic | 1 | 50 |
| | | | | | | | | smectite | | |
| Example 11 | 1 | Layer 1 | None | Polystyrene | Polystyrene | 1.2 | KUNIPIS-110 | Organic | 1 | 100 |
| | | | | | | | | bentonite | | |
| Example 12 | 1 | Layer 1 | None | LM-20 | Polyvinyl | 1.2 | SUMECTON-SEN | Organic | 1 | 50 |
| | | | | | alcohol | | | smectite | | |
| Example 13 | 1 | Layer 1 | None | MMA/MAA | MMA/MAA | 1.2 | SOMASIF MEE | Organic | 10 | 300 |
| | | | | copolymer | copolymer | | | mica | | |
| Example 14 | 1 | Layer 1 | None | MMA/MAA | MMA/MAA | 1.2 | SOMASIF MTE | Organic | 10 | 300 |
| | | | | copolymer | copolymer | | | mica | | |
| Example 15 | 1 | Layer 1 | None | MMA/MAA | MMA/MAA | 1.2 | SOMASIF MAE | Organic | 10 | 300 |
| | | | | copolymer | copolymer | | | mica | | |
| Example 16 | 1 | Layer 1 | None | MMA/MAA | MMA/MAA | 1.2 | SUMECTON-STN | Organic | 1 | 50 |
| | | | | copolymer | copolymer | | | smectite | | |
| Example 17 | 1 | Layer 1 | None | MMA/MAA | MMA/MAA | 1.2 | SUMECTON-STN | Organic | 1 | 50 |
| | | | | copolymer | copolymer | | | smectite | | |
| Example 18 | 1 | Layer 1 | None | MMA/MAA | MMA/MAA | 1.2 | SUMECTON-STN | Organic | 1 | 50 |
| | | | | copolymer | copolymer | | | smectite | | |
| Example 19 | 1 | Layer 1 | None | MMA/MAA | MMA/MAA | 1.2 | SUMECTON-STN | Organic | 1 | 50 |
| | | | | copolymer | copolymer | | | smectite | | |
| Example 20 | 1 | Layer 1 | None | MMA/MAA | MMA/MAA | 1.5 | SUMECTON-STN | Organic | 1 | 50 |
| | | | | copolymer | copolymer | | | smectite | | |
| Example 21 | 1 | Layer 1 | None | Metal oxide | Metal oxide | 1.2 | SUMECTON-STN | Organic | 1 | 50 |
| | | | | | | | | smectite | | |
| Example 22 | 1 | Layer 1 | None | Metal oxide | Metal oxide | 1.5 | SUMECTON-STN | Organic | 1 | 50 |
| | | | | | | | | smectite | | |
| Example 23 | 1 | Layer 1 | None | Metal oxide | Metal oxide | 1.5 | SUMECTON-STN | Organic | 1 | 50 |
| | | | | | | | | smectite | | |
| Example 24 | 1 | Layer 1 | None | Metal oxide | Metal oxide | 1.5 | SUMECTON-STN | Organic | 1 | 50 |
| | | | | | | | | smectite | | |
| Example 25 | 1 | Layer 1 | None | Metal oxide | Metal oxide | 1.5 | SUMECTON-STN | Organic | 1 | 50 |
| | | | | | | | | smectite | | |
| Example 26 | 1 | Layer 1 | None | Metal oxide | Metal oxide | 1.5 | SUMECTON-STN | Organic | 1 | 50 |
| | | | | | | | | smectite | | |
| Example 27 | 1 | Layer 1 | None | Metal oxide | Metal oxide | 1.5 | SUMECTON-STN | Organic | 1 | 50 |
| | | | | | | | | smectite | | |
| Example 28 | 1 | Layer 1 | None | MMA/MAA | MMA/MAA | 1.2 | SUMECTON-STN | Organic | 1 | 50 |
| | | | | copolymer | copolymer | | | smectite | | |
| Example 29 | 1 | Layer 1 | None | MMA/MAA | MMA/MAA | 1.2 | SUMECTON-STN | Organic | 1 | 50 |
| | | | | copolymer | copolymer | | | smectite | | |
| Example 30 | 1 | Layer 1 | None | MMA/MAA | MMA/MAA | 1.2 | SUMECTON-STN | Organic | 1 | 50 |
| | | | | copolymer | copolymer | | | smectite | | |
| Example 31 | 1 | Layer 1 | None | MMA/MAA | MMA/MAA | 1.2 | SUMECTON-STN | Organic | 1 | 50 |
| | | | | copolymer | copolymer | | | smectite | | |
| Example 32 | 1 | Layer 1 | None | MMA/MAA | MMA/MAA | 1.2 | SUMECTON-STN | Organic | 1 | 50 |
| | | | | copolymer | copolymer | | | smectite | | |
| Example 33 | 1 | Layer 1 | None | MMA/MAA | MMA/MAA | 1.2 | SUMECTON-STN | Organic | 1 | 50 |
| | | | | copolymer | copolymer | | | smectite | | |
| Example 34 | 1 | Layer 1 | None | MMA/MAA | MMA/MAA | 1.2 | SUMECTON-STN | Organic | 1 | 50 |
| | | | | copolymer | copolymer | | | smectite | | |
| Example 35 | 1 | Layer 1 | None | MMA/MAA | MMA/MAA | 2 | SUMECTON-STN | Organic | 1 | 50 |
| | | | | copolymer | copolymer | | | smectite | | |
| Example 36 | 1 | Layer 1 | None | MMA/MAA | MMA/MAA | 2 | SUMECTON-STN | Organic | 1 | 50 |
| | | | | copolymer | copolymer | | | smectite | | |
| Example 37 | 2 | Layer 2 | None | MMA/MAA | MMA/MAA | 1.2 | SUMECTON-STN | Organic | 1 | 50 |
| | | | | copolymer | copolymer | | | smectite | | |
| Example 38 | 3 | Layer 3 | Formed | MMA/MAA | MMA/MAA | 1.2 | SUMECTON-STN | Organic | 1 | 50 |
| | | | | copolymer | copolymer | | | smectite | | |
| Example 39 | 3 | Layer 4 | Formed | MMA/MAA | MMA/MAA | 1.2 | SUMECTON-STN | Organic | 1 | 50 |
| | | | | copolymer | copolymer | | | smectite | | |
| Example 40 | 3 | Layer 5 | Formed | MMA/MAA | MMA/MAA | 1.2 | SUMECTON-STN | Organic | 1 | 50 |
| | | | | copolymer | copolymer | | | smectite | | |
| Example 41 | 3 | Layer 6 | Formed | MMA/MAA | MMA/MAA | 1.2 | SUMECTON-STN | Organic | 1 | 50 |
| | | | | copolymer | copolymer | | | smectite | | |
| Example 42 | 3 | Layer 7 | Formed | MMA/MAA | MMA/MAA | 1.2 | SUMECTON-STN | Organic | 1 | 50 |
| | | | | copolymer | copolymer | | | smectite | | |
| Example 43 | 2 | Layer 2 | None | MMA/MAA | MMA/MAA | 1.2 | SUMECTON-STN | Organic | 1 | 50 |
| | | | | copolymer | copolymer | | | smectite | | |
| Example 44 | 3 | Layer 3 | Formed | MMA/MAA | MMA/MAA | 1.2 | SUMECTON-STN | Organic | 1 | 50 |
| | | | | copolymer | copolymer | | | smectite | | |
| Example 45 | 3 | Layer 4 | Formed | MMA/MAA | MMA/MAA | 1.2 | SUMECTON-STN | Organic | 1 | 50 |
| | | | | copolymer | copolymer | | | smectite | | |
| Example 46 | 3 | Layer 5 | Formed | MMA/MAA | MMA/MAA | 1.2 | SUMECTON-STN | Organic | 1 | 50 |
| | | | | copolymer | copolymer | | | smectite | | |
| Example 47 | 3 | Layer 6 | Formed | MMA/MAA | MMA/MAA | 1.2 | SUMECTON-STN | Organic | 1 | 50 |
| | | | | copolymer | copolymer | | | smectite | | |
| Example 48 | 3 | Layer 7 | Formed | MMA/MAA | MMA/MAA | 1.2 | SUMECTON-STN | Organic | 1 | 50 |
| | | | | copolymer | copolymer | | | smectite | | |
| Comparative | 1 | Layer 1 | None | PVA-405 | Polyvinyl | 1.2 | None | | | |
| Example 1 | | | | | alcohol | | | | | |
| Comparative | 1 | Layer 1 | None | Polystyrene | Polystyrene | 1.2 | None | | | |
| Example 2 | | | | | | | | | | |
| Comparative | 1 | Layer 1 | None | LM-20 | Polyvinyl | 1.2 | None | | | |
| Example 3 | | | | | alcohol | | | | | |
| Comparative | 1 | Layer 1 | None | MMA/MAA | MMA/MAA | 1.2 | None | | | |
| Example 4 | | | | copolymer | copolymer | | | | | |
| Comparative | 1 | Layer 1 | None | Metal oxide | Metal oxide | 1.5 | None | | | |
| Example 5 | | | | | | | | | | |
| Comparative | 1 | Layer 1 | None | Metal oxide | Metal oxide | 1.5 | None | | | |
| Example 6 | | | | | | | | | | |
| Comparative | 1 | Layer 1 | None | Styrene-methyl | Styrene-methyl | 1.2 | None | | | |
| Example 7 | | | | methacrylate | methacrylate | | | | | |
| | | | | copolymer | copolymer | | | | | |
| Comparative | 2 | Layer 2 | None | MMA/MAA | MMA/MAA | 1.2 | None | | | |
| Example 8 | | | | copolymer | copolymer | | | | | |
| Comparative | 3 | Layer 3 | Formed | MMA/MAA | MMA/MAA | 1.2 | None | | | |
| Example 9 | | | | copolymer | copolymer | | | | | |
| Comparative | 3 | Layer 4 | Formed | MMA/MAA | MMA/MAA | 1.2 | None | | | |
| Example 10 | | | | copolymer | copolymer | | | | | |
| Comparative | 3 | Layer 5 | Formed | MMA/MAA | MMA/MAA | 1.2 | None | | | |
| Example 12 | | | | copolymer | copolymer | | | | | |
| Comparative | 3 | Layer 6 | Formed | MMA/MAA | MMA/MAA | 1.2 | None | | | |
| Example 13 | | | | copolymer | copolymer | | | | | |
| Comparative | 3 | Layer 7 | Formed | MMA/MAA | MMA/MAA | 1.2 | None | | | |
| Example 14 | | | | copolymer | copolymer | | | | | |

| | Non-printing surface side | | | | | | Evaluation | | |
|---|---|---|---|---|---|---|---|---|---|
| | Tabular | | | | | | result | | |
| | particles | Particles other than tablular particles | | | | | | | Abra- |
| | Addition | | | | | Addition | | Scratch | sion |
| | amount | | | Thickness | Aspect | amount | | resist- | resist- |
| | (mg/m²) | Type | Detail | (nm) | ratio | (mg/m²) | Sa | ance | ance |
| Example 1 | 100 | None | | | | | 0.15 | 4 | 4 |
| Example 2 | 100 | None | | | | | 0.15 | 4 | 4 |
| Example 3 | 100 | None | | | | | 0.15 | 4 | 4 |
| Example 4 | 100 | None | | | | | 0.15 | 4 | 4 |
| Example 5 | 100 | None | | | | | 0.15 | 4 | 4 |
| Example 6 | 100 | None | | | | | 0.15 | 4 | 4 |
| Example 7 | 100 | None | | | | | 0.15 | 4 | 4 |
| Example 8 | 100 | None | | | | | 0.15 | 4 | 4 |
| Example 9 | 100 | None | | | | | 0.15 | 4 | 4 |
| Example 10 | 100 | None | | | | | 0.15 | 4 | 4 |
| Example 11 | 100 | None | | | | | 0.15 | 4 | 4 |
| Example 12 | 100 | None | | | | | 0.15 | 4 | 4 |
| Example 13 | 100 | None | | | | | 0.15 | 4 | 4 |
| Example 14 | 100 | None | | | | | 0.15 | 4 | 4 |
| Example 15 | 100 | None | | | | | 0.15 | 4 | 4 |
| Example 16 | 10 | None | | | | | 0.15 | 3 | 3 |
| Example 17 | 100 | None | | | | | 0.15 | 4 | 4 |
| Example 18 | 300 | None | | | | | 0.15 | 5 | 5 |
| Example 19 | 500 | None | | | | | 0.15 | 5 | 5 |
| Example 20 | 100 | None | | | | | 0.15 | 4 | 4 |
| Example 21 | 100 | None | | | | | 0.15 | 4 | 4 |
| Example 22 | 10 | None | | | | | 0.15 | 3 | 3 |
| Example 23 | 100 | None | | | | | 0.15 | 4 | 4 |
| Example 24 | 300 | None | | | | | 0.15 | 5 | 5 |
| Example 25 | 500 | None | | | | | 0.15 | 5 | 5 |
| Example 26 | 100 | ART PEARL | Silica-coated | 6 | 1 | 50 | 4.2 | 5 | 5 |
| | | J-7P | acrylic | | | | | | |
| Example 27 | 100 | SILYSIA 440 | Silica | 6 | 1.4 | 50 | 4.2 | 5 | 5 |
| Example 28 | 100 | OPTBEADS | Silica-coated | 3.5 | 1 | 50 | 1.2 | 5 | 5 |
| | | 3500M | melamine | | | | | | |
| Example 29 | 100 | TOSPEARL | Methyl | 4.5 | 1 | 50 | 1.7 | 5 | 5 |
| | | 145 | group- | | | | | | |
| | | | modified | | | | | | |
| | | | silica | | | | | | |
| Example 30 | 10 | ART PEARL | Acrylic | 4 | 1 | | 1.4 | 3 | 3 |
| | | 6PF | | | | | | | |
| Example 31 | 100 | ART PEARL | Acrylic | 4 | 1 | | 1.4 | 5 | 5 |
| | | 6PF | | | | | | | |
| Example 32 | 300 | ART PEARL | Acrylic | 4 | 1 | | 1.4 | 5 | 5 |
| | | 6PF | | | | | | | |
| Example 33 | 500 | ART PEARL | Acrylic | 4 | 1 | | 1.4 | 5 | 5 |
| | | 6PF | | | | | | | |
| Example 34 | 100 | ART PEARL | Acrylic | 4 | 1 | | 1.7 | 4 | 4 |
| | | 6PF | | | | | | | |
| Example 35 | 100 | ART PEARL | Silica-coated | 6 | 1 | | 2 | 5 | 5 |
| | | J-7P | acrylic | | | | | | |
| Example 36 | 100 | OPTBEADS | Silica-coated | 6.5 | 1 | | 2.5 | 5 | 5 |
| | | 3500M | melamine | | | | | | |
| Example 37 | 100 | None | | | | | 0.15 | 4 | 4 |
| Example 38 | 100 | None | | | | | 0.15 | 4 | 4 |
| Example 39 | 100 | None | | | | | 0.15 | 4 | 4 |
| Example 40 | 100 | None | | | | | 0.15 | 4 | 4 |
| Example 41 | 100 | None | | | | | 0.15 | 4 | 4 |
| Example 42 | 100 | None | | | | | 0.15 | 4 | 4 |
| Example 43 | 100 | ART PEARL | Acrylic | 4 | 1 | 100 | 1.5 | 5 | 5 |
| | | 6PF | | | | | | | |
| Example 44 | 100 | ART PEARL | Acrylic | 4 | 1 | 100 | 1.5 | 5 | 5 |
| | | 6PF | | | | | | | |
| Example 45 | 100 | ART PEARL | Acrylic | 4 | 1 | 100 | 1.5 | 5 | 5 |
| | | 6PF | | | | | | | |
| Example 46 | 100 | ART PEARL | Acrylic | 4 | 1 | 100 | 1.5 | 5 | 5 |
| | | 6PF | | | | | | | |
| Example 47 | 100 | ART PEARL | Acrylic | 4 | 1 | 100 | 1.5 | 5 | 5 |
| | | 6PF | | | | | | | |
| Example 48 | 100 | ART PEARL | Acrylic | 4 | 1 | 100 | 1.5 | 5 | 5 |
| | | 6PF | | | | | | | |
| Comparative | | None | | | | | 0.1 | 1 | 1 |
| Example 1 | | | | | | | | | |
| Comparative | | None | | | | | 0.1 | 1 | 1 |
| Example 2 | | | | | | | | | |
| Comparative | | None | | | | | 0.1 | 1 | 1 |
| Example 3 | | | | | | | | | |
| Comparative | | None | | | | | 0.1 | 1 | 1 |
| Example 4 | | | | | | | | | |
| Comparative | | None | | | | | 0.1 | 1 | 1 |
| Example 5 | | | | | | | | | |
| Comparative | | ART PEARL | Silica-coated | 6 | 1 | 50 | 2.5 | 2 | 2 |
| Example 6 | | J-7P | acrylic | | | | | | |
| Comparative | | SILYSIA 436 | Silica gel | 4 | 1.4 | 40 | 1.5 | 2 | 2 |
| Example 7 | | | | | | | | | |
| Comparative | | None | | | | | 0.1 | 2 | 2 |
| Example 8 | | | | | | | | | |
| Comparative | | None | | | | | 0.1 | 2 | 2 |
| Example 9 | | | | | | | | | |
| Comparative | | None | | | | | 0.1 | 2 | 2 |
| Example 10 | | | | | | | | | |
| Comparative | | None | | | | | 0.1 | 2 | 2 |
| Example 12 | | | | | | | | | |
| Comparative | | None | | | | | 0.1 | 2 | 2 |
| Example 13 | | | | | | | | | |
| Comparative | | None | | | | | 0.1 | 2 | 2 |
| Example 14 | | | | | | | | | |

<Production of Supports 4 to 12>

Each aluminum plate (aluminum alloy plate) formed of the material 1S with a thickness of 0.3 mm was subjected to any of the following treatments, thereby producing supports 4 to 12. Moreover, during all treatment steps, a water washing treatment was performed, and liquid cutting was performed using a nip roller after the water washing treatment.

<Treatment A: Production of Supports 4 to 6>

(A-a) Alkali Etching Treatment

The aluminum plate was subjected to an etching treatment by spraying a caustic soda aqueous solution in which the concentration of caustic soda was 26% by mass and the concentration of aluminum ions was 6.5% by mass using a spray at a temperature of 70° C. Thereafter, washing with water by spraying was performed. The dissolved aluminum amount of the surface to be subjected to an electrochemical roughening treatment was 5 g/m².

(A-b) Desmutting Treatment Using Acidic Aqueous Solution

Next, a desmutting treatment was performed using an acidic aqueous solution. Specifically, the desmutting treatment was performed for 3 seconds by spraying the acidic aqueous solution to an aluminum plate using a spray. The acidic aqueous solution used in the desmutting treatment was an aqueous solution having a sulfuric acid concentration of 150 g/L. The solution temperature was 30° C.

(A-c) Electrochemical Roughening Treatment Using Hydrochloric Acid Aqueous Solution

Next, an electrochemical roughening treatment was performed using the AC current and an electrolyte having a hydrochloric acid concentration of 14 g/L, an aluminum ion concentration of 13 g/L, and a sulfuric acid concentration of 3 g/L. The solution temperature of the electrolyte was 30° C. The aluminum ion concentration was adjusted by adding aluminum chloride.

The waveform of the AC current was a sine wave in which the positive and negative waveforms were symmetrical, the frequency was 50 Hz, the ratio between the anodic reaction time and the cathodic reaction time in one cycle of the AC current was 1:1, and the current density was 75 A/dm² in terms of the peak current value of the AC current waveform. Further, the sum total of electric quantity of the aluminum plate used for the anodic reaction was 450 C/dm², and the electrolytic treatment was performed four times at energization intervals of 4 seconds for each of the electric quantity of 112.5 C/dm². A carbon electrode was used as a counter electrode of the aluminum plate. Thereafter, a water washing treatment was performed.

(A-d) Alkali Etching Treatment

The aluminum plate after the electrochemical roughening treatment was subjected to an etching treatment by spraying a caustic soda aqueous solution in which the concentration of caustic soda was 5% by mass and the concentration of aluminum ions was 0.5% by mass using a spray tube at a temperature of 45° C. Thereafter, washing with water by spraying was performed. The dissolved aluminum amount of the surface to be subjected to an electrochemical roughening treatment was 0.2 g/m².

(A-e) Desmutting Treatment Using Acidic Aqueous Solution

Next, a desmutting treatment was performed using an acidic aqueous solution. Specifically, the desmutting treatment was performed for 3 seconds by spraying the acidic aqueous solution to an aluminum plate using a spray. As the acidic aqueous solution used for the desmutting treatment, a waste liquid generated in the anodizing treatment step (an aqueous solution having a sulfuric acid concentration of 170 g/L and an aluminum ion concentration of 5 g/L) was used. The solution temperature was 30° C.

(A-f) Anodizing Treatment

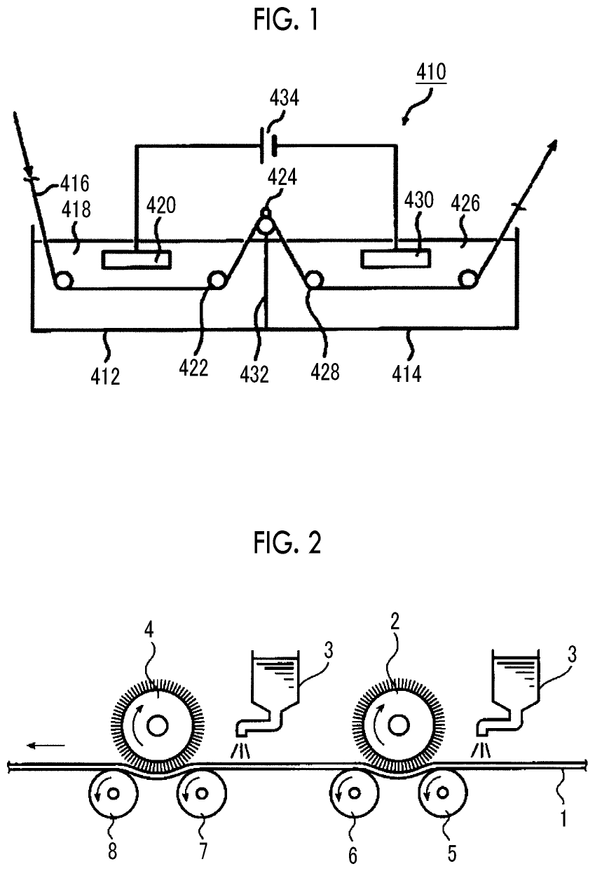

An anodizing treatment was performed with an anodizing device using DC electrolysis having the structure shown in FIG. 1. An anodized film having a predetermined coating amount was formed by performing an anodizing treatment under conditions in the columns of “first anodizing treatment” listed in Table F.

An aluminum plate 416 in an anodizing device 410 illustrated in FIG. 1 is transported as indicated by the arrow in FIG. 1. The aluminum plate 416 is positively (+) charged by a power supply electrode 420 in a power supply tank 412 in which an electrolyte 418 is stored. Further, the aluminum plate 416 is transported upward by a roller 422 in the power supply tank 412, redirected downward by a nip roller 424, transported toward an electrolytic treatment tank 414 in which an electrolyte 426 was stored, and redirected to the horizontal direction by a roller 428. Next, the aluminum plate 416 is negatively (−) charged by an electrolytic electrode 430 so that an anodized film is formed on the surface thereof, and the aluminum plate 416 coming out of the electrolytic treatment tank 414 is transported to the next step. In the anodizing device 410, direction changing means is formed of the roller 422, the nip roller 424, and the roller 428. The aluminum plate 416 is transported in a mountain shape and an inverted U shape by the roller 422, the nip roller 424, and the roller 428 in an inter-tank portion between the power supply tank 412 and the electrolytic treatment tank 414. The power supply electrode 420 and the electrolytic electrode 430 are connected to a DC power source 434.

TABLE F

| | First anodizing treatment | | | | |
|---|---|---|---|---|---|
| | | | Tem- | | |
| | Sulfuric acid | Phosphoric acid | pera- | Current | Coating |
| | concentration of | concentration of | ture | density | amount |
| Support | electrolyte (g/l) | electrolyte (g/l) | (° C.) | (A/dm²) | (g/m²) |
| Support 7 | 170 | — | 50 | 30 | 0.3 |

(A-g) Pore Widening Treatment

The aluminum plate after having been subjected to the anodizing treatment was subjected to a pore widening treatment by being immersed in a caustic soda aqueous solution in which the concentration of caustic soda was 5% by mass and the concentration of aluminum ions was 0.5% by mass at a temperature listed in Table G under a time condition listed in Table G. Thereafter, washing with water by spraying was performed.

TABLE G

| | Pore widening treatment | |
|---|---|---|
| | Temperature | Time |
| Support | (° C.) | (second) |
| Support 4 | 28 | 3 |
| Support 5 | 40 | 3 |
| Support 6 | 40 | 15 |

<Treatment (B): Production of Support 7>

(B-a) Alkali Etching Treatment

The aluminum plate was subjected to an etching treatment by spraying a caustic soda aqueous solution in which the concentration of caustic soda was 26% by mass and the concentration of aluminum ions was 6.5% by mass using a spray at a temperature of 70° C. Thereafter, washing with water by spraying was performed. The dissolved aluminum amount of the surface to be subjected to an electrochemical roughening treatment was 5 g/m².

(B-b) Desmutting Treatment Using Acidic Aqueous Solution

Next, a desmutting treatment was performed using an acidic aqueous solution. Specifically, the desmutting treatment was performed for 3 seconds by spraying the acidic aqueous solution to an aluminum plate using a spray. The acidic aqueous solution used in the desmutting treatment was an aqueous solution having a sulfuric acid concentration of 150 g/L. The solution temperature was 30° C.

(B-c) Electrochemical Roughening Treatment Using Hydrochloric Acid Aqueous Solution

Next, an electrochemical roughening treatment was performed using the AC current and an electrolyte having a hydrochloric acid concentration of 14 g/L, an aluminum ion concentration of 13 g/L, and a sulfuric acid concentration of 3 g/L. The solution temperature of the electrolyte was 30° C. The aluminum ion concentration was adjusted by adding aluminum chloride.

The waveform of the AC current was a sine wave in which the positive and negative waveforms were symmetrical, the frequency was 50 Hz, the ratio between the anodic reaction time and the cathodic reaction time in one cycle of the AC current was 1:1, and the current density was 75 A/dm² in terms of the peak current value of the AC current waveform. Further, the total electric quantity of the aluminum plate used for the anodic reaction was 450 C/dm², and the electrolytic treatment was performed four times at energization intervals of 4 seconds for each of the electric quantity of 112.5 C/dm². A carbon electrode was used as a counter electrode of the aluminum plate. Thereafter, a water washing treatment was performed.

(B-d) Alkali Etching Treatment

The aluminum plate after the electrochemical roughening treatment was subjected to an etching treatment by spraying a caustic soda aqueous solution in which the concentration of caustic soda was 5% by mass and the concentration of aluminum ions was 0.5% by mass using a spray tube at a temperature of 45° C. Thereafter, washing with water by spraying was performed. The dissolved aluminum amount of the surface to be subjected to an electrochemical roughening treatment was 0.2 g/m².

(B-e) Desmutting Treatment Using Acidic Aqueous Solution

Next, a desmutting treatment was performed using an acidic aqueous solution. Specifically, the desmutting treatment was performed for 3 seconds by spraying the acidic aqueous solution to an aluminum plate using a spray. As the acidic aqueous solution used for the desmutting treatment, a waste liquid generated in the anodizing treatment step (an aqueous solution having a sulfuric acid concentration of 170 g/L and an aluminum ion concentration of 5 g/L) was used. The solution temperature was 30° C.

(B-f) First Step of Anodizing Treatment

A first step of an anodizing treatment was performed with an anodizing device using DC electrolysis having the structure shown in FIG. 1. An anodized film having a predetermined coating amount was formed by performing an anodizing treatment under conditions in the columns of the “first anodizing treatment” listed in Table H.

TABLE H

| | First anodizing treatment | | | | |
|---|---|---|---|---|---|
| | | | Tem- | | |
| | Sulfuric acid | Phosphoric acid | pera- | Current | Coating |
| | concentration of | concentration of | ture | density | amount |
| Support | electrolyte (g/l) | electrolyte (g/l) | (° C.) | (A/dm²) | (g/m²) |
| Support 7 | 170 | — | 50 | 30 | 0.3 |

(B-g) Pore Widening Treatment

The aluminum plate after being subjected to the anodizing treatment was subjected to a pore widening treatment by being immersed in a caustic soda aqueous solution in which the concentration of caustic soda was 5% by mass and the concentration of aluminum ions was 0.5% by mass at a temperature of 40° C. under a time condition listed in Table I. Thereafter, washing with water by spraying was performed.

TABLE I

| | Pore widening treatment | |
|---|---|---|
| | Temperature | Time |
| Support | (° C.) | (second) |
| Support 7 | 40 | 3 |

(B-h) Second Step of Anodizing Treatment

A second step of an anodizing treatment was performed with an anodizing device using DC electrolysis having the structure shown in FIG. 1. An anodized film having a predetermined coating amount was formed by performing an anodizing treatment under conditions in the columns of the “second anodizing treatment” listed in Table J.

TABLE J

| | First anodizing treatment | | | | |
|---|---|---|---|---|---|
| | | | Tem- | | |
| | Sulfuric acid | Phosphoric acid | pera- | Current | Coating |
| | concentration of | concentration of | ture | density | amount |
| Support | electrolyte (g/l) | electrolyte (g/l) | (° C.) | (A/dm²) | (g/m²) |
| Support 7 | 170 | — | 50 | 13 | 2.1 |

<Treatment D: Production of Support 8>

(D-a) Mechanical Roughening Treatment (Brush Grain Method)

Using the device shown in FIG. 2, while supplying a suspension of pumice (specific gravity of 1.1 g/cm³) to the surface of an aluminum plate as a polishing slurry liquid, a mechanical roughening treatment was performed using rotating bundle bristle brushes. In FIG. 2, the reference numeral 1 represents an aluminum plate, the reference numerals 2 and 4 represent roller-like brushes (in the present examples, bundle bristle brushes), the reference numeral 3 represents a polishing slurry liquid, and the reference numerals 5, 6, 7, and 8 represent a support roller.

The mechanical roughening treatment is performed under conditions in which the median diameter (μm) of a polishing material was 30 μm, the number of the brushes was four, and the rotation speed (rpm) of the brushes was set to 250 rpm. The material of the bundle bristle brushes was nylon 6·10, the diameter of the brush bristles was 0.3 mm, and the bristle length was 50 mm. The brushes were produced by implanting bristles densely into holes in a stainless steel cylinder having a diameter of φ300 mm. The distance between two support rollers (φ200 mm) of the lower portion of the bundle bristle brushes was 300 mm. The bundle bristle brushes were pressed until the load of a driving motor for rotating the brushes became 10 kW plus with respect to the load before the bundle bristle brushes were pressed against the aluminum plate. The rotation direction of the brush was the same as the moving direction of the aluminum plate.

(D-b) Alkali Etching Treatment

The aluminum plate was subjected to an etching treatment by spraying a caustic soda aqueous solution in which the concentration of caustic soda was 26% by mass and the concentration of aluminum ions was 6.5% by mass using a spray at a temperature of 70° C. Thereafter, washing with water by spraying was performed. The dissolved aluminum amount of the surface to be subjected to an electrochemical roughening treatment was 10 g/m².

(D-c) Desmutting Treatment Using Acidic Aqueous Solution

Next, a desmutting treatment was performed using an acidic aqueous solution. Specifically, the desmutting treatment was performed for 3 seconds by spraying the acidic aqueous solution to an aluminum plate using a spray. As the acidic aqueous solution used in the desmutting treatment, a waste liquid of nitric acid used in electrochemical roughening treatment of the subsequent step was used. The solution temperature was 35° C.

(D-d) Electrochemical Roughening Treatment Using Nitric Acid Aqueous Solution

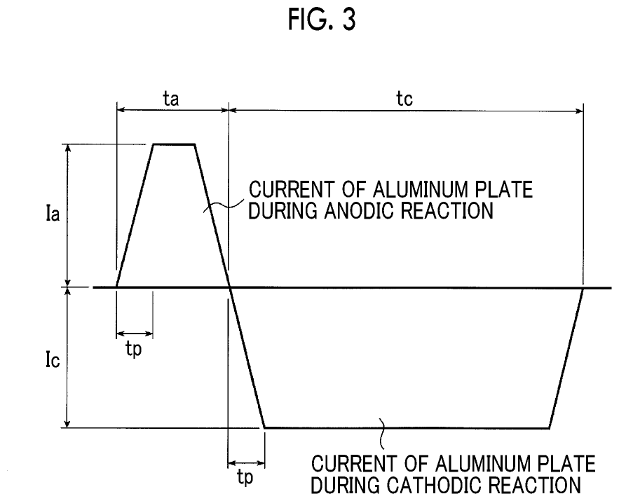

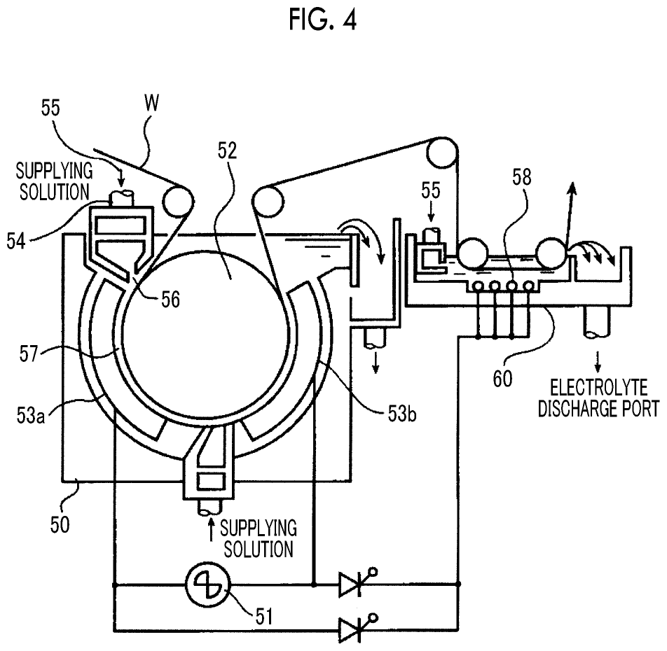

An electrochemical roughening treatment was continuously performed using an AC voltage of 60 Hz in nitric acid electrolysis. An electrolyte which had been adjusted to have a concentration of aluminum ions of 4.5 g/L by adding aluminum nitrate to a nitric acid aqueous solution having a concentration of 10.4 g/L at a solution temperature of 35° C. was used. Using a trapezoidal rectangular waveform AC having a time tp, until the current value reached a peak from zero, of 0.8 msec and the duty ratio of 1:1 as an AC power source waveform which is a waveform shown in FIG. 3, the electrochemical roughening treatment was performed using a carbon electrode as a counter electrode. As an auxiliary anode, ferrite was used. In FIG. 3, ta represents an anodic reaction time, tc represents a cathodic reaction time, tp represents a time taken for the current to reach the peak from 0, Ia represents the peak current on an anode cycle side, and Ic represents the peak current on a cathode cycle side. As an electrolytic cell, the electrolytic cell shown in FIG. 4 was used.

In FIG. 4, the reference numeral 50 represents a main electrolytic cell, the reference numeral 51 represents an AC power source, the reference numeral 52 represents a radial drum roller, the reference numerals 53a and 53b represent a main pole, the reference numeral 54 represents an electrolyte supply port, the reference numeral 55 represents an electrolyte, the reference numeral 56 represents a slit, the reference numeral 57 represents an electrolyte passage, the reference numeral 58 represents an auxiliary anode, the reference numeral 60 represents an auxiliary anode cell, and the symbol W represents an aluminum plate.

The current density was 30 A/dm² as the peak current value, and 5% of the current from the power source was separately flowed to the auxiliary anode. The electric quantity (C/dm²) was 185 C/dm² as the sum total of electric quantity at the time of anodization of the aluminum plate.

(D-e) Alkali Etching Treatment

The obtained aluminum plate was subjected to an etching treatment by spraying a caustic soda aqueous solution in which the concentration of caustic soda was 27% by mass and the concentration of aluminum ions was 2.5% by mass using a spray at a temperature of 50° C. Thereafter, washing with water by spraying was performed. The amount of aluminum dissolved was 0.5 g/m².

(D-f) Desmutting Treatment Using Acidic Aqueous Solution

Next, a desmutting treatment was performed using a sulfuric acid aqueous solution. Specifically, the desmutting treatment was performed for 3 seconds by spraying the sulfuric acid aqueous solution to an aluminum plate using a spray. As the sulfuric acid aqueous solution used in the desmutting treatment, a solution in which the concentration of sulfuric acid was 170 g/L and the concentration of aluminum ions was 5 g/L was used. The solution temperature was 30° C.

(D-g) Electrochemical Roughening Treatment Using Hydrochloric Acid Aqueous Solution

An electrochemical roughening treatment was continuously performed using an AC voltage of 60 Hz in hydrochloric acid electrolysis. An electrolyte which had been adjusted to have a concentration of aluminum ions of 4.5 g/L by adding aluminum chloride to a hydrochloric acid aqueous solution having a concentration of 6.2 g/L, and of which the solution temperature was 35° C. was used. Using a trapezoidal rectangular waveform AC having a time tp, until the current value reached a peak from zero, of 0.8 msec and the duty ratio of 1:1 as an AC power source waveform which is a waveform shown in FIG. 3, the electrochemical roughening treatment was performed using a carbon electrode as a counter electrode. As an auxiliary anode, ferrite was used. As an electrolytic cell, the electrolytic cell shown in FIG. 4 was used. The current density was 25 A/dm² as the peak current value, and the electric quantity (C/dm²) in the hydrochloric acid electrolysis was 63 C/dm² as the sum total of electric quantity at the time of anodization of the aluminum plate. Thereafter, washing with water by spraying was performed.

(D-h) Alkali Etching Treatment

The obtained aluminum plate was subjected to an etching treatment by spraying a caustic soda aqueous solution in which the concentration of caustic soda was 5% by mass and the concentration of aluminum ions was 0.5% by mass using a spray at a temperature of 60° C. Thereafter, washing with water by spraying was performed. The amount of aluminum dissolved was 0.1 g/m².

(D-i) Desmutting Treatment Using Acidic Aqueous Solution

Next, a desmutting treatment was performed using a sulfuric acid aqueous solution. Specifically, the desmutting treatment was performed for 4 seconds by spraying the sulfuric acid aqueous solution to an aluminum plate using a spray. As the sulfuric acid aqueous solution used for the desmutting treatment, a waste liquid generated in the anodizing treatment step (an aqueous solution having a sulfuric acid concentration of 170 g/L and an aluminum ion concentration of 5 g/L) was used. The solution temperature was 35° C.

(D-j) Anodizing Treatment

An anodizing treatment was performed with an anodizing device using DC electrolysis having the structure shown in FIG. 1. An anodized film having a predetermined coating amount was formed by performing an anodizing treatment under conditions in the columns of “first anodizing treatment” listed in Table K.

TABLE K

| | First anodizing treatment | | | | |
|---|---|---|---|---|---|
| | Sulfuric acid | Phosphoric acid | Tem- | Current | Coating |
| | concentration of | concentration of | perature | density | amount |
| Support | electrolyte (g/l) | electrolyte (g/l) | (° C.) | (A/dm²) | (g/m²) |
| Support 8 | 170 | — | 50 | 30 | 2.4 |

(D-k) Pore Widening Treatment

The aluminum plate after being subjected to the anodizing treatment was subjected to a pore widening treatment by being immersed in a caustic soda aqueous solution in which the concentration of caustic soda was 5% by mass and the concentration of aluminum ions was 0.5% by mass at a temperature of 40° C. for 3 seconds. Thereafter, washing with water by spraying was performed.

(D-l) Hydrophilization Treatment

In order to ensure hydrophilicity of a non-image area, the obtained aluminum plate was subjected to a silicate treatment by being dipped in 2.5% by mass of a No. 3 sodium silicate aqueous solution at 50° C. for 7 seconds. The adhesion amount of Si was 8.5 mg/m². Thereafter, washing with water by spraying was performed.

<Treatment (F): Production of Support 9>

(F-a) Alkali Etching Treatment

The aluminum plate was subjected to an etching treatment by spraying a caustic soda aqueous solution in which the concentration of caustic soda was 26% by mass and the concentration of aluminum ions was 6.5% by mass using a spray at a temperature of 70° C. Thereafter, washing with water by spraying was performed. The dissolved aluminum amount of the surface to be subjected to an electrochemical roughening treatment was 5 g/m².

(F-b) Desmutting Treatment Using Acidic Aqueous Solution

Next, a desmutting treatment was performed using an acidic aqueous solution. Specifically, the desmutting treatment was performed for 3 seconds by spraying the acidic aqueous solution to an aluminum plate using a spray. The acidic aqueous solution used in the desmutting treatment was an aqueous solution having a sulfuric acid of 150 g/L. The solution temperature was 30° C.

(F-c) Electrochemical Roughening Treatment

Next, an electrochemical roughening treatment was performed using the AC current and an electrolyte having a hydrochloric acid concentration of 14 g/L, an aluminum ion concentration of 13 g/L, and a sulfuric acid concentration of 3 g/L. The solution temperature of the electrolyte was 30° C. The aluminum ion concentration was adjusted by adding aluminum chloride.

The waveform of the AC current was a sine wave in which the positive and negative waveforms were symmetrical, the frequency was 50 Hz, the ratio between the anodic reaction time and the cathodic reaction time in one cycle of the AC current was 1:1, and the current density was 75 A/dm² in terms of the peak current value of the AC current waveform. Further, the sum total of electric quantity of the aluminum plate used for the anodic reaction was 450 C/dm², and the electrolytic treatment was performed four times at energization intervals of 4 seconds for each of the electric quantity of 112.5 C/dm². A carbon electrode was used as a counter electrode of the aluminum plate. Thereafter, a water washing treatment was performed.

(F-d) Alkali Etching Treatment

The aluminum plate after the electrochemical roughening treatment was subjected to an etching treatment by spraying a caustic soda aqueous solution in which the concentration of caustic soda was 5% by mass and the concentration of aluminum ions was 0.5% by mass using a spray tube at a temperature of 45° C. The dissolved aluminum amount of the surface to be subjected to an electrochemical roughening treatment was 0.2 g/m². Thereafter, a water washing treatment was performed.

(F-e) Desmutting Treatment Using Acidic Aqueous Solution

Next, a desmutting treatment was performed using an acidic aqueous solution. Specifically, the desmutting treatment was performed for 3 seconds by spraying the acidic aqueous solution to an aluminum plate using a spray. As the acidic aqueous solution used in the desmutting treatment, a solution in which the concentration of sulfuric acid was 170 g/L and the concentration of aluminum ions was 5 g/L was used. The solution temperature was 35° C.

(F-f) First Step of Anodizing Treatment

A first step of an anodizing treatment was performed with an anodizing device using DC electrolysis having the structure shown in FIG. 1. An anodized film having a predetermined coating amount was formed by performing an anodizing treatment under conditions in the columns of “first anodizing treatment” listed in Table L.

TABLE L

| | First anodizing treatment | | | | |
|---|---|---|---|---|---|
| | Sulfuric acid | Phosphoric acid | Tem- | Current | Coating |
| | concentration of | concentration of | perature | density | amount |
| Support | electrolyte (g/l) | electrolyte (g/l) | (° C.) | (A/dm²) | (g/m²) |
| Support 9 | — | 150 | 35 | 4.5 | 1 |

(F-g) Second Step of Anodizing Treatment

A second step of an anodizing treatment was performed with an anodizing device using DC electrolysis having the structure shown in FIG. 1. An anodized film having a predetermined coating amount was formed by performing an anodizing treatment under conditions in the columns of the “second anodizing treatment” listed in Table M.

TABLE M

| | Second anodizing treatment | | | | |
|---|---|---|---|---|---|
| | Sulfuric acid | Phosphoric acid | Tem- | Current | Coating |
| | concentration of | concentration of | perature | density | amount |
| Support | electrolyte (g/l) | electrolyte (g/l) | (° C.) | (A/dm²) | (g/m²) |
| Support 9 | 170 | — | 50 | 13 | 2.1 |

<Treatment (G): Production of Support 10>

(G-a) Alkali Etching Treatment

The aluminum plate was subjected to an etching treatment by spraying a caustic soda aqueous solution in which the concentration of caustic soda was 26% by mass and the concentration of aluminum ions was 6.5% by mass using a spray at a temperature of 70° C. Thereafter, washing with water by spraying was performed. The dissolved aluminum amount of the surface to be subjected to an electrochemical roughening treatment was 5 g/m².

(G-b) Desmutting Treatment Using Acidic Aqueous Solution

Next, a desmutting treatment was performed using an acidic aqueous solution. Specifically, the desmutting treatment was performed for 3 seconds by spraying the acidic aqueous solution to an aluminum plate using a spray. The acidic aqueous solution used in the desmutting treatment was an aqueous solution having a sulfuric acid of 150 g/L. The solution temperature was 30° C.

(G-c) Electrochemical Roughening Treatment

Next, an electrochemical roughening treatment was performed using the AC current and an electrolyte having a hydrochloric acid concentration of 14 g/L, an aluminum ion concentration of 13 g/L, and a sulfuric acid concentration of 3 g/L. The solution temperature of the electrolyte was 30° C. The aluminum ion concentration was adjusted by adding aluminum chloride.

The waveform of the AC current was a sine wave in which the positive and negative waveforms were symmetrical, the frequency was 50 Hz, the ratio between the anodic reaction time and the cathodic reaction time in one cycle of the AC current was 1:1, and the current density was 75 A/dm² in terms of the peak current value of the AC current waveform. Further, the sum total of electric quantity of the aluminum plate used for the anodic reaction was 450 C/dm², and the electrolytic treatment was performed four times at energization intervals of 4 seconds for each of the electric quantity of 112.5 C/dm². A carbon electrode was used as a counter electrode of the aluminum plate. Thereafter, a water washing treatment was performed.

(G-d) Alkali Etching Treatment

The aluminum plate after the electrochemical roughening treatment was subjected to an etching treatment by spraying a caustic soda aqueous solution in which the concentration of caustic soda was 5% by mass and the concentration of aluminum ions was 0.5% by mass using a spray tube at a temperature of 45° C. The dissolved aluminum amount of the surface to be subjected to an electrochemical roughening treatment was 0.2 g/m². Thereafter, a water washing treatment was performed.

(G-e) Desmutting Treatment Using Acidic Aqueous Solution

Next, a desmutting treatment was performed using an acidic aqueous solution. Specifically, the desmutting treatment was performed for 3 seconds by spraying the acidic aqueous solution to an aluminum plate using a spray. As the acidic aqueous solution used in the desmutting treatment, a solution in which the concentration of sulfuric acid was 170 g/L and the concentration of aluminum ions was 5 g/L was used. The solution temperature was 35° C.

(G-f) First Step of Anodizing Treatment

A first step of an anodizing treatment was performed with an anodizing device using DC electrolysis having the structure shown in FIG. 1. An anodized film having a predetermined coating amount was formed by performing an anodizing treatment under conditions in the columns of “first anodizing treatment” listed in Table N.

TABLE N

| | First anodizing treatment | | | | |
|---|---|---|---|---|---|
| | Sulfuric acid | Phosphoric acid | Tem- | Current | Coating |
| | concentration of | concentration of | perature | density | amount |
| Support | electrolyte (g/l) | electrolyte (g/l) | (° C.) | (A/dm²) | (g/m²) |
| Support 10 | — | 150 | 35 | 4.5 | 1 |

(G-g) Pore Widening Treatment

The aluminum plate after being subjected to the anodizing treatment was subjected to a pore widening treatment by being immersed in a caustic soda aqueous solution in which the concentration of caustic soda was 5% by mass and the concentration of aluminum ions was 0.5% by mass at a temperature of 40° C. under a time condition listed in Table O. Thereafter, washing with water by spraying was performed.

TABLE O

| | Pore widening treatment | |
|---|---|---|
| | Temperature | Time |
| Support | (° C.) | (second) |
| Support 10 | 40 | 4 |

(G-h) Second Step of Anodizing Treatment

A second step of an anodizing treatment was performed with an anodizing device using DC electrolysis having the structure shown in FIG. 1. An anodized film having a predetermined coating amount was formed by performing an anodizing treatment under conditions in the columns of “second anodizing treatment” listed in Table P.

TABLE P

| | Second anodizing treatment | | | | |
|---|---|---|---|---|---|
| | Sulfuric acid | Phosphoric acid | Tem- | Current | Coating |
| | concentration of | concentration of | perature | density | amount |
| Support | electrolyte (g/l) | electrolyte (g/l) | (° C.) | (A/dm²) | (g/m²) |
| Support 10 | 170 | — | 50 | 13 | 2.1 |

<Treatment (H): Production of Support 11>

(H-a) Alkali Etching Treatment

The aluminum plate was subjected to an etching treatment by spraying a caustic soda aqueous solution in which the concentration of caustic soda was 26% by mass and the concentration of aluminum ions was 6.5% by mass using a spray at a temperature of 70° C. Thereafter, washing with water by spraying was performed. The dissolved aluminum amount of the surface to be subjected to an electrochemical roughening treatment was 5 g/m².

(H-b) Desmutting Treatment Using Acidic Aqueous Solution

Next, a desmutting treatment was performed using an acidic aqueous solution. Specifically, the desmutting treatment was performed for 3 seconds by spraying the acidic aqueous solution to an aluminum plate using a spray. The acidic aqueous solution used in the desmutting treatment was an aqueous solution having a sulfuric acid of 150 g/L. The solution temperature was 30° C.

(H-c) Electrochemical Roughening Treatment

Next, an electrochemical roughening treatment was performed using the AC current and an electrolyte having a hydrochloric acid concentration of 14 g/L, an aluminum ion concentration of 13 g/L, and a sulfuric acid concentration of 3 g/L. The solution temperature of the electrolyte was 30° C. The aluminum ion concentration was adjusted by adding aluminum chloride.

The waveform of the AC current was a sine wave in which the positive and negative waveforms were symmetrical, the frequency was 50 Hz, the ratio between the anodic reaction time and the cathodic reaction time in one cycle of the AC current was 1:1, and the current density was 75 A/dm² in terms of the peak current value of the AC current waveform. Further, the sum total of electric quantity of the aluminum plate used for the anodic reaction was 450 C/dm², and the electrolytic treatment was performed four times at energization intervals of 4 seconds for each of the electric quantity of 112.5 C/dm². A carbon electrode was used as a counter electrode of the aluminum plate. Thereafter, a water washing treatment was performed.

(H-d) Alkali Etching Treatment

The aluminum plate after the electrochemical roughening treatment was subjected to an etching treatment by spraying a caustic soda aqueous solution in which the concentration of caustic soda was 5% by mass and the concentration of aluminum ions was 0.5% by mass using a spray tube at a temperature of 45° C. The dissolved aluminum amount of the surface to be subjected to an electrochemical roughening treatment was 0.2 g/m². Thereafter, a water washing treatment was performed.

(H-e) Desmutting Treatment Using Acidic Aqueous Solution

Next, a desmutting treatment was performed using an acidic aqueous solution. Specifically, the desmutting treatment was performed for 3 seconds by spraying the acidic aqueous solution to an aluminum plate using a spray. As the acidic aqueous solution used in the desmutting treatment, a solution in which the concentration of sulfuric acid was 170 g/L and the concentration of aluminum ions was 5 g/L was used. The solution temperature was 35° C.

(H-f) First Step of Anodizing Treatment

A first step of an anodizing treatment was performed with an anodizing device using DC electrolysis having the structure shown in FIG. 1. An anodized film having a predetermined coating amount was formed by performing an anodizing treatment under conditions in the columns of “first anodizing treatment” listed in Table Q.

TABLE Q

| | First anodizing treatment | | | | |
|---|---|---|---|---|---|
| | Sulfuric acid | Phosphoric acid | Tem- | Current | Coating |
| | concentration of | concentration of | perature | density | amount |
| Support | electrolyte (g/l) | electrolyte (g/l) | (° C.) | (A/dm²) | (g/m²) |
| Support 11 | — | 150 | 35 | 4.5 | 1 |

(H-g) Second Step of Anodizing Treatment

A second step of an anodizing treatment was performed with an anodizing device using DC electrolysis having the structure shown in FIG. 1. An anodized film having a predetermined coating amount was formed by performing an anodizing treatment under conditions in the columns of the “second anodizing treatment” listed in Table R.

TABLE R

| | Second anodizing treatment | | | | |
|---|---|---|---|---|---|
| | Sulfuric acid | Phosphoric acid | Tem- | Current | Coating |
| | concentration of | concentration of | perature | density | amount |
| Support | electrolyte (g/l) | electrolyte (g/l) | (° C.) | (A/dm²) | (g/m²) |
| Support 11 | — | 150 | 35 | 4.5 | 1 |

<Treatment (I): Production of Support 12>

(I-a) Alkali Etching Treatment

The aluminum plate was subjected to an etching treatment by spraying a caustic soda aqueous solution in which the concentration of caustic soda was 26% by mass and the concentration of aluminum ions was 6.5% by mass using a spray at a temperature of 70° C. Thereafter, washing with water by spraying was performed. The dissolved aluminum amount of the surface to be subjected to an electrochemical roughening treatment was 5 g/m².

(I-b) Desmutting Treatment Using Acidic Aqueous Solution

Next, a desmutting treatment was performed using an acidic aqueous solution. Specifically, the desmutting treatment was performed for 3 seconds by spraying the acidic aqueous solution to an aluminum plate using a spray. The acidic aqueous solution used in the desmutting treatment was an aqueous solution having a sulfuric acid of 150 g/L. The solution temperature was 30° C.

(I-c) Electrochemical Roughening Treatment

Next, an electrochemical roughening treatment was performed using the AC current and an electrolyte having a hydrochloric acid concentration of 14 g/L, an aluminum ion concentration of 13 g/L, and a sulfuric acid concentration of 3 g/L. The solution temperature of the electrolyte was 30° C. The aluminum ion concentration was adjusted by adding aluminum chloride.

The waveform of the AC current was a sine wave in which the positive and negative waveforms were symmetrical, the frequency was 50 Hz, the ratio between the anodic reaction time and the cathodic reaction time in one cycle of the AC current was 1:1, and the current density was 75 A/dm² in terms of the peak current value of the AC current waveform. Further, the sum total of electric quantity of the aluminum plate used for the anodic reaction was 450 C/dm², and the electrolytic treatment was performed four times at energization intervals of 4 seconds for each of the electric quantity of 112.5 C/dm². A carbon electrode was used as a counter electrode of the aluminum plate. Thereafter, a water washing treatment was performed.

(I-d) Alkali Etching Treatment

The aluminum plate after the electrochemical roughening treatment was subjected to an etching treatment by spraying a caustic soda aqueous solution in which the concentration of caustic soda was 5% by mass and the concentration of aluminum ions was 0.5% by mass using a spray tube at a temperature of 45° C. The dissolved aluminum amount of the surface to be subjected to an electrochemical roughening treatment was 0.2 g/m². Thereafter, a water washing treatment was performed.

(I-e) Desmutting Treatment Using Acidic Aqueous Solution

Next, a desmutting treatment was performed using an acidic aqueous solution. Specifically, the desmutting treatment was performed for 3 seconds by spraying the acidic aqueous solution to an aluminum plate using a spray. As the acidic aqueous solution used in the desmutting treatment, a solution in which the concentration of sulfuric acid was 170 g/L and the concentration of aluminum ions was 5 g/L was used. The solution temperature was 35° C.

(I-f) First Step of Anodizing Treatment

A first step of an anodizing treatment was performed with an anodizing device using DC electrolysis having the structure shown in FIG. 1. An anodized film having a predetermined coating amount was formed by performing an anodizing treatment under conditions in the columns of “first anodizing treatment” listed in Table S.

TABLE S

| | First anodizing treatment | | | | |
|---|---|---|---|---|---|
| | Sulfuric acid | Phosphoric acid | Tem- | Current | Coating |
| | concentration of | concentration of | perature | density | amount |
| Support | electrolyte (g/l) | electrolyte (g/l) | (° C.) | (A/dm²) | (g/m²) |
| Support 12 | — | 150 | 35 | 4.5 | 1 |

(I-g) Pore Widening Treatment

The aluminum plate after being subjected to the anodizing treatment was subjected to a pore widening treatment by being immersed in a caustic soda aqueous solution in which the concentration of caustic soda was 5% by mass and the concentration of aluminum ions was 0.5% by mass at a temperature of 40° C. under a time condition listed in Table T. Thereafter, washing with water by spraying was performed.

TABLE T

| | Pore widening treatment | |
|---|---|---|
| | Temperature | Time |
| Support | (° C.) | (second) |
| Support 12 | 40 | 8 |

(I-h) Second Step of Anodizing Treatment

A second step of an anodizing treatment was performed with an anodizing device using DC electrolysis having the structure shown in FIG. 1. An anodized film having a predetermined coating amount was formed by performing an anodizing treatment under conditions in the columns of the “second anodizing treatment” listed in Table U.

TABLE U

| | Second anodizing treatment | | | | |
|---|---|---|---|---|---|
| | Sulfuric acid | Phosphoric acid | Tem- | Current | Coating |
| | concentration of | concentration of | perature | density | amount |
| Support | electrolyte (g/l) | electrolyte (g/l) | (° C.) | (A/dm²) | (g/m²) |
| Support 12 | — | 150 | 35 | 4.5 | 2.1 |

<Production of Support 13>

—Aluminum Plate—

A molten metal was prepared using an aluminum alloy containing 0.06% by mass of Si, 0.30% by mass of Fe, 0.005% by mass of Cu, 0.001% by mass of Mn, 0.001% by mass of Mg, 0.001% by mass of Zn, and 0.03% by mass of Ti and, as the remainder, aluminum and unavoidable impurities, a molten metal treatment and filtration were performed, and an ingot having a thickness of 500 mm and a width of 1200 mm was produced according to a DC casting method. The surface was scraped off using a surface grinder having an average thickness of 10 mm and heated at 550° C. and maintained the state for approximately 5 hours. After the temperature was decreased to 400° C., a rolled sheet having a thickness of 2.7 mm was obtained using a hot rolling mill. Further, a heat treatment was performed thereon at 500° C. using a continuous annealing machine, and a cold rolling was performed so that the thickness of the rolled sheet was finished to 0.24 mm, thereby obtaining an aluminum plate formed of JIS 1050 material. The following surface treatment was performed after the width of this aluminum plate was adjusted to 1030 mm.

—Surface Treatment—

The surface treatment was performed by continuously performing the following treatments (b) to (j).

Further, liquid cutting was performed using a nip roller after each treatment and washing with water.

(b) Alkali Etching Treatment

The aluminum plate obtained in the above-described manner was subjected to an etching treatment by spraying an aqueous solution in which the concentration of caustic soda was 2.6% by mass and the concentration of aluminum ions was 6.5% by mass at a temperature of 70° C. so that 6 g/m² of the aluminum plate was dissolved. Thereafter, washing with water by spraying was performed.

(c) Desmutting Treatment

A desmutting treatment was performed by spraying an aqueous solution (containing 0.5% by mass of aluminum ions) having a nitric acid concentration of 1% by mass at a temperature of 30° C. Thereafter, washing with water by spraying was performed. As the nitric acid aqueous solution used for the desmutting treatment, a waste liquid used for the step of performing the electrochemical roughening treatment using the alternating current in a nitric acid aqueous solution was used.

(d) Electrochemical Roughening Treatment

An electrochemical roughening treatment was continuously performed using an AC voltage of 60 Hz. As an electrolyte at this time, an aqueous solution containing 10.5 g/L of nitric acid (containing 5 g/L of aluminum ions and 0.007% by mass of ammonium ions) was used, and the solution temperature was 50° C. Using a trapezoidal rectangular waveform AC having a time tp, until the current value reached a peak from zero, of 0.8 msec and the duty ratio of 1:1 as an AC power source waveform which is a waveform shown in FIG. 3, the electrochemical roughening treatment was performed using a carbon electrode as a counter electrode. As an auxiliary anode, ferrite was used. As an electrolytic cell to be used, the electrolytic cell shown in FIG. 4 was used. The current density was 30 A/dm² as the peak current value, and the electric quantity was 220 C/dm² as the sum total of electric quantity at the time of anodization of the aluminum plate. 5% of the current from the power source was separately flowed to the auxiliary anode. Thereafter, washing with water by spraying was performed.

(e) Alkali Etching Treatment

The aluminum plate was subjected to an etching treatment by spraying an aqueous solution in which the concentration of caustic soda was 26% by mass and the concentration of aluminum ions was 6.5% by mass at a temperature of 32° C. so that 0.25 g/m² of the aluminum plate was dissolved. Further, a smut component mainly containing aluminum hydroxide generated at the time of the electrochemical roughening treatment using the alternating current at the former step was removed, an edge portion of a generated pit was dissolved to smooth the edge portion. Thereafter, washing with water by spraying was performed.

(f) Desmutting Treatment

A desmutting treatment was performed by spraying an aqueous solution (containing 4.5% by mass of aluminum ions) having a sulfuric acid concentration of 15% by mass at a temperature of 30° C. Thereafter, washing with water was performed using a spray. As the nitric acid aqueous solution used for the desmutting treatment, a waste liquid used for the step of performing the electrochemical roughening treatment using the alternating current in a nitric acid aqueous solution was used.

(g) Electrochemical Roughening Treatment

An electrochemical roughening treatment was continuously performed using an AC voltage of 60 Hz. As an electrolyte at this time, an aqueous solution containing 2.5 g/L of hydrochloric acid (containing 5 g/L of aluminum ions) was used, and the temperature was 35° C. Using a trapezoidal rectangular waveform AC having a time tp, until the current value reached a peak from zero, of 0.8 msec and the duty ratio of 1:1 as an AC power source waveform which is a waveform shown in FIG. 3, the electrochemical roughening treatment was performed using a carbon electrode as a counter electrode. As an auxiliary anode, ferrite was used. As an electrolytic cell to be used, the electrolytic cell shown in FIG. 4 was used. The current density was 25 A/dm² as the peak current value, and the electric quantity was 50 C/dm² as the sum total of electric quantity at the time of anodization of the aluminum plate. Thereafter, washing with water by spraying was performed.

(h) Alkali Etching Treatment

The aluminum plate was subjected to an etching treatment by spraying an aqueous solution in which the concentration of caustic soda was 26% by mass and the concentration of aluminum ions was 6.5% by mass at a temperature of 32° C. so that 0.1 g/m² of the aluminum plate was dissolved. Further, a smut component mainly containing aluminum hydroxide generated at the time of the electrochemical roughening treatment using the alternating current at the former step was removed, an edge portion of a generated pit was dissolved to smooth the edge portion. Thereafter, washing with water by spraying was performed.

(i) Desmutting Treatment

A desmutting treatment was performed by spraying an aqueous solution (containing 0.5% by mass of aluminum ions) having a sulfuric acid concentration of 25% by mass at a temperature of 60° C. Thereafter, washing with water by spraying was performed.

(j) Anodizing Treatment

An anodizing treatment was performed with an anodizing device having a structure illustrated in FIG. 1, thereby obtaining a support 13. As the electrolyte supplied to first and second electrolysis portions, sulfuric acid was used. The electrolyte had a sulfuric acid concentration of 170 g/L (containing 0.5% by mass of aluminum ions) and the temperature thereof was 38° C. Thereafter, washing with water by spraying was performed. The final amount of the oxide film was 2.7 g/m².

<Production of Support 14>

In order to remove rolling oil from the surface of an aluminum plate (material JISA 1050) having a thickness of 0.3 mm, the surface was subjected to a degassing treatment at 50° C. for 30 seconds using a 10% by mass of sodium aluminate aqueous solution, and the surface of the aluminum plate was grained using three bundle bristle brushes having a bristle diameter of 0.3 mm and a pumice-water suspension (specific gravity of 1.1 g/cm³) having a median diameter of 25 μm and washed with water thoroughly. The aluminum plate was immersed in a 25% by mass of sodium hydroxide aqueous solution at 45° C. for 9 seconds so as to be etched, washed with water, further immersed in a 20% by mass of nitric acid aqueous solution at 60° C. for 20 seconds, and washed with water. The etching amount of the grained surface was approximately 3 g/m².

An electrochemical roughening treatment was continuously performed using an AC voltage of 60 Hz. A 1% by mass of nitric acid aqueous solution (containing 0.5% by mass of aluminum ions) was used as an electrolyte, and the solution temperature was 50° C. Using a trapezoidal rectangular waveform AC having a time tp, until the current value reached a peak from zero, of 0.8 msec and the duty ratio of 1:1 as the AC power source waveform, the electrochemical roughening treatment was performed using a carbon electrode as a counter electrode. As an auxiliary anode, ferrite was used. The current density was 30 A/dm² as the peak current value, and 5% of the current from the power source was separately flowed to the auxiliary anode. The electric quantity in nitric acid electrolysis was 175 C/dm² as the electric quantity at the time of anodization of the aluminum plate. Thereafter, washing with water by spraying was performed.

Next, an electrochemical roughening treatment was performed according to the same method as that for the nitric acid electrolysis using a 0.5% by mass of hydrochloric acid aqueous solution (containing 0.5% by mass of aluminum ions) and an electrolyte having a solution temperature of 50° C. under a condition of an electric quantity of 50 C/dm² at the time of anodization of the aluminum plate, and washing with water was performed using a spray.

The aluminum plate was provided with a DC anodized film with a coating amount of 2.5 g/m² at a current density of 15 A/dm² using a 15% by mass of sulfuric acid aqueous solution (containing 0.5% by mass of aluminum ions) as an electrolyte, washed with water, and dried.

Next, a sealing treatment was performed by spraying water vapor at 100° C. to the anodized film at a pressure of 1.033×10⁵ Pa for 8 seconds. Further, the aluminum support was immersed in a treatment liquid, obtained by dissolving 0.4% by mass of polyvinyl phosphonic acid (manufactured by PCAS) in pure water, at 53° C. for 10 seconds, and the excess treatment liquid was completely removed using a nip roll, thereby producing a support 14.

<Production of Support 15>

An aluminum plate (aluminum alloy plate) formed of the material 1S with a thickness of 0.3 mm was subjected to any of the following treatments, thereby producing a support 15. Moreover, during all treatment steps, a water washing treatment was performed, and liquid cutting was performed using a nip roller after the water washing treatment.

<Treatment J: Production of Support 15>

(J-a) Mechanical Roughening Treatment (Brush Grain Method)

Using the device shown in FIG. 2, while supplying a suspension of pumice (specific gravity of 1.1 g/cm³) to the surface of an aluminum plate as a polishing slurry liquid, a mechanical roughening treatment was performed using rotating bundle bristle brushes. In FIG. 2, the reference numeral 1 represents an aluminum plate, the reference numerals 2 and 4 represent roller-like brushes (in the present examples, bundle bristle brushes), the reference numeral 3 represents a polishing slurry liquid, and the reference numerals 5, 6, 7, and 8 represent a support roller.

The mechanical roughening treatment is performed under conditions in which the median diameter (μm) of a polishing material was 30 μm, the number of the brushes was four, and the rotation speed (rpm) of the brushes was set to 250 rpm. The material of the bundle bristle brushes was nylon 6·10, the diameter of the brush bristles was 0.3 mm, and the bristle length was 50 mm. The brushes were produced by implanting bristles densely into holes in a stainless steel cylinder having a diameter of φ300 mm. The distance between two support rollers (φ200 mm) of the lower portion of the bundle bristle brushes was 300 mm. The bundle bristle brushes were pressed until the load of a driving motor for rotating the brushes became 10 kW plus with respect to the load before the bundle bristle brushes were pressed against the aluminum plate. The rotation direction of the brush was the same as the moving direction of the aluminum plate.

(J-b) Alkali Etching Treatment

The aluminum plate was subjected to an etching treatment by spraying a caustic soda aqueous solution in which the concentration of caustic soda was 26% by mass and the concentration of aluminum ions was 6.5% by mass using a spray at a temperature of 70° C. Thereafter, washing with water by spraying was performed. The dissolved aluminum amount of the surface to be subjected to an electrochemical roughening treatment was 10 g/m².

(J-c) Desmutting Treatment Using Acidic Aqueous Solution

Next, a desmutting treatment was performed using an acidic aqueous solution. Specifically, the desmutting treatment was performed for 3 seconds by spraying the acidic aqueous solution to an aluminum plate using a spray. As the acidic aqueous solution used in the desmutting treatment, a waste liquid of nitric acid used in electrochemical roughening treatment of the subsequent step was used. The solution temperature was 35° C.

(J-d) Electrochemical Roughening Treatment Using Nitric Acid Aqueous Solution

An electrochemical roughening treatment was continuously performed using an AC voltage of 60 Hz in nitric acid electrolysis. An electrolyte which had been adjusted to have a concentration of aluminum ions of 4.5 g/L by adding aluminum nitrate to a nitric acid aqueous solution having a concentration of 10.4 g/L at a temperature of 35° C. was used. Using a trapezoidal rectangular waveform AC having a time tp, until the current value reached a peak from zero, of 0.8 msec and the duty ratio of 1:1 as an AC power source waveform which is a waveform shown in FIG. 3, the electrochemical roughening treatment was performed using a carbon electrode as a counter electrode. As an auxiliary anode, ferrite was used. As an electrolytic cell, the electrolytic cell shown in FIG. 4 was used. The current density was 30 A/dm² as the peak current value, and 5% of the current from the power source was separately flowed to the auxiliary anode. The electric quantity (C/dm²) was 185 C/dm² as the sum total of electric quantity at the time of anodization of the aluminum plate.

(J-e) Alkali Etching Treatment

The obtained aluminum plate was subjected to an etching treatment by spraying a caustic soda aqueous solution in which the concentration of caustic soda was 27% by mass and the concentration of aluminum ions was 2.5% by mass using a spray at a temperature of 50° C. Thereafter, washing with water by spraying was performed. Further, the amount of aluminum dissolved was 3.5 g/m².

(J-f) Desmutting Treatment Using Acidic Aqueous Solution

Next, a desmutting treatment was performed using a sulfuric acid aqueous solution. Specifically, the desmutting treatment was performed for 3 seconds by spraying the sulfuric acid aqueous solution to an aluminum plate using a spray. As the sulfuric acid aqueous solution used in the desmutting treatment, a solution in which the concentration of sulfuric acid was 170 g/L and the concentration of aluminum ions was 5 g/L was used. The solution temperature was 30° C.

(J-g) Electrochemical Roughening Treatment Using Hydrochloric Acid Aqueous Solution

An electrochemical roughening treatment was continuously performed using an AC voltage of 60 Hz in hydrochloric acid electrolysis. An electrolyte which had been adjusted to have a concentration of aluminum ions of 4.5 g/L by adding aluminum chloride to a hydrochloric acid aqueous solution having a concentration of 6.2 g/L, and of which the solution temperature was 35° C. was used. Using a trapezoidal rectangular waveform AC having a time tp, until the current value reached a peak from zero, of 0.8 msec and the duty ratio of 1:1 as an AC power source waveform which is a waveform shown in FIG. 3, the electrochemical roughening treatment was performed using a carbon electrode as a counter electrode. As an auxiliary anode, ferrite was used. As an electrolytic cell, the electrolytic cell shown in FIG. 4 was used. The current density was 25 A/dm² as the peak current value, and the electric quantity (C/dm²) in the hydrochloric acid electrolysis was 63 C/dm² as the sum total of electric quantity at the time of anodization of the aluminum plate. Thereafter, washing with water by spraying was performed.

(J-h) Alkali Etching Treatment

The obtained aluminum plate was subjected to an etching treatment by spraying a caustic soda aqueous solution in which the concentration of caustic soda was 5% by mass and the concentration of aluminum ions was 0.5% by mass using a spray at a temperature of 60° C. Thereafter, washing with water by spraying was performed. The amount of aluminum dissolved was 0.2 g/m².

(J-i) Desmutting Treatment Using Acidic Aqueous Solution

Next, a desmutting treatment was performed using a sulfuric acid aqueous solution. Specifically, the desmutting treatment was performed for 4 seconds by spraying the sulfuric acid aqueous solution to an aluminum plate using a spray. As the sulfuric acid aqueous solution used for the desmutting treatment, a waste liquid generated in the anodizing treatment step (an aqueous solution having a sulfuric acid concentration of 170 g/L and an aluminum ion concentration of 5 g/L) was used. The solution temperature was 35° C.

(J-j) First Step of Anodizing Treatment

A first step of an anodizing treatment was performed with an anodizing device using DC electrolysis having the structure shown in FIG. 1. An anodized film having a predetermined coating amount was formed by performing an anodizing treatment under conditions in the columns of “first anodizing treatment” listed in Table V.

TABLE V

| | First anodizing treatment | | | | |
|---|---|---|---|---|---|
| | Sulfuric acid | Phosphoric acid | Tem- | Current | Coating |
| | concentration of | concentration of | perature | density | amount |
| Support | electrolyte (g/l) | electrolyte (g/l) | (° C.) | (A/dm²) | (g/m²) |
| Support 15 | 170 | — | 50 | 30 | 0.3 |

(J-k) Pore Widening Treatment

The aluminum plate after having been subjected to the anodizing treatment was subjected to a pore widening treatment by being immersed in a caustic soda aqueous solution in which the concentration of caustic soda was 5% by mass and the concentration of aluminum ions was 0.5% by mass at a temperature of 40° C. for the time listed in Table W. Thereafter, washing with water by spraying was performed.

TABLE W

| | Pore widening treatment | |
|---|---|---|
| | Temperature | Time |
| Support | (° C.) | (second) |
| Support 15 | 40 | 3 |

(J-l) Second Step of Anodizing Treatment

A second step of an anodizing treatment was performed with an anodizing device using DC electrolysis having the structure shown in FIG. 1. An anodized film having a predetermined coating amount was formed by performing an anodizing treatment under conditions in the columns of the “second anodizing treatment” listed in Table X.

TABLE X

| | Second anodizing treatment | | | | |
|---|---|---|---|---|---|
| | Sulfuric acid | Phosphoric acid | Tem- | Current | Coating |
| | concentration of | concentration of | perature | density | amount |
| Support | electrolyte (g/l) | electrolyte (g/l) | (° C.) | (A/dm²) | (g/m²) |
| Support 15 | 170 | — | 50 | 13 | 2.1 |

(J-m) Hydrophilization Treatment

In order to ensure hydrophilicity of a non-image area, the obtained aluminum plate was subjected to a silicate treatment by being dipped in 2.5% by mass of a No. 3 sodium silicate aqueous solution at 50° C. for 7 seconds. The adhesion amount of Si was 8.5 mg/m². Thereafter, washing with water by spraying was performed.

In each of the supports 4 to 15, the average diameter of micropores in the surface of the obtained anodized film on a side opposite to an aluminum plate side is collectively listed in Table Y.

The average diameter of micropores is calculated by observing 4 sheets (N=4) of the surfaces of the anodized film using FE-SEM at a magnification of 150000, measuring the diameters of micropores present in a range of 400 nm×600 nm² in the obtained four sheets of images, and averaging the values.

Further, in a case where the shape of the micropores is not circular, an equivalent circle diameter is used. The “equivalent circle diameter” is a diameter of a circle obtained by assuming the shape of an opening portion of a micropore as a circle having the same projected area as the projected area of the opening portion.

TABLE Y

| | Average diameter |
|---|---|
| | of micropores |
| Support | (nm) |
| Support 4 | 13 |
| Support 5 | 30 |
| Support 6 | 100 |
| Support 7 | 30 |
| Support 8 | 30 |
| Support 9 | 40 |
| Support 10 | 100 |
| Support 11 | 40 |
| Support 12 | 148 |
| Support 13 | 7 |
| Support 14 | 7 |
| Support 15 | 30 |

### Example 49

<Formation of Back Coat Layer>

(Preparation of Back Coat Layer Coating Solution (49))
BR-605 (acrylic resin), manufactured by Mitsubishi Chemical Corporation: 11.072 g
SUMECTON-SEN (tabular particles), manufactured by Kunimine Industries Co., Ltd.: 0.500 g
Acrylic particles ART PEARL J-6PF, manufactured by Negami Chemical Industrial Co., Ltd.: 0.975 g
RHEODOL TW-S106V (polyoxyethylene (6) sorbitan monostearate), manufactured by Kao Corporation: 0.250 g
2-butanone 74.123 g
1-methoxy-2-propanol 8.720 g
Methanol 4.360 g

The components were mixed and stirred, thereby a back coat layer coating solution (49) was prepared.

The surface of the support 1 on the back coat layer side (non-printing surface side) was bar-coated with the back coat layer coating solution (49) with the above-described composition and dried at 100° C. for 120 seconds, thereby forming a back coat layer having a thickness of 1.2 μm.

<Formation of Undercoat Layer>

The other surface (printing surface side) of the support 1 was coated with the undercoat layer coating solution (1) with the above-described composition such that the drying coating amount thereof reached 20 mg/m², thereby forming an undercoat layer.

<Formation of Image Recording Layer>

The undercoat layer of the support including a back coat layer and an undercoat layer was bar-coated with the image recording layer coating solution (2) with the following composition and dried in an oven at 70° C. for 60 seconds to form an image recording layer (polymer-containing layer 1) having a drying coating amount of 0.6 g/m², thereby producing a planographic printing plate precursor.

### Examples 50 to 58

Back coat layers, undercoat layers, and image recording layers were formed in the same manner as in Example 49 except that the support of Example 49 was changed as listed in Table 2, thereby producing planographic printing plate precursors.

### Example 59

<Formation of Back Coat Layer>

The surface of the support 2 on the back coat layer side (non-printing surface side) was bar-coated with the back coat layer coating solution (49) of Example 49 and dried at 100° C. for 120 seconds, thereby forming a back coat layer having a thickness of 1.2 μm.

<Formation of Image Recording Layer>

An image recording layer aqueous coating solution containing thermoplastic polymer particles, an infrared absorbent, and polyacrylic acid described below was prepared, the pH thereof was adjusted to 3.6, and the surface of the support 2 on the printing surface side was coated with the coating solution and dried at 50° C. for 1 minute to form and produce an image recording layer. The coating amount after the drying of each component is shown below.

Thermoplastic polymer particles: 0.7 g/m²

Infrared absorbent IR-01: 1.20×10⁻⁴ g/m²

Polyacrylic acid: 0.09 g/m²

The thermoplastic polymer particles, the infrared absorbent IR-01, the polyacrylic acid used for the image recording layer coating solution are as follows.

### Example 60

<Formation of Back Coat Layer>

The surface of the support 3 on the back coat layer side (non-printing surface side) was bar-coated with the back coat layer coating solution (49) of Example 49 and dried at 100° C. for 120 seconds, thereby forming a back coat layer having a thickness of 1.2 μm.

<Formation of Undercoat Layer>

The surface of the support 3 on the printing surface side was coated with the undercoat layer coating solution (1) such that the drying coating amount thereof reached 20 mg/m², thereby forming an undercoat layer.

The undercoat layer was bar-coated with an image recording layer coating solution (3) with the above composition and dried in an oven at 1000 for 60 seconds, thereby forming an image recording layer having a drying coating amount of 1.0 g/m².

<Formation of Protective Layer>

The image recording layer was bar-coated with a protective layer coating solution (1) with the above composition and dried in an oven at 1200 for 60 seconds to form a protective layer having a drying coating amount of 0.15 g/m², thereby producing a planographic printing plate precursor.

### Example 61

<Formation of Back Coat Layer>

The surface of the support 3 on the back coat layer side (non-printing surface side) was bar-coated with the back coat layer coating solution (49) of Example 49 and dried at 100° C. for 120 seconds, thereby forming a back coat layer having a thickness of 1.2 μm.

<Formation of Undercoat Layer>

The surface of the support 3 having the back coat layer used for production of Example 61 on the printing surface side was coated with the undercoat layer coating solution (2) with the above-described composition using a wire bar and dried at 90° C. for 30 seconds. The coating amount thereof was 10 mg/m².

<Formation of Image Recording Layer>

The undercoat layer was coated with the image recording layer coating solution (4) with the above composition using a wire bar and dried at 115° C. for 34 seconds using a hot air dryer. The coating amount after the drying was 1.4 g/m².

<Formation of Protective Layer>

The image recording layer was coated with the protective layer coating solution (2) with the above composition using a wire bar and dried at 125° C. for 75 seconds using a hot air dryer, thereby forming a protective layer. The coating amount after the drying was 1.6 g/m². In this manner, a planographic printing plate precursor of Example 61 was produced.

### Example 62

<Formation of Back Coat Layer>

The surface of the support 3 on the back coat layer side (non-printing surface side) was bar-coated with the back coat layer coating solution (49) of Example 49 and dried at 100° C. for 120 seconds, thereby forming a back coat layer having a thickness of 1.2 μm.

<Formation of Undercoat Layer>

The surface of the support 3 having the back coat layer used for production of Example 62 on the printing surface side was coated with the undercoat layer coating solution (3) with the above-described composition using a bar coater and dried at 80° C. for 15 seconds, thereby forming an undercoat layer having a coating amount of 18 mg/m² after the drying of the solution.

<Formation of Image Recording Layer>

The undercoat layer was coated with an underlayer coating solution with the following composition using a bar coater such that the coating amount after the drying was set to 0.85 g/m², dried at 160° C. for 44 seconds, and immediately cooled with cold air in a temperature range of 17° C. to 20° C. until the temperature of the support was set to 35° C., thereby forming an underlayer. Thereafter, the underlayer was coated with an upper layer coating solution with the following composition using a bar coater such that the coating amount after the drying was set to 0.22 g/m², dried at 148° C. for 25 seconds, and gradually cooled with air in a temperature range of 20° C. to 26° C., thereby forming an upper layer. In this manner, a planographic printing plate precursor of Example 62 was produced.

(Underlayer Coating Solution)
N-(4-aminosulfonylphenyl)methacrylamide/acrylonitrile/methyl methacrylate 2.1 g (36/34/30% by mass: mass average molecular weight of 50000, acid value of 2.65)
m,p-cresol novolac 0.1 g (m/p ratio=6/4, mass average molecular weight of 4500, containing 0.8% by mass of unreacted cresol, Tg: 75° C.)
Cyanine dye A (the following structure) 0.13 g
4,4′-bishydroxyphenylsulfone 0.13 g
Tetrahydrophthalic anhydride 0.19 g
p-toluenesulfonic acid 0.008 g
3-methoxy-4-diazodiphenylamine hexafluorophosphate 0.032 g
Dye obtained by changing counter ion of ethyl violet into 6-hydroxy-2-naphthalenesulfonic acid 0.078 g
Fluorine-based surfactant B (the following structure) 0.007 g
Methyl ethyl ketone 25.0 g
1-methoxy-2-propanol 13.0 g
γ-butyrolactone 13.0 g

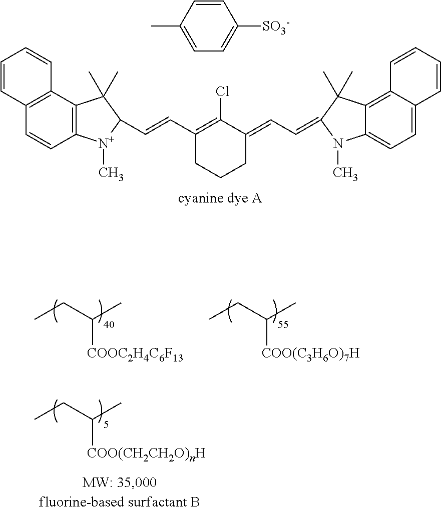

(Upper Layer Coating Solution)
Phenol/m-cresol/p-cresol novolac 0.35 g
(molar ratio=5/3/2, mass average molecular weight: 5000, content of unreacted cresol: 1.2% by mass, Tg: 70° C.)
Acrylic resin C (the following structure) 0.042 g
Cyanine dye A (the above structure) 0.019 g
Ammonium compound D (the following structure) 0.004 g
Sulfonium compound G (the following structure) 0.032 g
Fluorine-based surfactant B (the above structure) 0.0045 g
Fluorine-based surfactant E (the following structure) 0.0033 g
Fluorine-based polymer F (the following structure) 0.018 g
Methyl ethyl ketone 10.0 g
1-methoxy-2-propanol 20.0 g

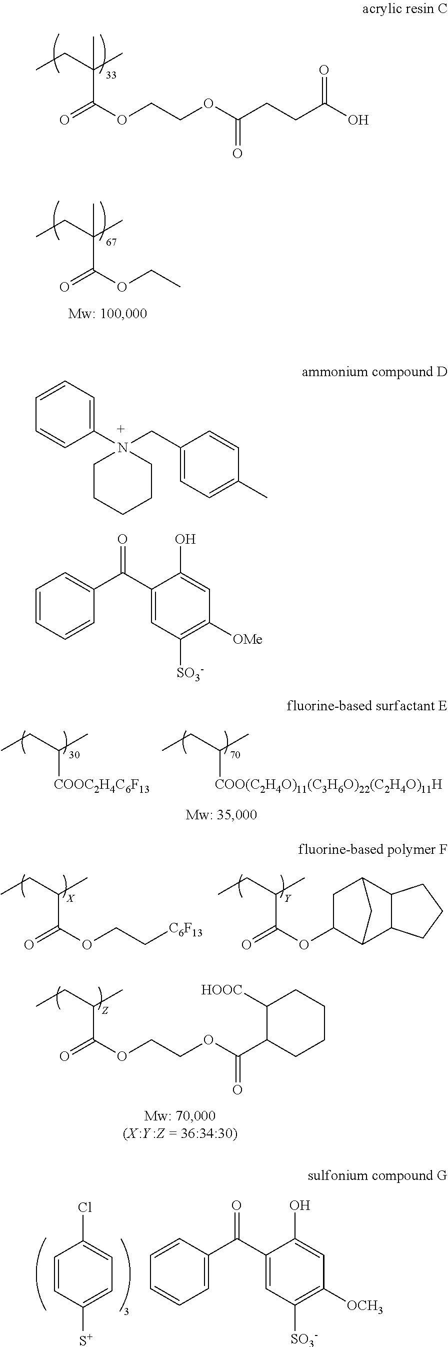

### Example 63

<Formation of Back Coat Layer>

The surface of the support 3 on the back coat layer side (non-printing surface side) was bar-coated with the back coat layer coating solution (49) of Example 49 and dried at 100° C. for 120 seconds, thereby forming a back coat layer having a thickness of 1.2 μm.

<Formation of Undercoat Layer>

The surface of the support 3 having the back coat layer used for production of Example 63 on the printing surface side was coated with the undercoat layer coating solution (4) with the above-described composition using a bar coater and dried at 80° C. for 15 seconds, thereby forming an undercoat layer having a coating amount of 18 mg/m² after the drying of the solution.

<Formation of Non-Photosensitive Layer>

The undercoat layer was bar-coated with a non-photosensitive layer coating solution (1) with the above composition and dried at 100° C. for 60 seconds, thereby forming a hydrophilic layer. The coating amount after the drying was 1.0 mg/m².

<Formation of Hydrophilic Layer>

The non-photosensitive layer was bar-coated with a hydrophilic layer coating solution (1) having the above composition and dried at 125° C. for 75 seconds, thereby forming a non-photosensitive layer. The coating amount after the drying was 1.6 mg/m². In this manner, a printing key plate precursor of Example 63 was produced.

### Example 64

A printing key plate precursor of Example 64 was produced in the same manner as in the production of Example 60 except that the infrared absorbent (1) and the polymerization initiator (1) were removed from the image recording layer coating solution (3).

### Example 65

<Formation of Back Coat Layer>

The surface of the support 13 on the back coat layer side (non-printing surface side) was bar-coated with the back coat layer coating solution (49) of Example 49 and dried at 100° C. for 120 seconds, thereby forming a back coat layer having a thickness of 1.2 μm.

<Formation of Undercoat Layer>

The surface of the support 13 having the back coat layer used for production of Example 65 on the printing surface side was coated with an undercoat layer coating solution (65) with the following composition such that the drying coating amount thereof reached 20 mg/m², thereby forming an undercoat layer.

(Undercoat Layer Coating Solution (65))
Compound for undercoat layer (2) (the following structure): 0.18 parts
Tetrasodium ethylenediaminetetraacetate: 0.10 parts
Polyoxyethylene lauryl ether: 0.03 parts
Water: 61.39 parts

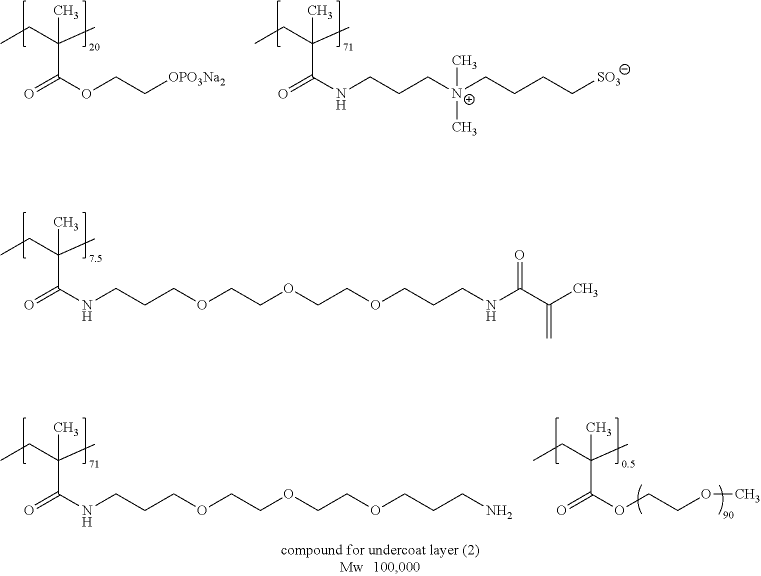

The numerical values on the lower right side of the parentheses of each constitutional unit in the above-described compound (2) for an undercoat layer indicate the mass ratios, and the numerical values on the lower right side of the parentheses of each ethyleneoxy unit indicate the repetition numbers.

<Formation of Image Recording Layer>

The undercoat layer was bar-coated with an image recording layer coating solution (65) with the following composition and dried in an oven at 100° for 60 seconds, thereby forming an image recording layer 3 having a thickness of 1 μm.

The image recording layer coating solution (65) was obtained by mixing a photosensitive solution (2) and a microgel solution (2) described below immediately before the coating and then stirring the solution.

<Photosensitive Solution (2)>
Binder polymer (2) (the following structure, Mw: 50000 and n (number of ethylene oxide (EO) repeating units: 4)): 0.480 parts
Infrared absorbent (1) (described above): 0.030 parts
Borate compound (Sodium tetraphenylborate): 0.014 parts
Polymerization initiator (1) (described above): 0.234 parts
Polymerizable compound (tris(acryloyloxyethyl) isocyanurate, NK ESTER A-9300, manufactured by Shin-Nakamura Chemical Co., Ltd.): 0.192 parts
Low-molecular weight hydrophilic compound (1) (tris(2-hydroxyethyl) isocyanurate): 0.052 parts
Anionic surfactant 1 (described above): 0.099 parts
Oil sensitizing agent phosphonium compound (1) (the following structure): 0.12 parts
Oil sensitizing agent ammonium group-containing polymer (the following structure, reduced specific viscosity of 44 ml/g): 0.035 parts
Oil sensitizing agent benzyldimethyloctyl ammonium-PF6 salt: 0.032 parts
Colorant ethyl violet (the following structure): 0.030 parts
Fluorine-based surfactant (1) (described above): 0.02 parts
2-butanone: 1.091 parts
1-methoxy-2-propanol: 8.609 parts

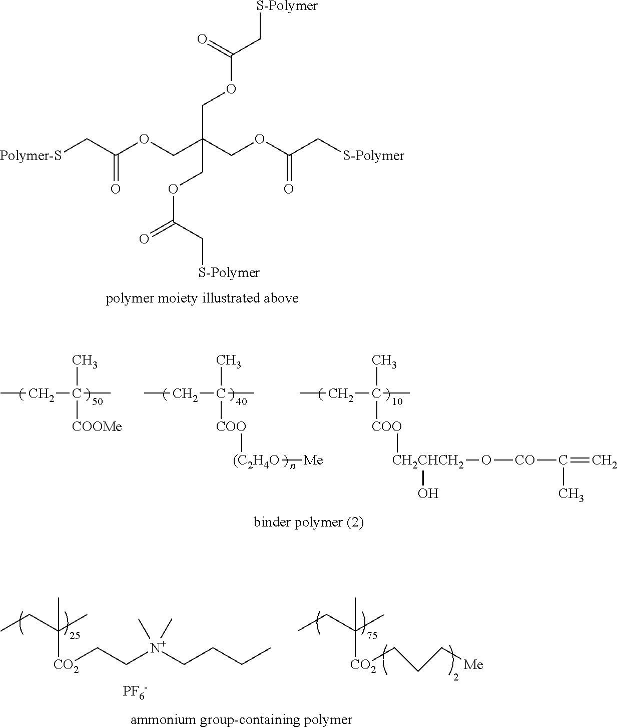

The numerical values on the lower right side of the parentheses of each constitutional unit of the binder polymer (2) and the ammonium group-containing polymer indicate the molar ratios. Me represents a methyl group.

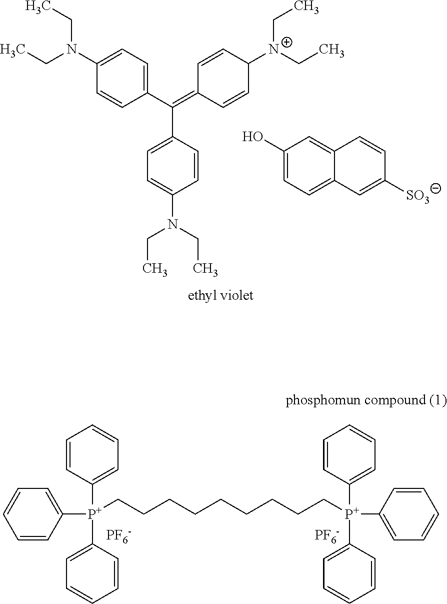

<Microgel Solution (2)>
Microgel (2): 1.580 parts
Distilled water: 1.455 parts

(Preparation of Microgel (2))

A method of preparing a microgel (2) used for the microgel solution (2) will be described below.

10 parts of an adduct (TAKENATE D-110N, manufactured by Mitsui Chemicals Polyurethanes, Inc.) of trimethylolpropane and xylene diisocyanate, 5.54 parts of dipentaerythritol pentaacrylate (SR-399, manufactured by Sartomer Japan Inc.), and 0.1 parts of PIONINE A-41C (manufactured by TAKEMOTO OIL & FAT Co., Ltd.), as oil phase components, were dissolved in 17 parts of ethyl acetate. As a water phase component, 40 parts of a 4% by mass of aqueous solution of PVA-205 was prepared. The oil phase components and the water phase components were mixed with each other and emulsified at 12,000 rpm for 10 minutes using a homogenizer. 25 parts of distilled water were added to the obtained emulsion, and the solution was stirred at room temperature (25° C., the same applies hereinafter) for 30 minutes and further stirred at 50° C. for 3 hours. The microgel solution obtained in this manner was diluted with distilled water such that the concentration of solid contents was set to 15% by mass, thereby preparing a microgel (2). The average particle diameter of the microgel measured by a light scattering method was 0.2 μm.

<Formation of Protective Layer>

The image recording layer was further bar-coated with a protective layer coating solution (65) with the following composition and dried in an oven at 1200 for 60 seconds to form a protective layer having a drying coating amount of 0.15 g/m², thereby obtaining a planographic printing plate precursor.

<Protective Layer Coating Solution (65)>
Inorganic layered compound dispersion liquid (1) (obtained in the above-described manner): 1.5 parts
Hydrophilic polymer (1) (solid content) [the following structure, Mw: 30000]: 0.55 parts
Polyvinyl alcohol (CKS50, manufactured by Nippon Synthetic Chemical Industry Co., Ltd., sulfonic acid-modified, saponification degree: 99% by mole or greater, degree of polymerization: 300) 6% by mass of aqueous solution: 0.10 parts
Polyvinyl alcohol (PVA-405, manufactured by KURARAY CO., LTD., saponification degree: 81.5% by mole, degree of polymerization: 500) 6% by mass of aqueous solution: 0.03 parts
Surfactant (RAPISOL A-80 (trade name), manufactured by NOF Corporation) 80% by mass of aqueous solution: 0.011 parts
Ion exchange water: 6.0 parts

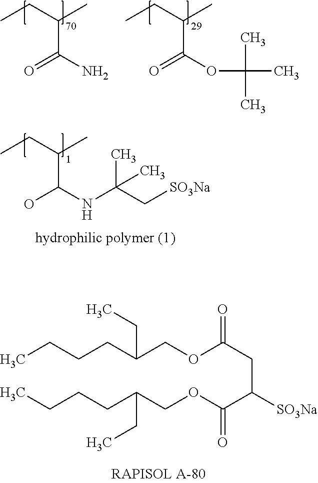

Further, the numerical values on the lower right side of the parentheses of each constitutional unit in the hydrophilic polymer (1) indicate the molar ratios.

### Example 66

<Formation of Back Coat Layer>

The surface of the support 14 on the back coat layer side (non-printing surface side) was bar-coated with the back coat layer coating solution (49) of Example 49 and dried at 100° C. for 120 seconds, thereby forming a back coat layer having a thickness of 1.2 μm.

<Formation of Image Recording Layer>

The surface of the support 14 having the back coat layer used for production of Example 66 on the printing surface side was bar-coated with an image recording layer coating solution (66) with the following composition and dried in an oven at 120° C. for 40 seconds, thereby forming an image recording layer having a coating amount of 1.0 g/m² after the drying of the solution.

<Image Recording Layer Coating Solution (66)>
Binder polymer (4) (the following structure): 4.09 parts by mass
SR399: 2.66 parts by mass
NK-Ester A-DPH: 2.66 parts by mass
CD9053: 0.53 parts by mass
Bis-t-butylphenylionoium tetraphenyl borate: 0.96 parts by mass
Fluor N2900: 0.11 parts by mass
Pigment 1 (the following structure): 0.73 parts by mass
Infrared absorbent (4) (the following structure): 0.27 parts by mass
Phosmer PE (manufactured by Uni-Chemical Co., Ltd.): 0.55 parts by mass
Ion exchange water: 13.77 parts by mass
1-methoxy-2-propanol: 48.18 parts by mass
2-butyrolactone: 13.77 parts by mass
2-butanone: 61.94 parts by mass

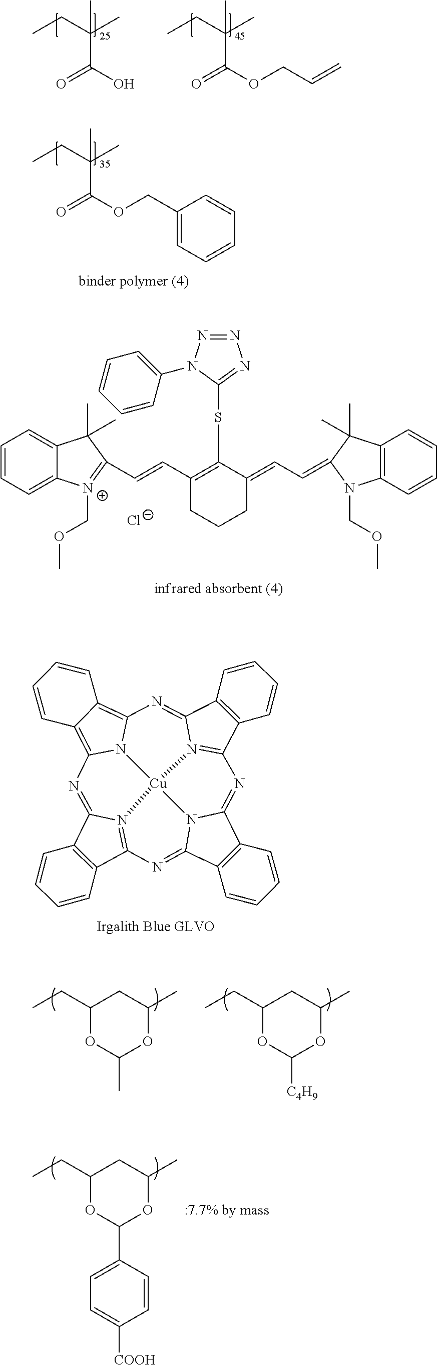

(C.I. Pigment Blue 15:4): 76.9% by mass Disperbyk 167: 15.4% by mass Pigment 1

Pigment 1 is a mixture formed of the above-described components (the pigment, the polymer, and the dispersant). Disperbyk 167 is a dispersant which is available from BYK Chemie GmbH).

SR-399: dipentaerythritol pentaacrylate (manufactured by Sartomer Japan Inc.)
NK-Ester A-DPH: dipentaerythritol hexaacrylate (manufactured by Shin-Nakamura Chemical Co., Ltd.)
CD9053: acid-modified acrylate (trifunctional) (manufactured by Sartomer Japan Inc.)
FluorN 2900: surfactant (available from Cytonix LLC)
Phosmer PE (manufactured by Uni-Chemical Co., Ltd.): the following structure

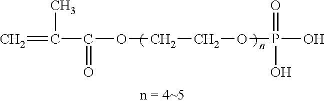

<Formation of Protective Layer>

The image recording layer was bar-coated with a protective layer coating solution (66) with the following composition and dried in an oven at 1200 for 60 seconds to form a protective layer having a drying coating amount of 0.5 g/m², thereby obtaining a planographic printing plate precursor.

(Protective Layer Coating Solution (66))
Polyvinyl alcohol (PVA-405, manufactured by KURARAY CO., LTD., saponification degree: 81.5 mol %, degree of polymerization: 500) 6% by mass of aqueous solution: 66.33 parts by mass
Surfactant (Masurf 1520, manufactured by Pilot Chemical Corp.): 0.02 parts by mass
Ion exchange water: 8.65 parts by mass

### Example 67

<Formation of Back Coat Layer>

The surface of the support 2 on the back coat layer side (non-printing surface side) was bar-coated with the back coat layer coating solution (49) of Example 49 and dried at 100° C. for 120 seconds, thereby forming a back coat layer having a thickness of 1.2 μm.

<Formation of Image Recording Layer>

The surface of the support 2 having the back coat layer used for production of Example 67 on the printing surface side was bar-coated with an image recording layer coating solution (67) with the following composition and dried in an oven at 90° C. for 60 seconds, thereby forming an image recording layer having a coating amount of 1.3 g/m² after the drying of the solution.

<Image Recording Layer Coating Solution (67)>
Binder polymer (4) (described above): 0.23 parts by mass
Urethane methacrylate oligomer (formed from reaction of glycerol dimethyl acrylate, glycerol monomethyl acrylate, propylene glycol methacrylate, and hexamethylene diisocyanate): 0.38 parts by mass
Ethoxylated bisphenol A diacrylate (NK ESTER BPE 500, manufactured by Shin-Nakamura Chemical Co., Ltd.): 0.06 parts by mass
Polymerization initiator (5) (the following structure): 0.07 parts by mass
Sensitizing dye (5) (the following structure): 0.04 parts by mass
Chain transfer agent (mercaptobenzothiazole): 0.005 parts by mass
Pigment (polymer dispersion of Heliogen Blue 7565): 0.038 parts by mass
Surfactant (BYK307, manufactured by BYK Chemie GmbH): 0.002 parts by mass
Phenoxyethanol: 10.35 parts by mass
Acetone: 1.15 parts by mass

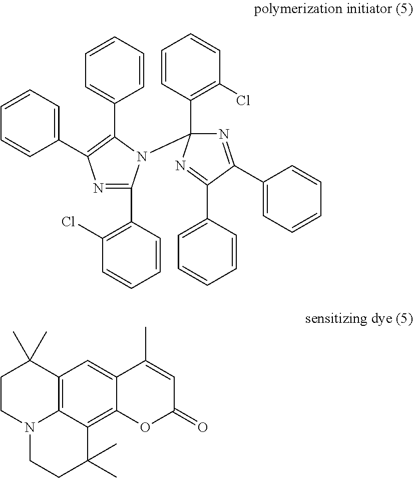

<Formation of Protective Layer>

The image recording layer was bar-coated with a protective layer coating solution (67) with the following composition and dried in an oven at 125° C. for 70 seconds to form a protective layer having a drying coating amount of 1.8 g/m².

(Protective Layer Coating Solution (67))
PVA-1 (Gohseran L-3266, manufactured by The Nippon Synthetic Chemical Industry Co., Ltd.): 0.61 parts by mass
PVA-2 (Nichigo G-Polymer AZF8035, manufactured by The Nippon Synthetic Chemical Industry Co., Ltd.): 0.32 parts by mass
Surfactant (EMALEX 710, manufactured by Nihon Emulsion Co., Ltd.): 0.002 parts by mass
Water: 13 parts by mass

### Example 68

<Formation of Back Coat Layer>

The surface of the support 15 on the back coat layer side (non-printing surface side) was bar-coated with the back coat layer coating solution (49) of Example 49 and dried at 100° C. for 120 seconds, thereby forming a back coat layer having a thickness of 1.2 μm.

<Formation of Undercoat Layer>

The surface of the support 15 having the back coat layer used for production of Example 68 on the printing surface side was coated with an undercoat layer coating solution (68) with the following composition such that the drying coating amount thereof reached 26 mg/m², thereby forming an undercoat layer.

(Undercoat Layer Coating Solution (68))
Compound for undercoat layer (2) (the following structure): 0.13 parts by mass
Hydroxyethyl imino diacetic acid: 0.05 parts by mass
Tetrasodium ethylenediaminetetraacetate: 0.05 parts by mass
Polyoxyethylene lauryl ether: 0.03 parts by mass
Water: 61.39 parts by mass

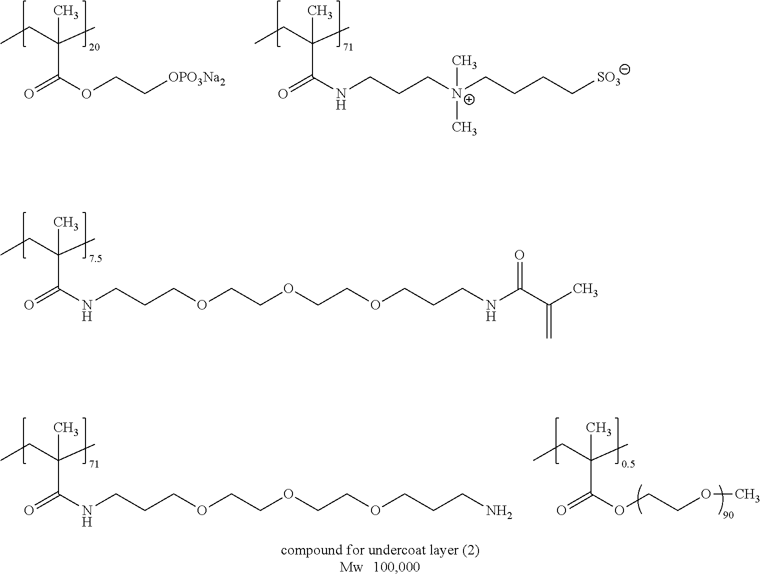

The numerical values on the lower right side of the parentheses of each constitutional unit in the above-described compound (2) for an undercoat layer indicate the mass ratios, and the numerical values on the lower right side of the parentheses of each ethyleneoxy unit indicate the repetition numbers.

<Formation of Image Recording Layer>

The undercoat layer was bar-coated with an image recording layer coating solution (68) with the following composition and dried in an oven at 100° for 60 seconds, thereby forming an image recording layer having a drying coating amount of 1.2 g/m². The image recording layer coating solution (68) was obtained by mixing a photosensitive solution (3) and a microgel solution (4) described below immediately before the coating and then stirring the solution.

(Image Recording Layer Coating Solution (68))

(Photosensitive Solution (3))
Binder polymer (6) 23% by mass of 1-methoxy-2-propanol solution (the following structure, Mw: 35,000 and n (number of ethylene oxide (EO) repeating units)): 0.3755 parts
Binder polymer (7) 23% by mass of 1-methoxy-2-propanol solution (the following structure, Mw: 35,000 and n (number of ethylene oxide (EO) repeating units)): 0.3755 parts
Infrared absorbent (1) (the following structure): 0.0278 parts
Borate compound (1) (Sodium tetraphenylborate): 0.015 parts
Polymerization initiator (1) (the following structure): 0.2348 parts
Polymerizable compound (1) (tris(acryloyloxyethyl) isocyanurate, NK ESTER A-9300 40% by mass of 2-butanone solution, manufactured by Shin-Nakamura Chemical Co., Ltd.): 0.2875 parts
Low-molecular weight hydrophilic compound (1) (tris(2-hydroxyethyl)isocyanurate): 0.0287 parts
Low-molecular weight hydrophilic compound (2) (trimethylglycine): 0.0147 parts
Anionic surfactant 1 30% by mass of aqueous solution (the following structure): 0.25 parts
Ultraviolet absorbent (1) (TINUVIN 405, manufactured by BASF SE) (the following structure): 0.04 parts
Fluorine-based surfactant (1) (the following structure): 0.004 parts
Phosphonium compound (1) (the following structure): 0.020 parts
2-butanone: 5.346 parts
1-methoxy-2-propanol: 3.128 parts
Methanol: 0.964 parts
Pure water: 0.036 parts

(Microgel Solution (4))
Microgel (4) (concentration of solid contents 21.8% by mass): 2.243 parts
1-methoxy-2-propanol: 0.600 parts

(Production of Microgel (4))

A method of preparing a microgel (1) used for the microgel solution will be described below.

<Preparation of Polyvalent Isocyanate Compound (1)>

0.043 parts of bismuth tris(2-ethylhexanoate) (NEOSTANN U-600, manufactured by NITTO KASEI CO., LTD.) was added to an ethyl acetate (25.31 parts) suspension solution of 17.78 parts (80 molar equivalent) of isophorone diisocyanate and 7.35 parts (20 molar equivalent) of the following polyhydric phenol compound (1), and the solution was stirred. The reaction temperature was set to 50° C. at the time of heat generation being subsided, and the solution was stirred for 3 hours, thereby obtaining an ethyl acetate solution (50% by mass) of a polyvalent isocyanate compound (1).

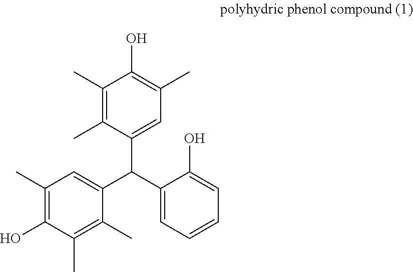 [SMILES: Cc1cc(C(c2ccccc2O)c2cc(C)c(O)c(C)c2C)c(C)c(C)c1O]

<Preparation of Microgel (4)>

The following oil phase components and the water phase component were mixed with each other and emulsified at 12,000 rpm for 10 minutes using a homogenizer. The obtained emulsion was stirred at 45° C. for 4 hours, 5.20 parts of a 10% by mass of aqueous solution of 1,8-diazabicyclo[5.4.0]undeca-7-ene-octylate (U-CAT SA102, manufactured by San-Apro Ltd.) was added thereto, and the solution was stirred at room temperature for 30 minutes and allowed to stand at 45° C. for 24 hours. The concentration of solid contents was adjusted to 21.8% by mass using distilled water, thereby obtaining an aqueous dispersion liquid of the microgel (4). The volume average particle diameter was measured using a dynamic light scattering type particle size distribution measuring device LB-500 (manufactured by Horiba Ltd.) according to a light scattering method, and the value was 0.28 Gm.

(Oil Phase Components)
(Component 1) ethyl acetate: 12.0 parts
(Component 2) adduct (50% by mass of ethyl acetate solution, manufactured by Mitsui Chemicals, Inc.) obtained by adding trimethylolpropane (6 mol) and xylene diisocyanate (18 mol) and adding methyl one-terminal polyoxyethylene (1 mol, repetition number of oxyethylene units: 90) thereto: 3.76 parts
(Component 3) polyvalent isocyanate compound (1) (as 50% by mass of ethyl acetate solution): 15.0 parts
(Component 4) 65% by mass of solution of dipentaerythritol pentaacrylate (SR-399, manufactured by Sartomer Japan Inc.) in ethyl acetate: 11.54 parts
(Component 5) 10% solution of sulfonate type surfactant (PIONINE A-41-C, manufactured by TAKEMOTO OIL & FAT Co., Ltd.) in ethyl acetate: 4.42 parts

(Water Phase Component)
Distilled water: 46.87 parts

<Synthesis of Binder Polymer (6)>

78.0 g of 1-methoxy-2-propanol was weighed in a three-neck flask and heated to 70° C. in a nitrogen stream. A mixed solution formed of 52.1 g of BLEMMER PME-100 (methoxy diethylene glycol monomethacrylate, manufactured by NOF Corporation), 21.8 g of methyl methacrylate, 14.2 g of methacrylic acid, 2.15 g of hexakis(3-mercaptopropionic acid) dipentaerythritol, 0.38 g of V-601 (2,2′-azobis(isobutyric acid) dimethyl, manufactured by Wako Pure Chemical Industries, Ltd.), and 54 g of 1-methoxy-2-propanol was added dropwise to the reaction container for 2 hours and 30 minutes. After the dropwise addition, the solution was heated to 80° C. to further continue the reaction for 2 hours. A mixed solution formed of 0.04 g of V-601 and 4 g of 1-methoxy-2-propanol was added thereto, the solution was heated to 90° C. to further continue the reaction for 2.5 hours. After completion of the reaction, the reaction solution was cooled to room temperature.

137.2 g of 1-methoxy-2-propanol, 0.24 g of 4-hydroxytetramethylpiperidine-N-oxide, 26.0 g of glycidyl methacrylate, and 3.0 g of tetraethylammonium bromide were added to the reaction solution, and the resulting solution was stirred thoroughly and heated to 90° C.

After 18 hours, the reaction solution was cooled to room temperature (25° C.) and diluted by adding 99.4 g of 1-methoxy-2-propanol thereto.

The concentration of solid contents in a binder polymer (6) obtained in the above-described manner was 23% by mass, and the weight-average molecular weight thereof in terms of polystyrene which was measured by GPC was 35000.

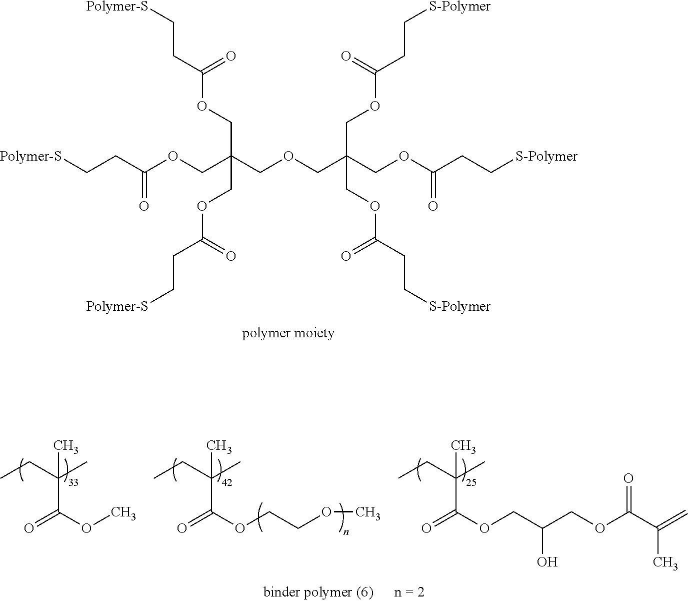

<Synthesis of Binder Polymer (7)>

78.00 g of 1-methoxy-2-propanol was weighed in a three-neck flask and heated to 70° C. in a nitrogen stream. A mixed solution formed of 52.8 g of BLEMMER PME-100 (methoxy diethylene glycol monomethacrylate, manufactured by NOF Corporation), 2.8 g of methyl methacrylate, 25.0 g of methacrylic acid, 6.4 g of hexakis(3-mercaptopropionic acid) dipentaerythritol, 1.1 g of V-601 (2,2′-azobis(isobutyric acid) dimethyl, manufactured by Wako Pure Chemical Industries, Ltd.), and 55 g of 1-methoxy-2-propanol was added dropwise to the reaction container for 2 hours and 30 minutes. After the dropwise addition, the solution was heated to 80° C. to further continue the reaction for 2 hours. After 2 hours, a mixed solution formed of 0.11 g of V-601 and 1 g of 1-methoxy-2-propanol was added thereto, the solution was heated to 90° C. to further continue the reaction for 2.5 hours. After completion of the reaction, the reaction solution was cooled to room temperature.

177.2 g of 1-methoxy-2-propanol, 0.28 g of 4-hydroxytetramethylpiperidine-N-oxide, 46.0 g of glycidyl methacrylate, and 3.4 g of tetrabutylammonium bromide were added to the reaction solution, and the resulting solution was stirred thoroughly and heated to 90° C.

After 18 hours, the reaction solution was cooled to room temperature (25° C.) and diluted by adding 0.06 g of 4-methoxyphenol and 114.5 g of 1-methoxy-2-propanol thereto.

The concentration of solid contents in a binder polymer (7) obtained in the above-described manner was 23% by mass, and the weight-average molecular weight thereof in terms of polystyrene which was measured by GPC was 15000.

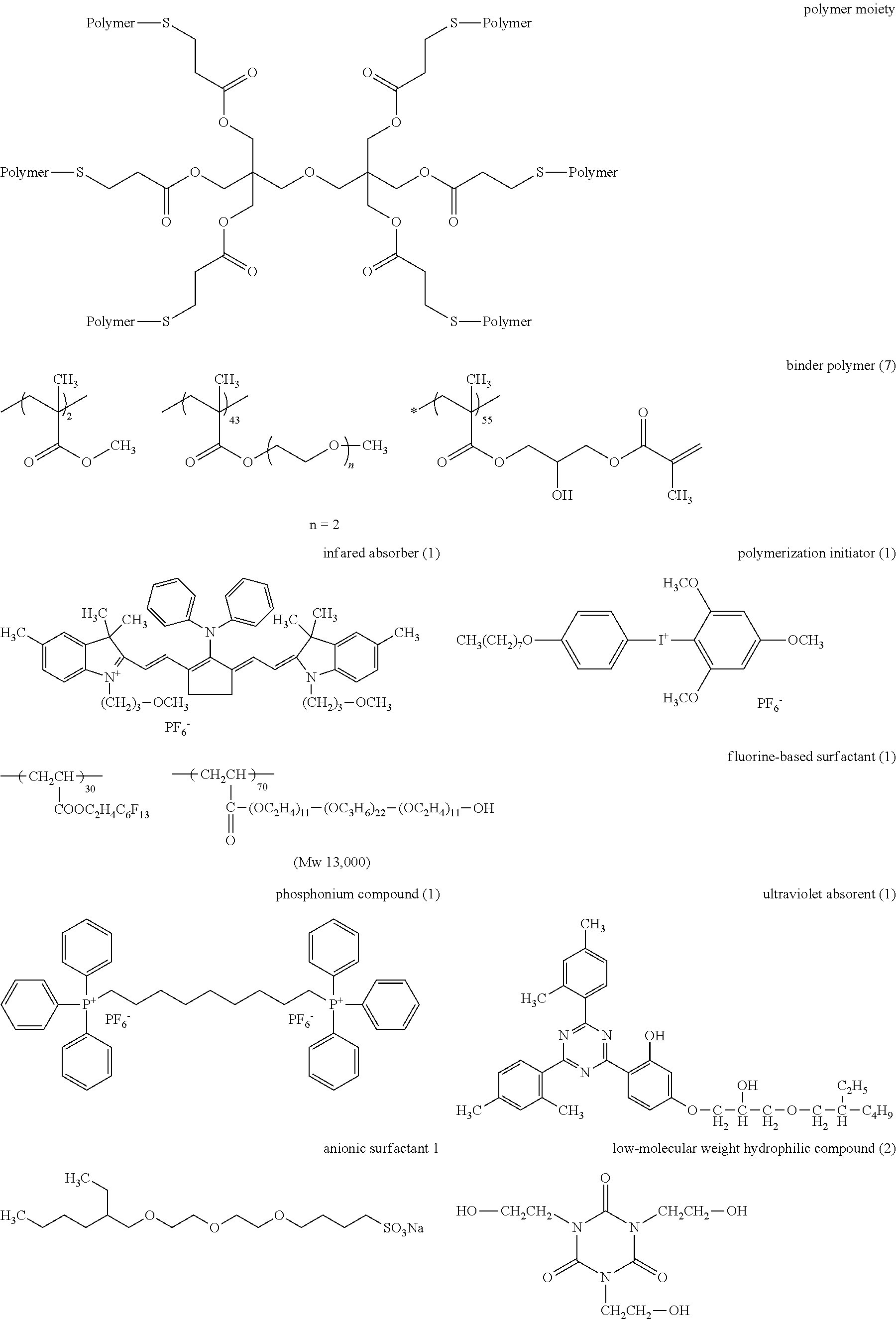

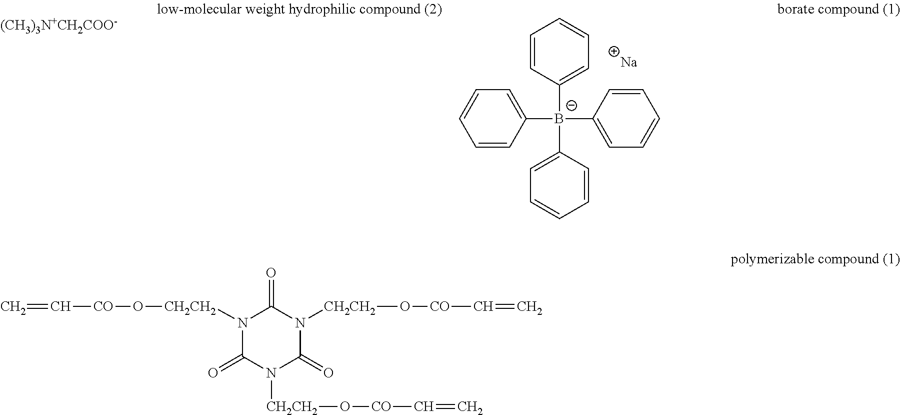

<Formation of Protective Layer>

The image recording layer was bar-coated with a protective layer coating solution (68) with the following composition and dried in an oven at 1200 for 60 seconds to form a protective layer having a drying coating amount of 0.18 g/m², thereby producing a planographic printing plate precursor.

(Protective Layer Coating Solution (68))
Inorganic layered compound dispersion liquid (1) 2.290 g
Polyvinyl alcohol (CKS50, manufactured by Nippon Synthetic Chemical Industry Co., Ltd., sulfonic acid-modified, saponification degree: 99 mol % or greater, degree of polymerization: 300) 6% by mass of aqueous solution 1.083 parts
Surfactant (RAPISOL A-80 (the following structure), manufactured by NOF Corporation, 80% by mass of aqueous solution): 0.015 parts
Phosphoric acid (85% by mass of aqueous solution) 0.032 parts
Diammonium hydrogen phosphate: 0.044 parts
Pure water 4.517 parts

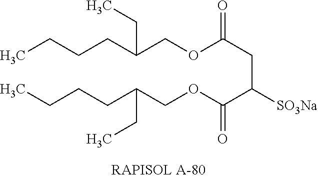

### Example 69

<Formation of Back Coat Layer>

The surface of the support 15 on the back coat layer side (non-printing surface side) was bar-coated with the back coat layer coating solution (49) of Example 49 and dried at 100° C. for 120 seconds, thereby forming a back coat layer having a thickness of 1.2 μm.

<Formation of Undercoat Layer>

The surface of the support 15 having the back coat layer used for production of Example 69 on the printing surface side was coated with the undercoat layer coating solution (68) with the above-described composition such that the drying coating amount thereof reached 26 mg/m², thereby forming an undercoat layer.

<Formation of Image Recording Layer>

An image recording layer was formed in the same manner as in Example 68 except that the amount of the binder polymer (6) and the amount of the binder polymer (7) in the image recording layer coating solution (68) of Example 68 were respectively changed to 0.2891 parts and 0.4574 parts.

<Formation of Protective Layer>

The image recording layer was bar-coated with a protective layer coating solution (69) with the following composition and dried in an oven at 1200 for 60 seconds to form a protective layer having a drying coating amount of 0.18 g/m², thereby producing a planographic printing plate precursor.

(Protective Layer Coating Solution (69))
Inorganic layered compound dispersion liquid (1) 2.212 parts
Polyvinyl alcohol (Gohseran L-3266, manufactured by The Nippon Synthetic Chemical Industry Co., Ltd., sulfonic acid-modified, saponification degree of 85% by mole) 6% by mass of aqueous solution: 1.440 parts
Surfactant (PIONINE A-32-B (the following structure), manufactured by TAKEMOTO OIL & FAT Co., Ltd., 40% by mass of aqueous solution): 0.014 parts
Surfactant (SURFYNOL 465 (the following structure), manufactured by Nissin Chemical Co., Ltd.): 0.006 parts
Phosphoric acid (85% by mass of aqueous solution) 0.023 parts
Diammonium hydrogen phosphate: 0.032 parts
Pure water 3.983 parts

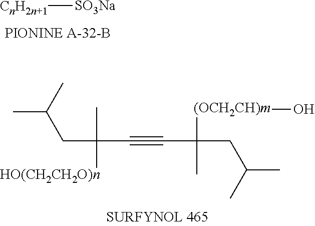

### Example 70

<Formation of Back Coat Layer>

A back coat layer was formed in the same manner as in Example 49 except that the amount of the tabular particles added to the back coat layer coating solution (49) was changed as listed in Table 2.

<Formation of Undercoat Layer>

The surface of the support 15 having the back coat layer used for production of Example 70 on the printing surface side was coated with the undercoat layer coating solution (68) with the above-described composition such that the drying coating amount thereof reached 26 mg/m², thereby forming an undercoat layer.

<Formation of Image Recording Layer>

An image recording layer was formed in the same manner as in Example 68 except that the amount of the binder polymer (6) and the amount of the binder polymer (7) in the image recording layer coating solution (68) of Example 68 were respectively changed to 0.2891 parts and 0.4574 parts.

<Formation of Protective Layer>

The image recording layer was bar-coated with a protective layer coating solution (69) with the above composition and dried in an oven at 1200 for 60 seconds to form a protective layer having a drying coating amount of 0.18 g/m², thereby producing a planographic printing plate precursor.

### Example 71

<Formation of Back Coat Layer>

A back coat layer was formed in the same manner as in Example 49 except that the amount of the tabular particles added to the back coat layer coating solution (49) was changed as listed in Table 2.

<Formation of Undercoat Layer>

The surface of the support 15 having the back coat layer used for production of Example 71 on the printing surface side was coated with the undercoat layer coating solution (68) with the above-described composition such that the drying coating amount thereof reached 26 mg/m², thereby forming an undercoat layer.

<Formation of Image Recording Layer>

An image recording layer was formed in the same manner as in Example 68 except that the amount of the binder polymer (6) and the amount of the binder polymer (7) in the image recording layer coating solution (68) of Example 68 were respectively changed to 0.2891 parts and 0.4574 parts.

<Formation of Protective Layer>

The image recording layer was bar-coated with a protective layer coating solution (69) with the above composition and dried in an oven at 1200 for 60 seconds to form a protective layer having a drying coating amount of 0.18 g/m², thereby producing a planographic printing plate precursor.

### Example 72

<Formation of Back Coat Layer>

A back coat layer was formed in the same manner as in Example 49 except that the amount of the tabular particles added to the back coat layer coating solution (49) was changed as listed in Table 2.

<Formation of Undercoat Layer>

The surface of the support 15 having the back coat layer used for production of Example 72 on the printing surface side was coated with the undercoat layer coating solution (68) with the above-described composition such that the drying coating amount thereof reached 26 mg/m², thereby forming an undercoat layer.

<Formation of Image Recording Layer>

An image recording layer was formed in the same manner as in Example 68 except that the amount of the binder polymer (6) and the amount of the binder polymer (7) in the image recording layer coating solution (68) of Example 68 were respectively changed to 0.2891 parts and 0.4574 parts.

<Formation of Protective Layer>

The image recording layer was bar-coated with a protective layer coating solution (69) with the above composition and dried in an oven at 1200 for 60 seconds to form a protective layer having a drying coating amount of 0.18 g/m², thereby producing a planographic printing plate precursor.

[Evaluation of Printing Plate Precursor]

The scratch resistance, the abrasion resistance, and the measurement of the arithmetic average height Sa of the layer containing tabular particles of the printing plate precursors (the planographic printing plate precursors and the printing key plate precursors) obtained in each example and each comparative example were evaluated in the same manners as described above.

The evaluation results were listed in Table 2.

TABLE 2

| | | | | Non-printing surface side | | | | | | | |
|---|---|---|---|---|---|---|---|---|---|---|---|
| | | Printing surface side | | Layer component | | | Tabular particles | | | | |
| | | Layer | | | | | | | | | Addition |
| | Support | containing | Protective | | | Thickness | | | Thickness | Aspect | amount |
| | Type | polymer | layer | Type | Detail | (nm) | Type | Detail | (nm) | ratio | (mg/m²) |
| Example 49 | 1 | Layer 1 | None | BR-605 | Acrylic | 1.2 | SUMECTON- | Organic | 1 | 50 | 50 |
| | | | | (RHEODOL | | | | | | | |
| | | | | 24 mg/m²) | resin | | SEN | smectite | | | |
| Example 50 | 4 | Layer 1 | None | BR-605 | Acrylic | 1.2 | SUMECTON- | Organic | 1 | 50 | 50 |
| | | | | (RHEODOL | resin | | SEN | smectite | | | |
| | | | | 24 mg/m²) | | | | | | | |
| Example 51 | 5 | Layer 1 | None | BR-605 | Acrylic | 1.2 | SUMECTON- | Organic | 1 | 50 | 50 |
| | | | | (RHEODOL | resin | | SEN | smectite | | | |
| | | | | 24 mg/m²) | | | | | | | |
| Example 52 | 6 | Layer 1 | None | BR-605 | Acrylic | 1.2 | SUMECTON- | Organic | 1 | 50 | 50 |
| | | | | (RHEODOL | | | SEN | smectite | | | |
| | | | | 24 mg/m²) | | | | | | | |
| Example 53 | 7 | Layer 1 | None | BR-605 | Acrylic | 1.2 | SUMECTON- | Organic | 1 | 50 | 50 |
| | | | | (RHEODOL | resin | | SEN | smectite | | | |
| | | | | 24 mg/m²) | | | | | | | |
| Example 54 | 8 | Layer 1 | None | BR-605 | Acrylic | 1.2 | SUMECTON- | Organic | 1 | 50 | 50 |
| | | | | (RHEODOL | resin | | SEN | smectite | | | |
| | | | | 24 mg/m²) | | | | | | | |
| Example 55 | 9 | Layer 1 | None | BR-605 | Acrylic | 1.2 | SUMECTON- | Organic | 1 | 50 | 50 |
| | | | | (RHEODOL | resin | | SEN | smectite | | | |
| | | | | 24 mg/m²) | | | | | | | |
| Example 56 | 10 | Layer 1 | None | BR-605 | Acrylic | 1.2 | SUMECTON- | Organic | 1 | 50 | 50 |
| | | | | (RHEODOL | resin | | SEN | smectite | | | |
| | | | | 24 mg/m²) | | | | | | | |
| Example 57 | 11 | Layer 1 | None | BR-605 | Acrylic | 1.2 | SUMECTON- | Organic | 1 | 50 | 50 |
| | | | | (RHEODOL | resin | | SEN | smectite | | | |
| | | | | 24 mg/m²) | | | | | | | |
| Example 58 | 12 | Layer 1 | None | BR-605 | Acrylic | 1.2 | SUMECTON- | Organic | 1 | 50 | 50 |
| | | | | (RHEODOL | resin | | SEN | smectite | | | |
| | | | | 24 mg/m²) | | | | | | | |
| Example 59 | 2 | Layer 2 | None | BR-605 | Acrylic | 1.2 | SUMECTON- | Organic | 1 | 50 | 50 |
| | | | | (RHEODOL | resin | | SEN | smectite | | | |
| | | | | 24 mg/m²) | | | | | | | |
| Example 60 | 3 | Layer 3 | Formed | BR-605 | Acrylic | 1.2 | SUMECTON- | Organic | 1 | 50 | 50 |
| | | | | (RHEODOL | resin | | SEN | smectite | | | |
| | | | | 24 mg/m²) | | | | | | | |
| Example 61 | 3 | Layer 4 | Formed | BR-605 | Acrylic | 1.2 | SUMECTON- | Organic | 1 | 50 | 50 |
| | | | | (RHEODOL | resin | | SEN | smectite | | | |
| | | | | 24 mg/m²) | | | | | | | |
| Example 62 | 3 | Layer 5 | Formed | BR-605 | Acrylic | 1.2 | SUMECTON- | Organic | 1 | 50 | 50 |
| | | | | (RHEODOL | resin | | SEN | smectite | | | |
| | | | | 24 mg/m²) | | | | | | | |
| Example 63 | 3 | Layer 6 | Formed | BR-605 | Acrylic | 1.2 | SUMECTON- | Organic | 1 | 50 | 50 |
| | | | | (RHEODOL | resin | | SEN | smectite | | | |
| | | | | 24 mg/m²) | | | | | | | |
| Example 64 | 3 | Layer 7 | Formed | BR-605 | Acrylic | 1.2 | SUMECTON- | Organic | 1 | 50 | 50 |
| | | | | (RHEODOL | resin | | SEN | smectite | | | |
| | | | | 24 mg/m²) | | | | | | | |
| Example 65 | 13 | Layer 8 | Formed | BR-605 | Acrylic | 1.2 | SUMECTON- | Organic | 1 | 50 | 50 |
| | | | | (RHEODOL | resin | | SEN | smectite | | | |
| | | | | 24 mg/m²) | | | | | | | |
| Example 66 | 14 | Layer 9 | Formed | BR-605 | Acrylic | 1.2 | SUMECTON- | Organic | 1 | 50 | 50 |
| | | | | (RHEODOL | resin | | SEN | smectite | | | |
| | | | | 24 mg/m²) | | | | | | | |
| Example 67 | 2 | Layer 10 | Formed | BR-605 | Acrylic | 1.2 | SUMECTON- | Organic | 1 | 50 | 50 |
| | | | | (RHEODOL | resin | | SEN | smectite | | | |
| | | | | 24 mg/m²) | | | | | | | |
| Example 68 | 15 | Layer 11 | Formed | BR-605 | Acrylic | 1.2 | SUMECTON- | Organic | 1 | 50 | 50 |
| | | | | (RHEODOL | resin | | SEN | smectite | | | |
| | | | | 24 mg/m²) | | | | | | | |
| Example 69 | 15 | Layer 12 | Formed | BR-605 | Acrylic | 1.2 | SUMECTON- | Organic | 1 | 50 | 50 |
| | | | | (RHEODOL | resin | | SEN | smectite | | | |
| | | | | 24 mg/m²) | | | | | | | |
| Example 70 | 15 | Layer 12 | Formed | BR-605 | Acrylic | 1.2 | SUMECTON- | Organic | 1 | 50 | 40 |
| | | | | (RHEODOL | resin | | SEN | smectite | | | |
| | | | | 24 mg/m²) | | | | | | | |
| Example 71 | 15 | Layer 12 | Formed | BR-605 | Acrylic | 1.2 | SUMECTON- | Organic | 1 | 50 | 30 |
| | | | | (RHEODOL | resin | | SEN | smectite | | | |
| | | | | 24 mg/m²) | | | | | | | |
| Example 72 | 15 | Layer 12 | Formed | BR-605 | Acrylic | 1.2 | SUMECTON- | Organic | 1 | 50 | 20 |
| | | | | (RHEODOL | resin | | SEN | smectite | | | |
| | | | | 24 mg/m²) | | | | | | | |

| | Non-printing surface side | | | | | | | | |
|---|---|---|---|---|---|---|---|---|---|
| | Tabular particles | Particles other than tabular particles | | | | | | | |
| | Addition | | | Thick- | | Addition | Evaluation result | | |
| | amount | | | ness | Aspect | amount | | Scratch | Abrasion |
| | (mg/m²) | Type | Detail | (nm) | ratio | (mg/m²) | Sa | resistance | resistance |
| Example 49 | 50 | ART PEARL 6PF | Acrylic | 4 | 1 | 93 | 1.7 | 5 | 5 |
| Example 50 | 50 | ART PEARL 6PF | Acrylic | 4 | 1 | 93 | 1.7 | 5 | 5 |
| Example 51 | 50 | ART PEARL 6PF | Acrylic | 4 | 1 | 93 | 1.7 | 5 | 5 |
| Example 52 | 50 | ART PEARL 6PF | Acrylic | 4 | 1 | 93 | 1.7 | 5 | 5 |
| Example 53 | 50 | ART PEARL 6PF | Acrylic | 4 | 1 | 93 | 1.7 | 5 | 5 |
| Example 54 | 50 | ART PEARL 6PF | Acrylic | 4 | 1 | 93 | 1.7 | 5 | 5 |
| Example 55 | 50 | ART PEARL 6PF | Acrylic | 4 | 1 | 93 | 1.7 | 5 | 5 |
| Example 56 | 50 | ART PEARL 6PF | Acrylic | 4 | 1 | 93 | 1.7 | 5 | 5 |
| Example 57 | 50 | ART PEARL 6PF | Acrylic | 4 | 1 | 93 | 1.7 | 5 | 5 |
| Example 58 | 50 | ART PEARL 6PF | Acrylic | 4 | 1 | 93 | 1.7 | 5 | 5 |
| Example 59 | 50 | ART PEARL 6PF | Acrylic | 4 | 1 | 93 | 1.7 | 5 | 5 |
| Example 60 | 50 | ART PEARL 6PF | Acrylic | 4 | 1 | 93 | 1.7 | 5 | 5 |
| Example 61 | 50 | ART PEARL 6PF | Acrylic | 4 | 1 | 93 | 1.7 | 5 | 5 |
| Example 62 | 50 | ART PEARL 6PF | Acrylic | 4 | 1 | 93 | 1.7 | 5 | 5 |
| Example 63 | 50 | ART PEARL 6PF | Acrylic | 4 | 1 | 93 | 1.7 | 5 | 5 |
| Example 64 | 50 | ART PEARL 6PF | Acrylic | 4 | 1 | 93 | 1.7 | 5 | 5 |
| Example 65 | 50 | ART PEARL 6PF | Acrylic | 4 | 1 | 93 | 1.7 | 5 | 5 |
| Example 66 | 50 | ART PEARL 6PF | Acrylic | 4 | 1 | 93 | 1.7 | 5 | 5 |
| Example 67 | 50 | ART PEARL 6PF | Acrylic | 4 | 1 | 93 | 1.7 | 5 | 5 |
| Example 68 | 50 | ART PEARL 6PF | Acrylic | 4 | 1 | 93 | 1.7 | 5 | 5 |
| Example 69 | 50 | ART PEARL 6PF | Acrylic | 4 | 1 | 93 | 1.7 | 5 | 5 |
| Example 70 | 40 | ART PEARL 6PF | Acrylic | 4 | 1 | 93 | 1.7 | 4 | 4 |
| Example 71 | 30 | ART PEARL 6PF | Acrylic | 4 | 1 | 93 | 1.7 | 4 | 4 |
| Example 72 | 20 | ART PEARL 6PF | Acrylic | 4 | 1 | 93 | 1.7 | 3 | 3 |

According to the present invention, it is possible to provide a printing plate precursor which is capable of preventing scratches on a rear surface layer and peeling of the rear surface layer even without interleaving paper in a case where printing plate precursors each including a planographic printing plate precursor and a key plate precursor are laminated. Further, it is also possible to provide a laminate of the printing plate precursors.

The present invention has been described with reference to detailed and specific embodiments, but various changes or modifications can be made without departing from the spirit and the scope of the present invention and this is apparent to those skilled in the art.

The present application is based on Japanese Patent Application (JP2017-167854) filed on Aug. 31, 2017, and the contents of which are incorporated herein by reference.

### EXPLANATION OF REFERENCES

1: Aluminum plate
2, 4: Roller-like brush
3: Polishing slurry liquid
5, 6, 7, 8: Support roller
50: Main electrolytic cell
51: AC power source
52: Radial drum roller
53a, 53b: Main pole
54: Electrolyte supply port
55: Electrolyte
56: Slit
57: Electrolyte passage
58: Auxiliary anode
60: Auxiliary anode cell
W: Aluminum plate
410: Anodizing device
412: Power supply tank
414: Electrolytic treatment tank
416: Aluminum plate
418, 426: Electrolyte
420: Power supply electrode
422, 428: Roller
424: Nip roller
430: Electrolytic electrode
432: Tank wall
434: DC power source

What is claimed is:

1. A printing plate precursor comprising:
an aluminum support;
a layer containing a polymer on a printing surface side on the aluminum support; and
a layer containing tabular particles on a non-printing surface side opposite to the layer containing the polymer in a state of sandwiching the aluminum support therebetween.

2. The printing plate precursor according to claim 1,
wherein a thickness of each of the tabular particles is smaller than a thickness of the layer containing the tabular particles.

3. The printing plate precursor according to claim 1,
wherein the tabular particles contain a silicon atom and an oxygen atom.

4. The printing plate precursor according to claim 2,
wherein the tabular particles contain a silicon atom and an oxygen atom.

5. The printing plate precursor according to claim 3,
wherein the tabular particles containing a silicon atom and an oxygen atom are smectite, bentonite, or mica.

6. The printing plate precursor according to claim 4,
wherein the tabular particles containing a silicon atom and an oxygen atom are smectite, bentonite, or mica.

7. The printing plate precursor according to claim 1,
wherein the layer containing the tabular particles contains a polymer or a metal oxide obtained by hydrolyzing and polycondensing an organic metal compound or an inorganic metal compound.

8. The printing plate precursor according to claim 2,
wherein the layer containing the tabular particles contains a polymer or a metal oxide obtained by hydrolyzing and polycondensing an organic metal compound or an inorganic metal compound.

9. The printing plate precursor according to claim 1,
wherein the layer containing the tabular particles further contains particles other than the tabular particles, and
an average particle diameter of the particles other than the tabular particles is 0.1 μm or greater and is greater than a thickness of the layer containing the tabular particles.

10. The printing plate precursor according to claim 2,
wherein the layer containing the tabular particles further contains particles other than the tabular particles, and
an average particle diameter of the particles other than the tabular particles is 0.1 μm or greater and is greater than a thickness of the layer containing the tabular particles.

11. The printing plate precursor according to claim 9,
wherein the particles other than the tabular particles are organic resin particles, inorganic particles, or organic-inorganic composite particles.

12. The printing plate precursor according to claim 10,
wherein the particles other than the tabular particles are organic resin particles, inorganic particles, or organic-inorganic composite particles.

13. The printing plate precursor according to claim 1,
wherein an arithmetic average height Sa of the layer containing the tabular particles is in a range of 0.1 to 20 μm.

14. The printing plate precursor according to claim 2,
wherein an arithmetic average height Sa of the layer containing the tabular particles is in a range of 0.1 to 20 μm.

15. The printing plate precursor according to claim 1,
wherein the layer containing the polymer is an image recording layer including an infrared absorbent, a polymerization initiator, a polymerizable compound, and a polymer compound having a particle shape.

16. The printing plate precursor according to claim 2,
wherein the layer containing the polymer is an image recording layer including an infrared absorbent, a polymerization initiator, a polymerizable compound, and a polymer compound having a particle shape.

17. The printing plate precursor according to claim 15,
wherein the polymer compound having a particle shape contained in the image recording layer has a hydrophobic main chain and both of a constitutional unit (i) which contains a pendant-cyano group directly bonded to the hydrophobic main chain and a constitutional unit (ii) which contains a pendant group having a hydrophilic polyalkylene oxide segment.

18. The printing plate precursor according to claim 16,
wherein the polymer compound having a particle shape contained in the image recording layer has a hydrophobic main chain and both of a constitutional unit (i) which contains a pendant-cyano group directly bonded to the hydrophobic main chain and a constitutional unit (ii) which contains a pendant group having a hydrophilic polyalkylene oxide segment.

19. The printing plate precursor according to claim 1,
wherein the layer containing the polymer includes an infrared absorbent and thermoplastic polymer particles.

20. A printing plate precursor laminate which is obtained by laminating a plurality of printing plate precursors,
wherein each of the plurality of printing plate precursors comprises an aluminum support; a layer containing a polymer on a printing surface side on the aluminum support; and
a layer containing tabular particles on a non-printing surface side opposite to the layer containing the polymer in a state of sandwiching the aluminum support therebetween, and
wherein the printing plate precursor laminate is formed such that an outermost layer on a surface where the layer containing the polymer is provided and an outermost layer on a surface where the layer containing the tabular particles is provided are laminated by being brought into direct contact with each other.
